(19) United States
(12) Patent Application Publication
(10) Pub. No.: US 2026/0101668 A1
(43) Pub. Date: Apr. 9, 2026

(54) METAL COMPLEX AND ELECTROLUMINESCENT DEVICE

(71) Applicant: GUANGDONG AGLAIA OPTOELECTRONIC MATERIALS CO., LTD, Guangdong (CN)

(72) Inventors: Shaofu CHEN, Guangdong (CN); Li WANG, Guangdong (CN); Kangzhi YE, Guangdong (CN); Lei DAI, Guangdong (CN); Lifei CAI, Guangdong (CN)

(73) Assignee: GUANGDONG AGLAIA OPTOELECTRONIC MATERIALS CO., LTD, Guangdong (CN)

(21) Appl. No.: 19/471,481

(22) PCT Filed: Feb. 1, 2024
(86) PCT No.: PCT/CN2024/075114

§ 371 Date: Oct. 1, 2025

(30) Foreign Application Priority Data
Feb. 16, 2023 (CN) 202310119984.4
Jan. 24, 2024 (CN) 202410104891.9

(51) Int. Cl. H10K 85/30; C07B 59/00; C07F 15/00; C09K 11/06; H10K 50/12

(52) U.S. Cl. CPC H10K 85/342; C07B 59/004; C07F 15/0033; C09K 11/06; C07B 2200/05; C09K 2211/1029; C09K 2211/1033; C09K 2211/1037; C09K 2211/185; H10K 50/12

(57) ABSTRACT

A metal complex and an electroluminescent device. The metal complex has a general formula of Ir(La)(Lb)(Lc), the structure of which is represented by formula (1). The metal complex has the advantages of a low evaporation temperature, high photochemical and electrochemical stability, a narrow half-peak width, a high color saturation, a high light-emitting efficiency, a long device service life, etc., can be used in an organic light-emitting device and especially used as a red light-emitting phosphorescent material, and has the potential of being applied to the AMOLED industry.

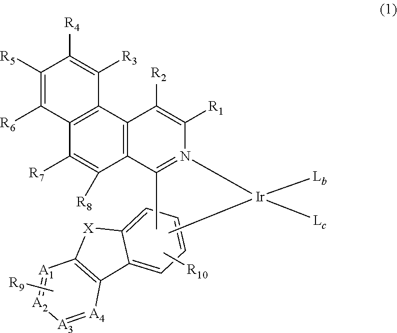

### CROSS-REFERENCE TO RELATED APPLICATIONS

This application is a national phase entry under 35 USC § 371 of International Application No. PCT/CN2024/075114 filed Feb. 1, 2024, which claims the benefit of and priority to Chinese Patent Application No. 202310119984.4, filed Feb. 16, 2023, and Chinese Patent Application No. 202410104891.9, filed Jan. 24, 2024, the entire disclosures of which are incorporated herein by reference.

### TECHNICAL FIELD

The present disclosure relates to the technical field of organic electroluminescence, in particular, to an organic light-emitting material, and more particularly, to a metal complex and an electroluminescent device.

### BACKGROUND

At present, organic electroluminescent devices (OLEDs), as a new generation of display technology, have received increasing attentions in both display and lighting technologies, and have broad application prospects. However, compared with market application requirements, the performances of light-emitting efficiency, driving voltage, and service life, etc., of OLED devices still need to be further strengthened and improved.

Generally, the basic structure of an OLED device is a thin film of an organic functional material with various functions sandwiched between metal electrodes, like a sandwich structure. Driven by electric current, holes and electrons are injected from the anode and cathode respectively, after moving a certain distance, the holes and electrons are recombined in the light-emitting layer and released in the form of light or heat, thereby generating the luminescence of the OLED.

However, the organic functional material is a core component of organic electroluminescent devices. The thermal stability, photochemical stability, electrochemical stability, quantum yield, film formation stability, crystallinity, color saturation, etc. of the material are all major factors affecting the performance of the device.

Generally, organic functional materials include fluorescent materials and phosphorescent materials. Fluorescent materials are usually small organic molecular materials, which can generally only utilize 25% singlet state to emit light, thus having relatively low luminescence efficiency. Whereas, due to spin-orbit coupling caused by heavy-atom effect, phosphorescent materials can utilize the energy of 75% triplet excitons in addition to the 25% singlet excitons, thus enabling a significant improvement in light-emitting efficiency. However, compared with fluorescent materials, the research of phosphorescent materials started later, and their thermal stability, lifetime, color saturation, etc., all need to be improved, which is a challenging task. Various organometallic compounds have been developed as such phosphorescent materials. For example, invention patent document CN1589307A discloses a class of metal complexes

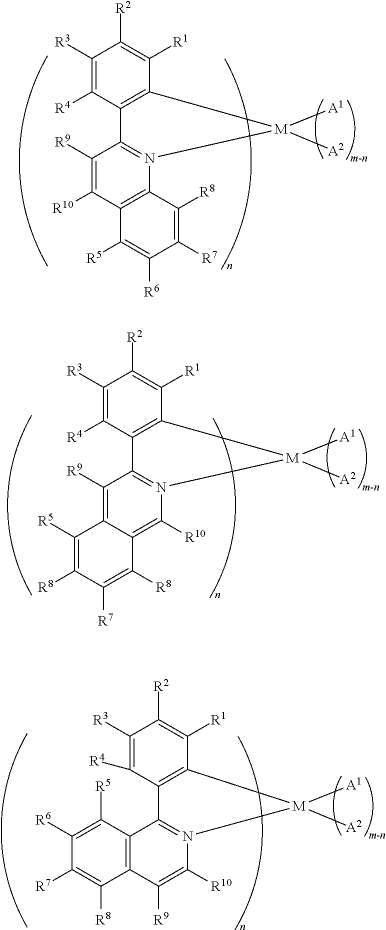

with compounds of quinoline or isoquinoline linked to benzene rings as ligands, especially particularly an iridium complex, which can provide luminescence at 500-700 nm. It also points out that the luminescence color of the compound can be adjusted by selecting electron-donating or electron-withdrawing groups at specific positions. Invention patent document CN104885248B discloses an iridium complex

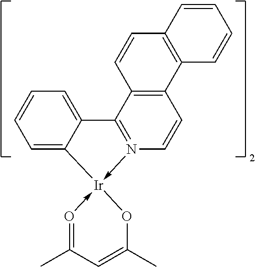

with benzisoquinoline linked to phenyl as ligands, where the applicant points out that high device efficiency and long service life can be provided by adjusting the matching and combination of light-emitting layers. Invention patent document U.S. Pat. No. 9,917,264B2 discloses a tri-ligand iridium complex

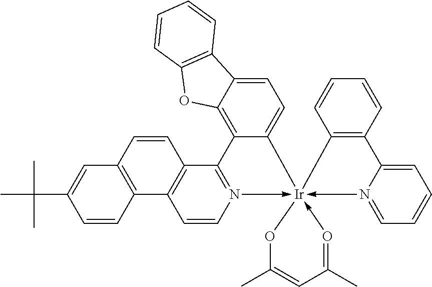

containing benzisoquinoline, where although the applicant has improved the light-emitting efficiency and lifetime by incorporating the light-emitting layers, it still fails not meet the application requirements. Invention patent document CN111377974A reports an iridium complex

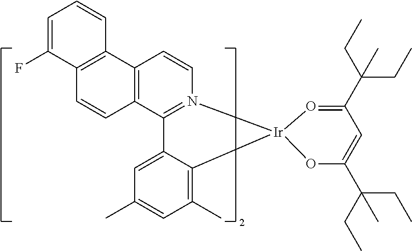

of a 2+1 ligand of benzisoquinoline. However, this type of material has a relatively wide full width at half maximum, and the color saturation, device efficiency, and lifespan need to be improved. Invention patent CN111377969B discloses a complex of N-heterodibenzofuran-isoquinoline structure and an organic electroluminescent device and compound

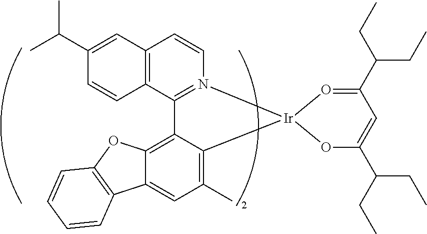

containing the complex, however the efficiency and lifespan of which still need to be further improved to meet the growing demands of the market. Invention patent documents CN114736244A and CN114805448A respectively disclose methal complexes with D-substitution at the 3 and 4 positions of benzoisoquinoline,

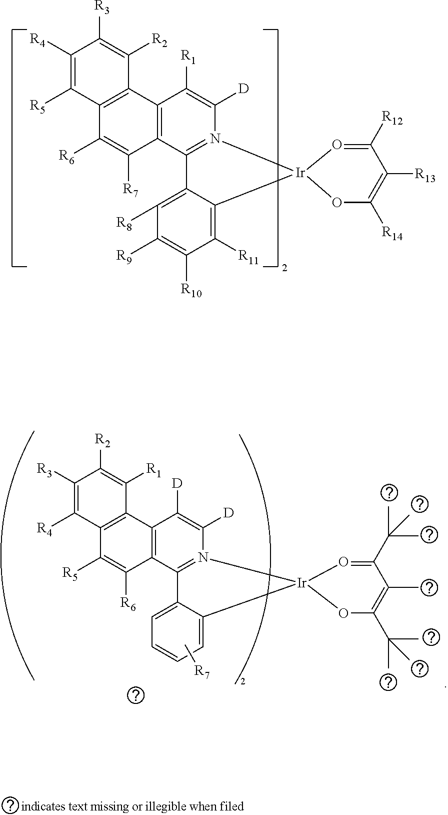

Although the device lifetime is slightly improved, this type of material has a relatively wide full width at half maximum, and both its color saturation and device light-emitting efficiency need to be improved. Therefore, the applicant still hopes to further develop a novel material that can improve the performance of the organic electroluminescent device.

### SUMMARY

The present disclosure has been completed in order to solve the above-mentioned problems, and an objective of the present disclosure is to provide a high-performance organic electroluminescent device and a novel material capable of realizing such an organic electroluminescent device.

The present applicant has repeatedly conducted intensive studies so as to achieve the aforementioned objective and has found that a high-performance organic electroluminescent device can be obtained by using a metal complex comprising a structure represented by the following formula (1) as a ligand.

One of the objectives of the present disclosure is to provide a metal complex having the advantages of a low evaporation temperature, high photochemical and electrochemical stability, a narrow full width at half maximum, a high color saturation, a high light-emitting efficiency, a long service life of device, and the like, and can be used in an organic electroluminescent device. Especially it can be used as a red light-emitting dopant, and has the potential to be applied in the OLED industry.

A metal complex has a general formula of Ir(La)(Lb)(Lc), and includes a structure represented by formula (1),

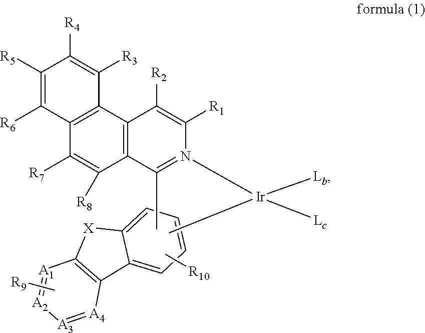

wherein

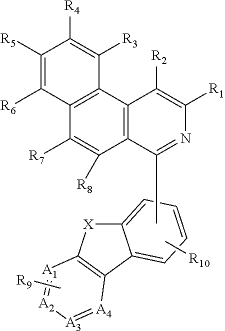

is a ligand La;
wherein X is independently selected from O, S, or Se;
wherein one of A₁ to A₄ is CR₉, the other three of A₁ to A₄ are independently CR₀ or N, and at least one of the other three of A₁ to A₄ is N;
wherein R₀ and R₁-R₁₀ are independently selected from the group consisting of hydrogen, deuterium, halogen, a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, a substituted or unsubstituted heterocycloalkyl with 3-20 ring-forming carbon atoms, a substituted or unsubstituted C3-C30 alkylsilyl, a substituted or unsubstituted C1-C10 alkoxy, a substituted or unsubstituted C7-C30 aralkyl, a substituted or unsubstituted C6-C30 aryloxy, a substituted or unsubstituted C2-C20 alkenyl, a substituted or unsubstituted C2-C20 alkynyl, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano and phosphino;
wherein the substitution in R₀ and R₁-R₁₀ refers to being substituted with deuterium, F, Cl, Br, C1-C4 alkyl, C1-C4 alkoxy, C3-C6 cycloalkyl, C1-C4 alkyl substituted amino, C6-C10 aryl, C1-C4 alkyl substituted C6-C10 aryl, cyano, isocyano or phosphino;
wherein the heteroatom in the heteroalkyl, heterocycloalkyl or heteroaryl is at least one of S, O and N;
wherein each of Lb and Lc is a monoanionic bidentate ligand, and two of La, Lb and Lc are arbitrarily connected to each other to form a multidentate ligand, or La, Lb and Lc are connected through a single group; and
wherein at least two of La, Lb and Lc are the same.

In some embodiments, in accordance with the metal complex of the present disclosure, La has the following structure:

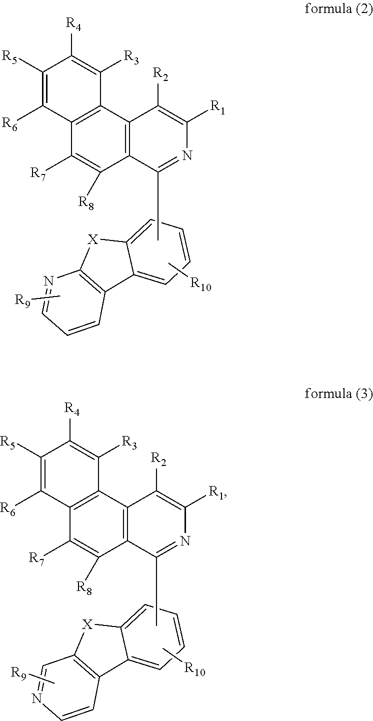

wherein R₁-R₁₀ are as defined above, and R₁₀ is not hydrogen.

In some embodiments, in accordance with the metal complex of the present disclosure, Lb has a structure represented by formula (4):

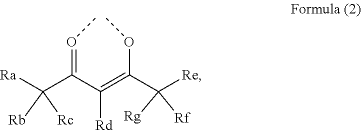

wherein a dotted line represents a position of connection to the metal iridium Ir;
wherein Rₐ-R_{g} are independently selected from the group consisting of hydrogen, deuterium, halogen, a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, and a substituted or unsubstituted heterocycloalkyl with 3-20 ring-forming carbon atoms, or two of Rₐ, R_{b} and R_{c} are connected to each other to form an aliphatic cyclic structure, and two of Rₑ, R_{f} and R_{g} are connected to each other to form an aliphatic cyclic structure; and
wherein the substitution in Rₐ-R_{g} refers to being substituted with deuterium, F, Cl, Br, C1-C4 alkyl, C1-C4 alkoxy, C3-C6 cycloalkyl, and C1-C4 alkyl substituted amino, cyano, isocyano, or phosphino.

As a preferred metal complex, Lc and La have the same structure and are formed a (La)₂Ir(Lb) structure.

Rₐ, R_{b}, and R_{c} are the same as Rₑ, R_{f}, and R_{g}, respectively.

Rₐ, R_{b}, R_{c}, Rₑ, R_{f} and R_{g} are independently selected from the group consisting of hydrogen, deuterium, halogen, a substituted or unsubstituted alkyl with 1-10 main-chain carbon atoms, and a substituted or unsubstituted cycloalkyl with 3-20 ring-forming carbon atoms; or two of Rₐ, R_{b} and R_{c} are connected to each other to form an aliphatic cyclic structure, two of Rₑ, R_{f} and R_{g} are connected to each other to form an aliphatic cyclic structure, and R_{d} is selected from hydrogen, deuterium, halogen, and a substituted or unsubstituted alkyl with 1-10 main-chain carbon atoms; wherein the substitution in Rₐ-R_{g} refers to being substituted with deuterium, F, Cl, Br, C1-C4 alkyl, or C3-C6 cycloalkyl.

In some embodiments, in accordance with the metal complex of the present disclosure, La has the following structure:

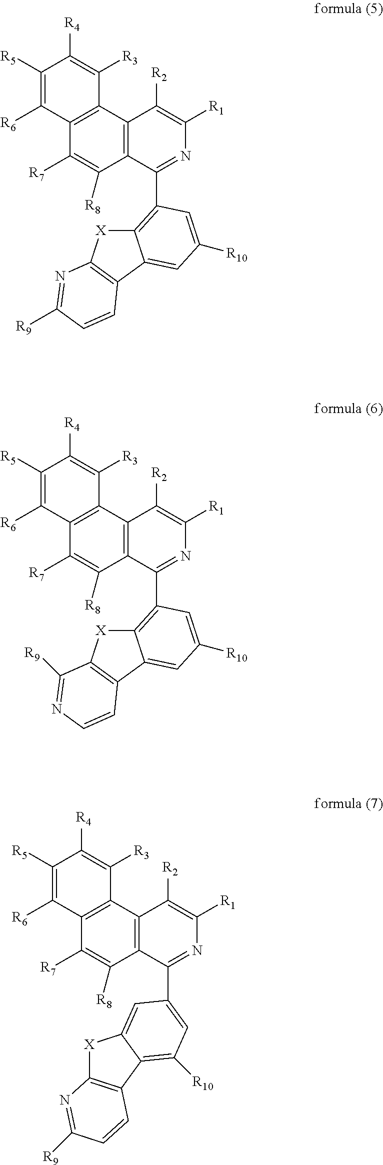

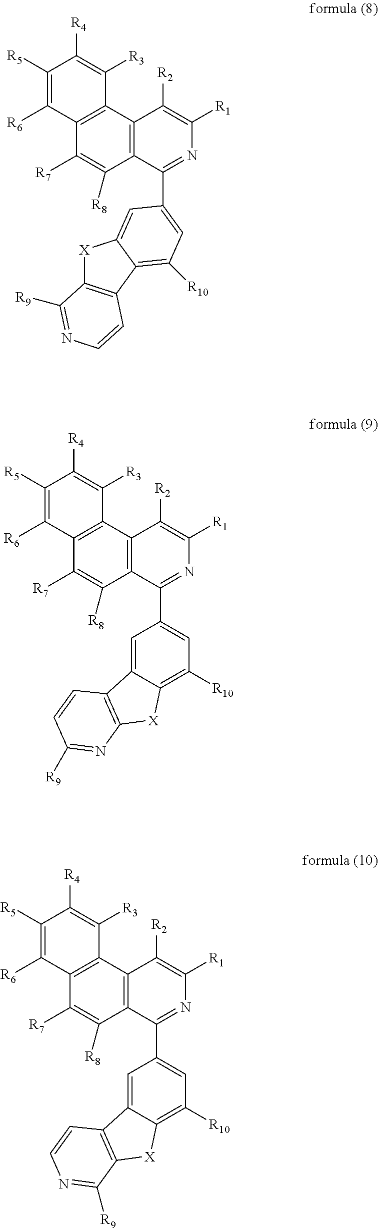

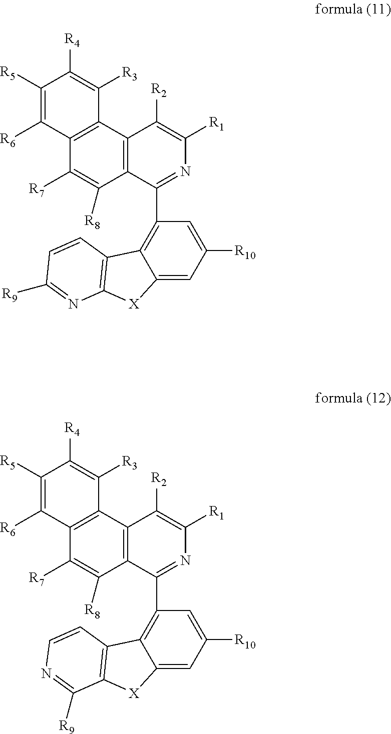

In some embodiments, in accordance with the metal complex of the present disclosure, at least one of R₁-R₉ is not hydrogen, and R₁₀ is a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, or a substituted or unsubstituted heterocycloalkyl with 3-20 ring-forming carbon atoms.

Preferably, R₉ and R₁₀ are independently a substituted or unsubstituted alkyl with a number of carbon atoms in the main chain of no more than 4, or a substituted or unsubstituted cycloalkyl with a number of ring-forming carbon atoms of no more than 6.

In some embodiments, in accordance with a preferred metal complex of the present disclosure, R₁-R₈ are independently selected from the group consisting of hydrogen, deuterium, halogen, a substituted or unsubstituted alkyl with 1-10 main-chain carbon atoms, a substituted or unsubstituted cycloalkyl with 3-10 ring-forming carbon atoms, a substituted or unsubstituted C6-C20 aryl, a substituted or unsubstituted C3-C20 heteroaryl, cyano and isocyano; wherein the substitution in R₁-R₈ refers to being substituted with deuterium, F, Cl, Br, C1-C4 alkyl, cyano or isocyano.

In some embodiments, in accordance with the metal complex of the present disclosure, X is an oxygen atom O.

In some embodiments, in accordance with the metal complex of the present disclosure, one of R₁-R₈ is an electron-withdrawing group, such as F, F substituted C1-C4 alkyl, cyano, or pyridyl, and the rest of R₁-R₈ are hydrogen or each contain one or two deuteriums.

In some embodiments, in accordance with the metal complex of the present disclosure, La is independently selected from one of the following structural formulae or corresponding partially or completely deuterated compounds thereof or corresponding partially or completely fluorinated compounds thereof:

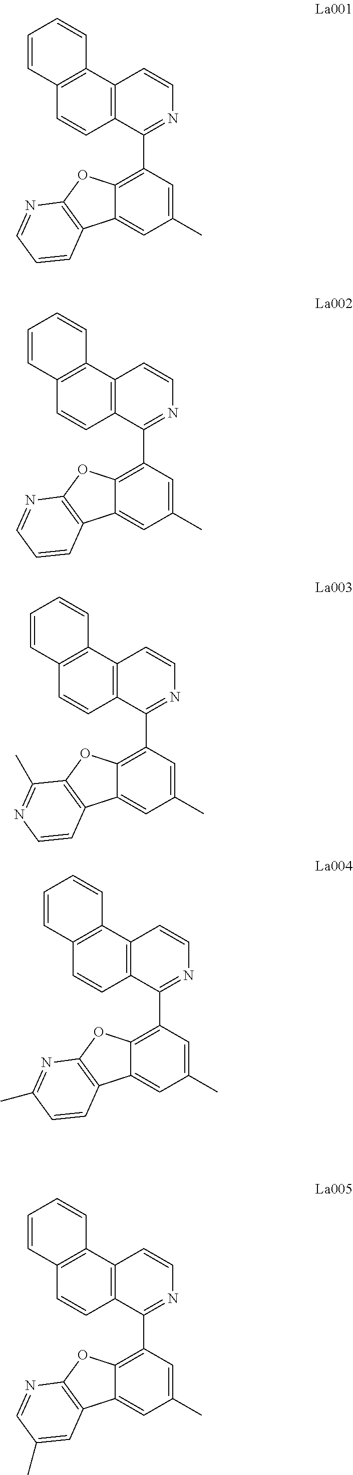

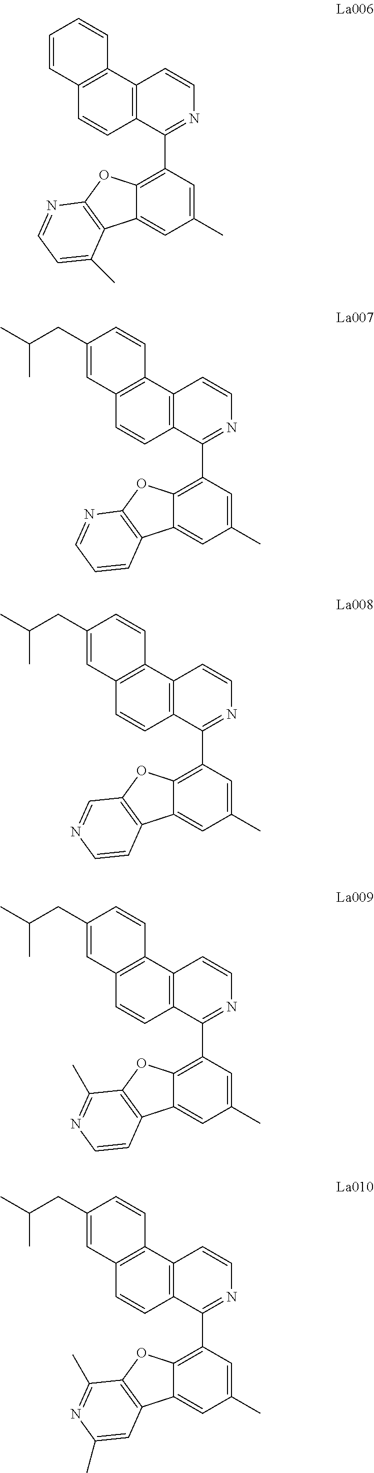

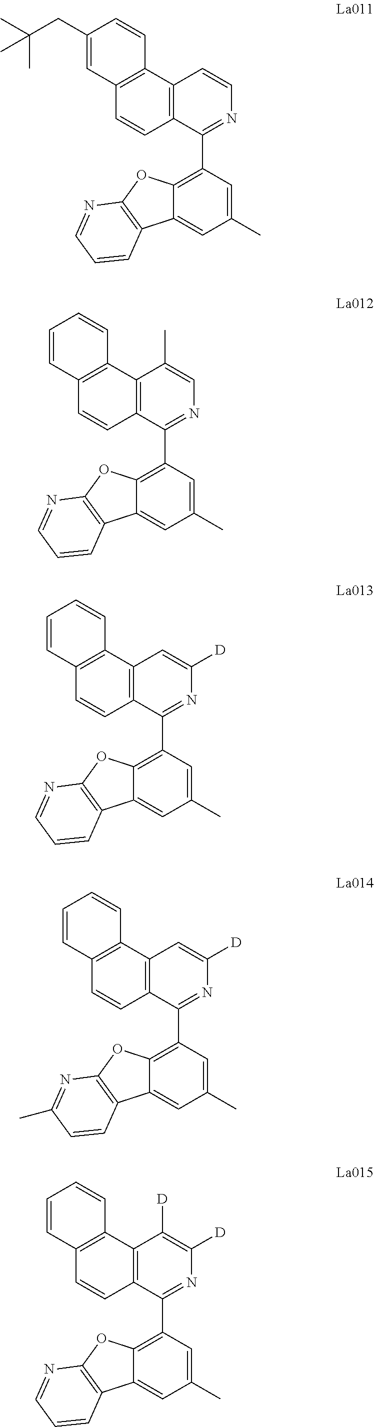

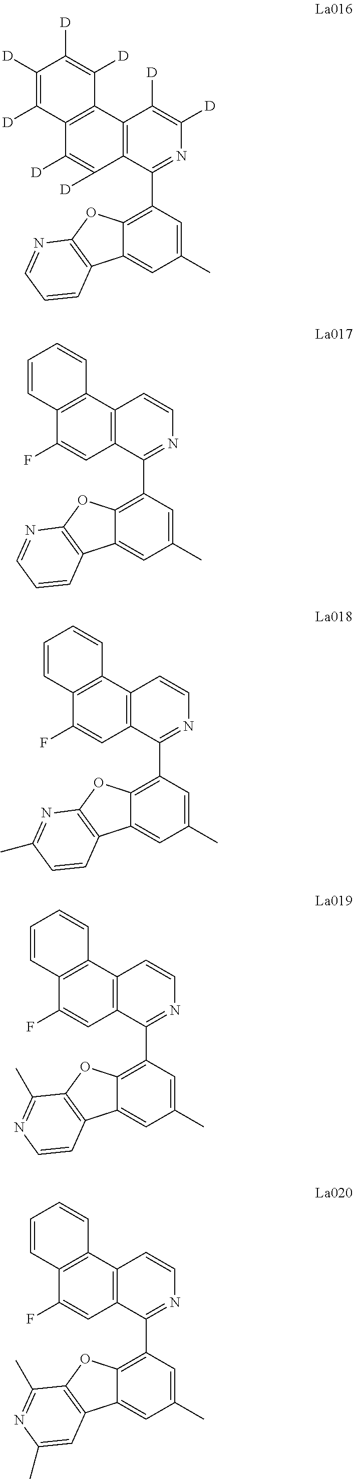

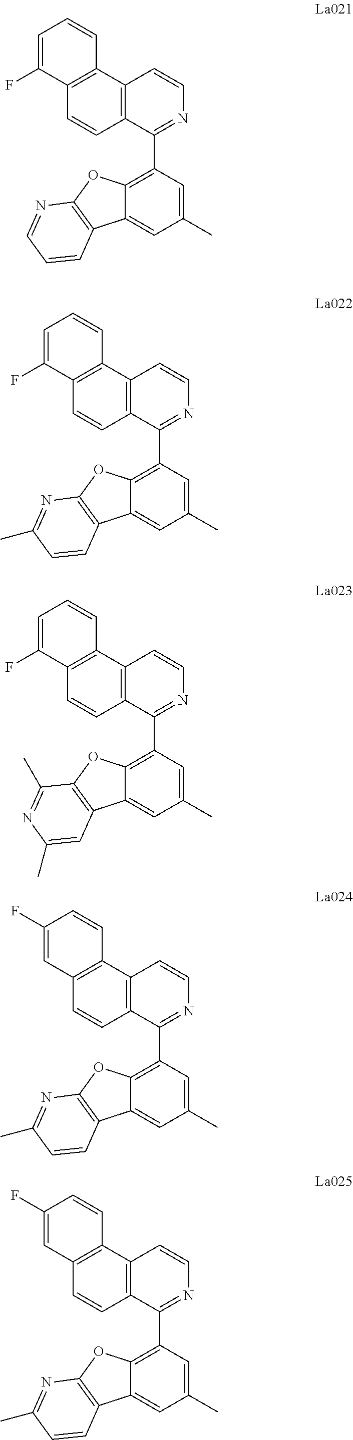

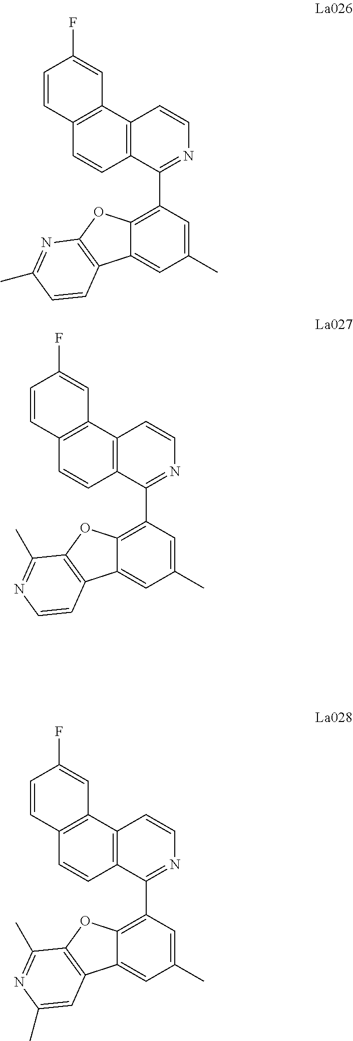

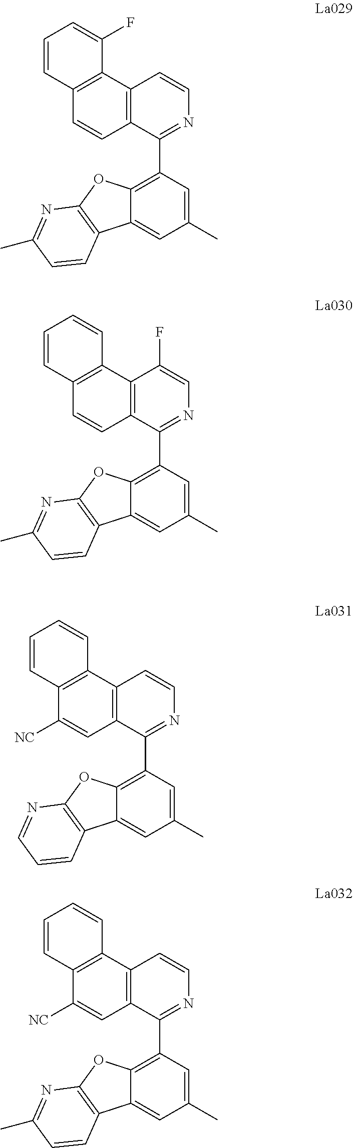

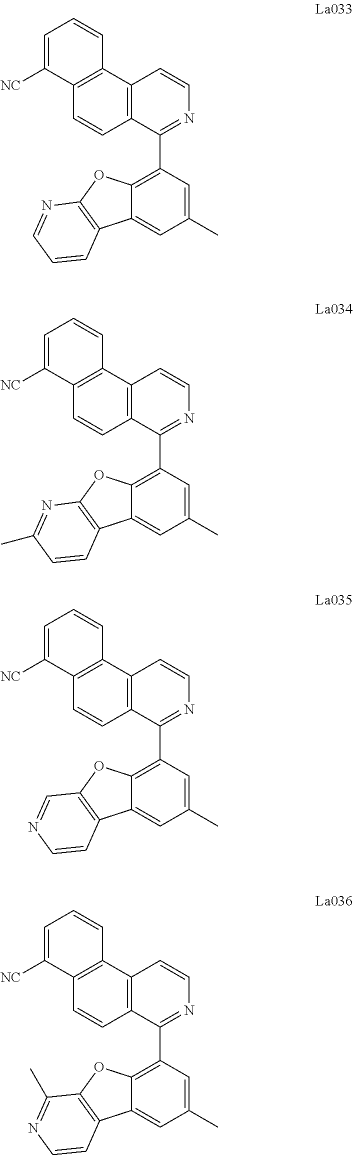

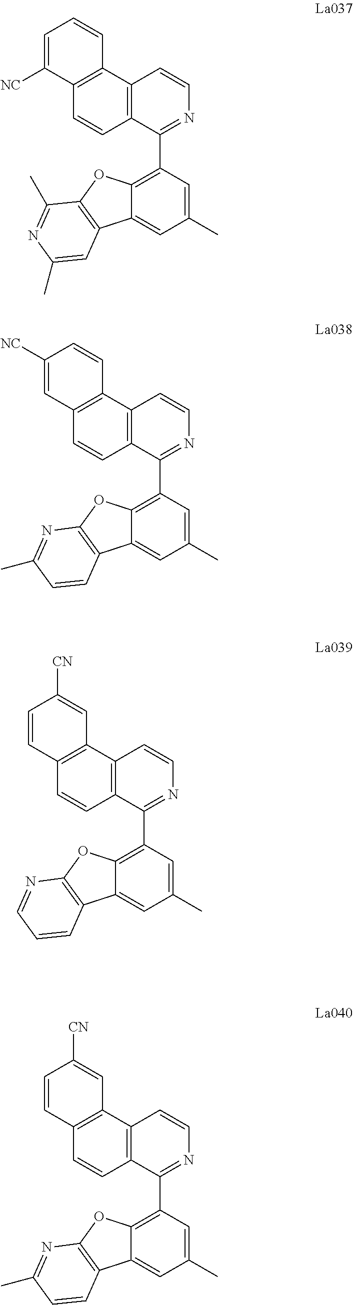

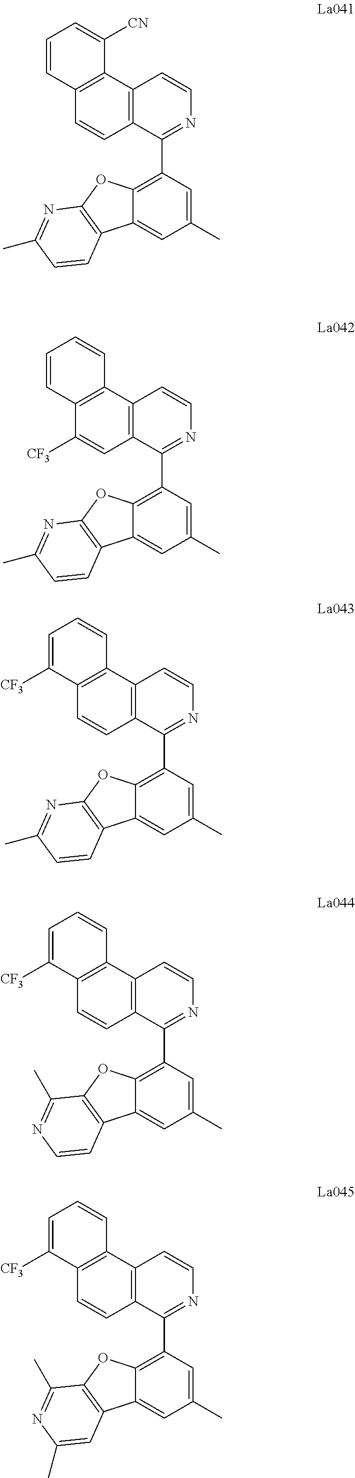

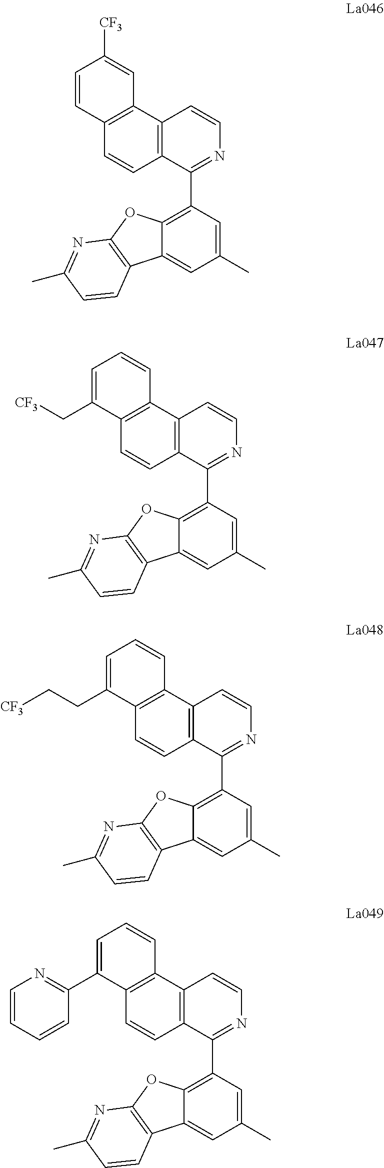

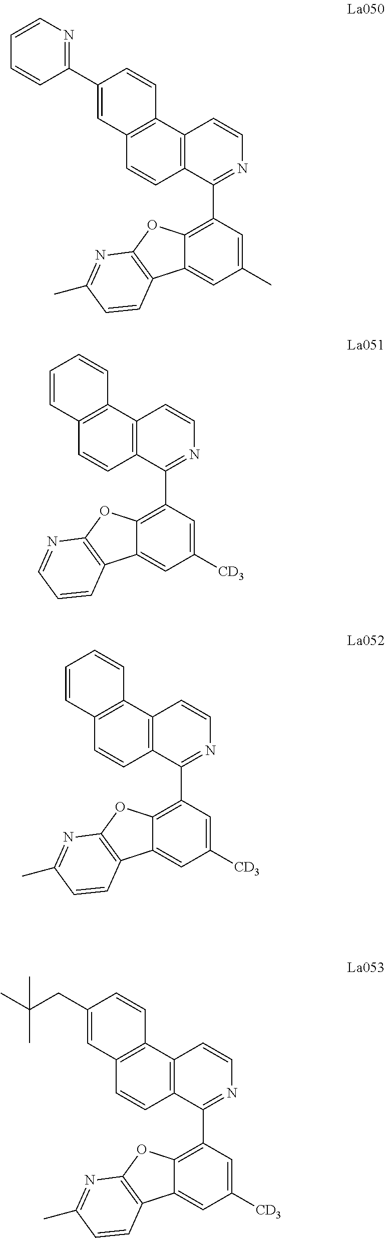

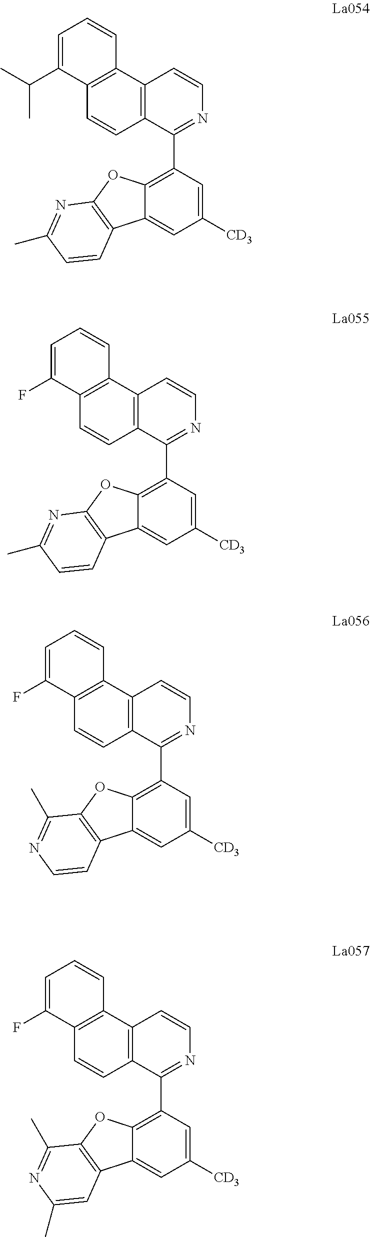 [SMILES: [2H]C([2H])([2H])c1cc(-c2nccc3c2ccc2c(C(C)C)cccc23)c2oc3nc(C)ccc3c2c1 ; [2H]C([2H])([2H])c1cc(-c2nccc3c2ccc2c(F)cccc23)c2oc3nc(C)ccc3c2c1 ; [2H]C([2H])([2H])c1cc(-c2nccc3c2ccc2c(F)cccc23)c2oc3c(C)nccc3c2c1 ; [2H]C([2H])([2H])c1cc(-c2nccc3c2ccc2c(F)cccc23)c2oc3c(C)nc(C)cc3c2c1]

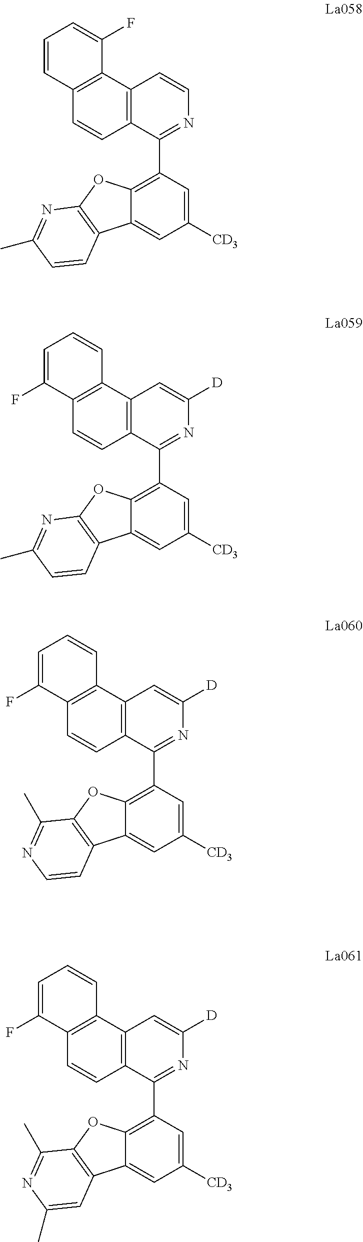 [SMILES: [2H]C([2H])([2H])c1cc(-c2nccc3c2ccc2cccc(F)c23)c2oc3nc(C)ccc3c2c1 ; [2H]c1cc2c(ccc3c(F)cccc32)c(-c2cc(C([2H])([2H])[2H])cc3c2oc2nc(C)ccc23)n1 ; [2H]c1cc2c(ccc3c(F)cccc32)c(-c2cc(C([2H])([2H])[2H])cc3c2oc2c(C)nccc23)n1 ; [2H]c1cc2c(ccc3c(F)cccc32)c(-c2cc(C([2H])([2H])[2H])cc3c2oc2c(C)nc(C)cc23)n1]

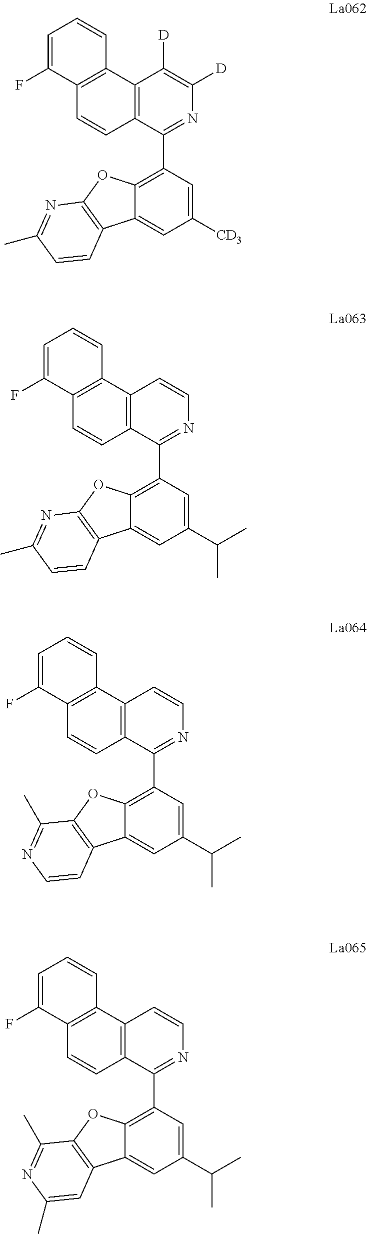 [SMILES: [2H]c1nc(-c2cc(C([2H])([2H])[2H])cc3c2oc2nc(C)ccc23)c2ccc3c(F)cccc3c2c1[2H] ; Cc1ccc2c(n1)oc1c(-c3nccc4c3ccc3c(F)cccc34)cc(C(C)C)cc12 ; Cc1nccc2c1oc1c(-c3nccc4c3ccc3c(F)cccc34)cc(C(C)C)cc12 ; Cc1cc2c(oc3c(-c4nccc5c4ccc4c(F)cccc45)cc(C(C)C)cc32)c(C)n1]

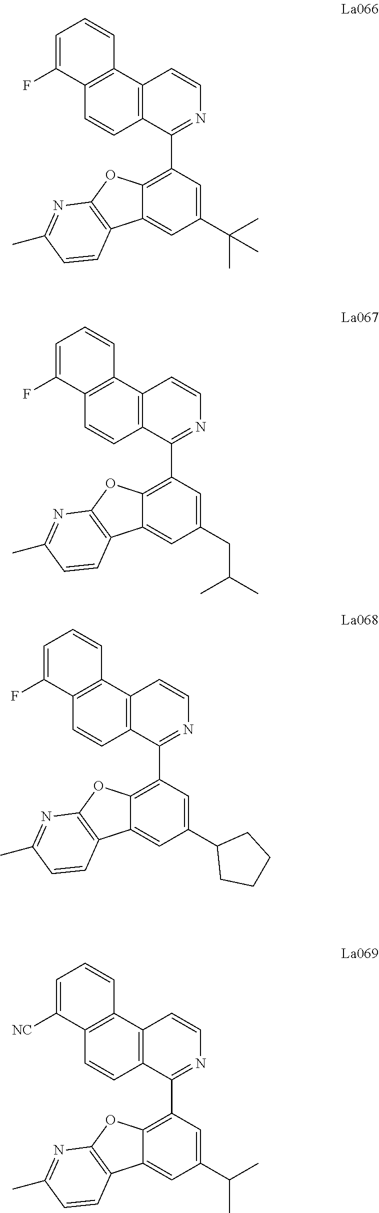

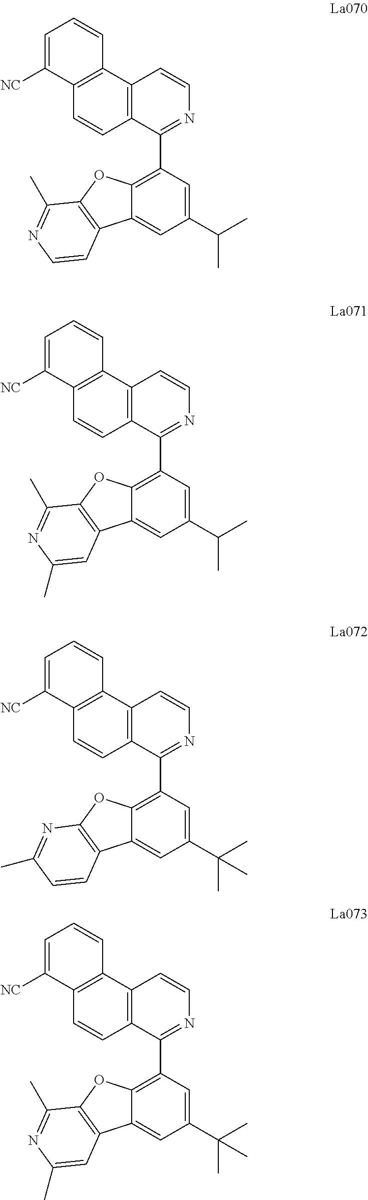

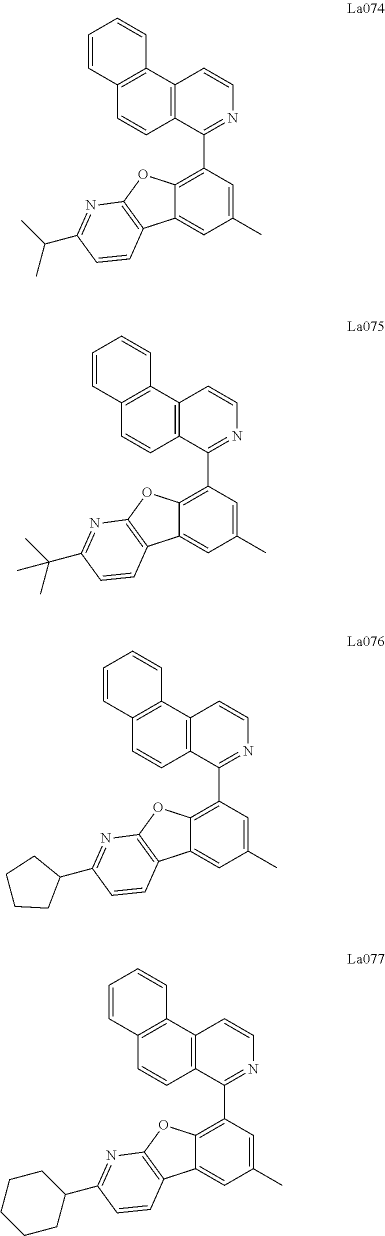

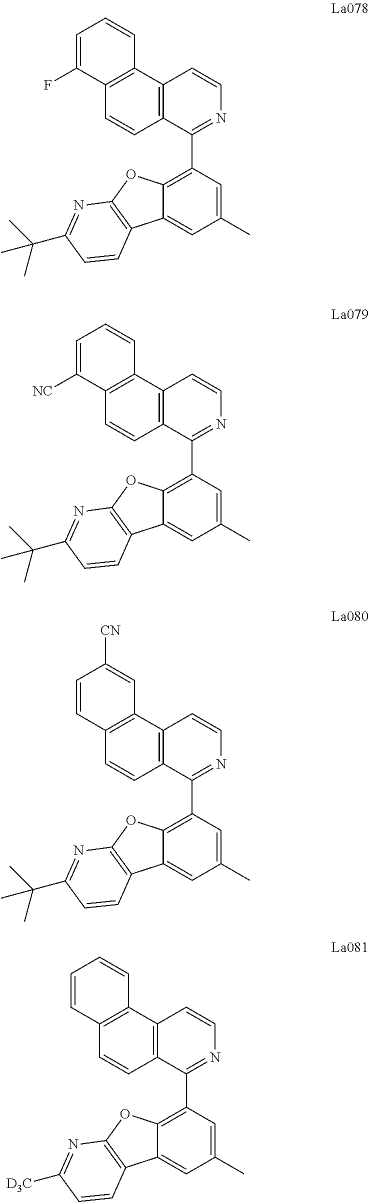

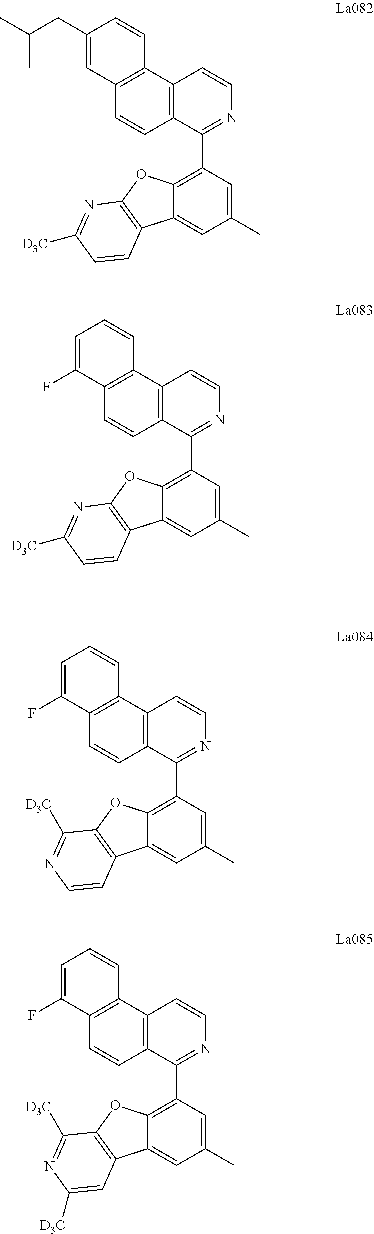 [SMILES: [2H]C([2H])([2H])c1ccc2c(n1)oc1c(-c3nccc4c3ccc3cc(CC(C)C)ccc34)cc(C)cc12 ; [2H]C([2H])([2H])c1ccc2c(n1)oc1c(-c3nccc4c3ccc3c(F)cccc34)cc(C)cc12 ; [2H]C([2H])([2H])c1nccc2c1oc1c(-c3nccc4c3ccc3c(F)cccc34)cc(C)cc12 ; [2H]C([2H])([2H])c1cc2c(oc3c(-c4nccc5c4ccc4c(F)cccc45)cc(C)cc32)c(C([2H])([2H])[2H])n1]

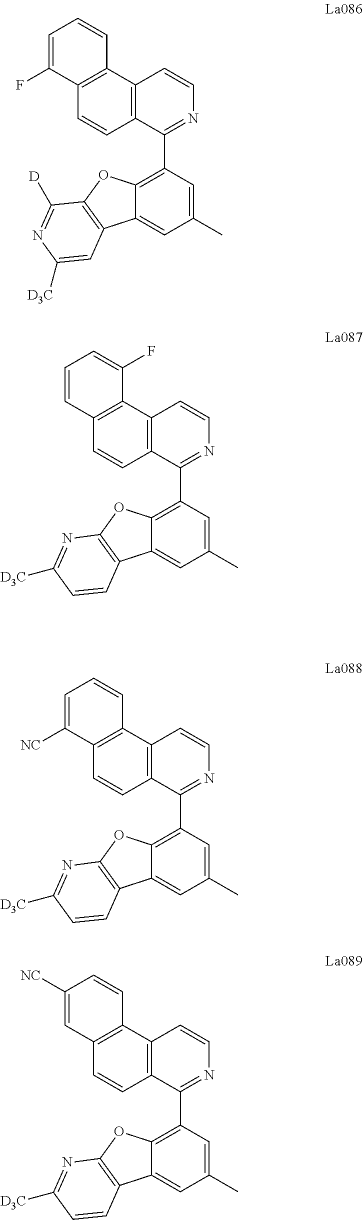 [SMILES: [2H]c1nc(C([2H])([2H])[2H])cc2c1oc1c(-c3nccc4c3ccc3c(F)cccc34)cc(C)cc12 ; [2H]C([2H])([2H])c1ccc2c(n1)oc1c(-c3nccc4c3ccc3cccc(F)c34)cc(C)cc12 ; [2H]C([2H])([2H])c1ccc2c(n1)oc1c(-c3nccc4c3ccc3c(C#N)cccc34)cc(C)cc12 ; [2H]C([2H])([2H])c1ccc2c(n1)oc1c(-c3nccc4c3ccc3cc(C#N)ccc34)cc(C)cc12]

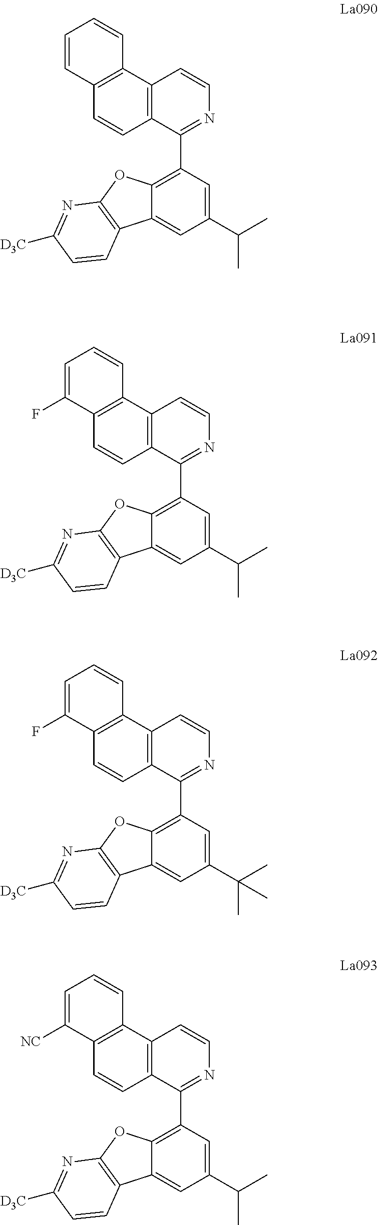 [SMILES: [2H]C([2H])([2H])c1ccc2c(n1)oc1c(-c3nccc4c3ccc3ccccc34)cc(C(C)C)cc12 ; [2H]C([2H])([2H])c1ccc2c(n1)oc1c(-c3nccc4c3ccc3c(F)cccc34)cc(C(C)C)cc12 ; [2H]C([2H])([2H])c1ccc2c(n1)oc1c(-c3nccc4c3ccc3c(F)cccc34)cc(C(C)(C)C)cc12 ; [2H]C([2H])([2H])c1ccc2c(n1)oc1c(-c3nccc4c3ccc3c(C#N)cccc34)cc(C(C)C)cc12]

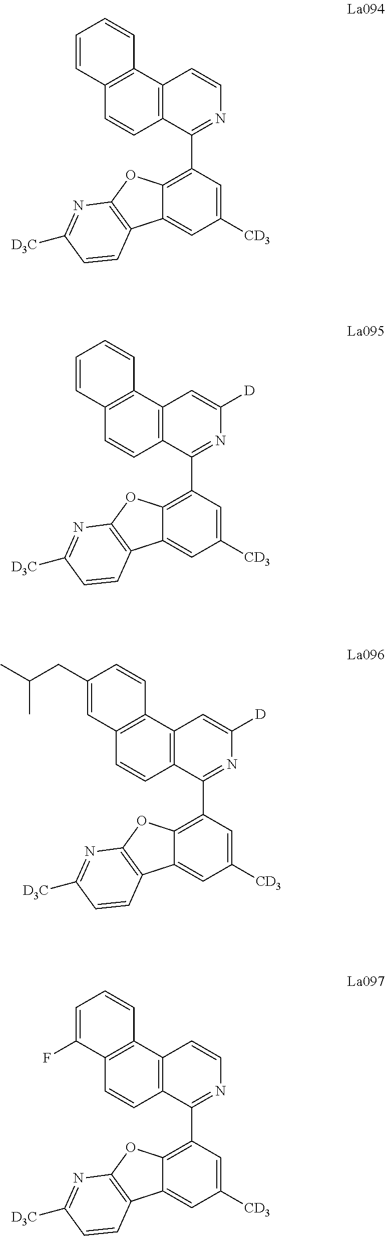 [SMILES: [2H]C([2H])([2H])c1cc(-c2nccc3c2ccc2ccccc23)c2oc3nc(C([2H])([2H])[2H])ccc3c2c1 ; [2H]c1cc2c(ccc3ccccc32)c(-c2cc(C([2H])([2H])[2H])cc3c2oc2nc(C([2H])([2H])[2H])ccc23)n1 ; [2H]c1cc2c(ccc3cc(CC(C)C)ccc32)c(-c2cc(C([2H])([2H])[2H])cc3c2oc2nc(C([2H])([2H])[2H])ccc23)n1 ; [2H]C([2H])([2H])c1cc(-c2nccc3c2ccc2c(F)cccc23)c2oc3nc(C([2H])([2H])[2H])ccc3c2c1]

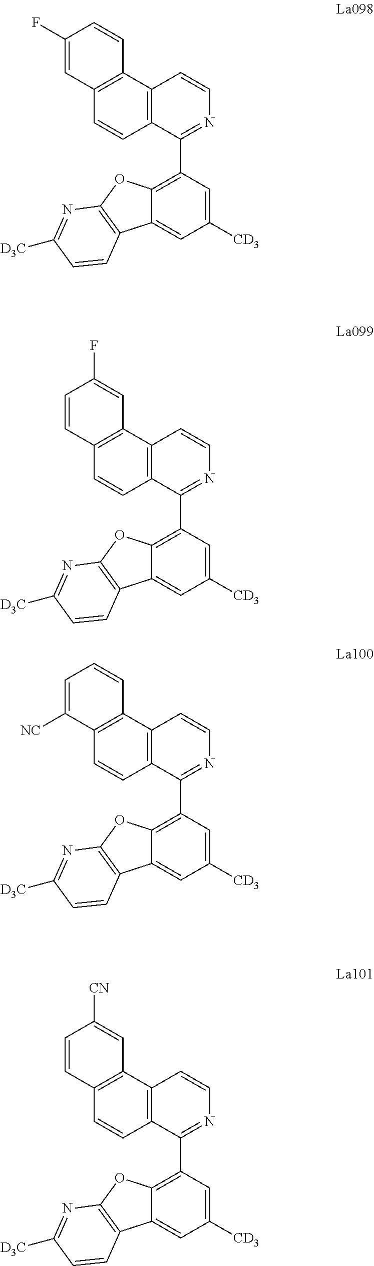

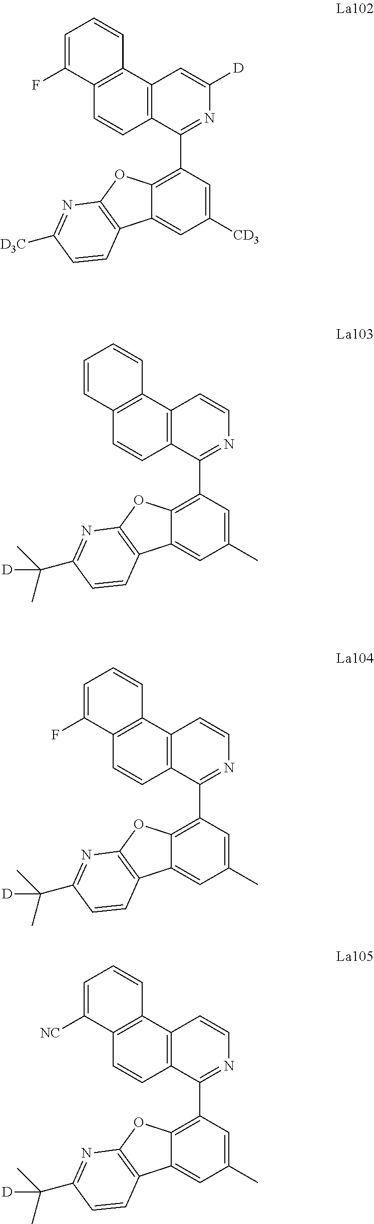 [SMILES: [2H]c1cc2c(ccc3c(F)cccc32)c(-c2cc(C([2H])([2H])[2H])cc3c2oc2nc(C([2H])([2H])[2H])ccc23)n1 ; [2H]C(C)(C)c1ccc2c(n1)oc1c(-c3nccc4c3ccc3ccccc34)cc(C)cc12 ; [2H]C(C)(C)c1ccc2c(n1)oc1c(-c3nccc4c3ccc3c(F)cccc34)cc(C)cc12 ; [2H]C(C)(C)c1ccc2c(n1)oc1c(-c3nccc4c3ccc3c(C#N)cccc34)cc(C)cc12]

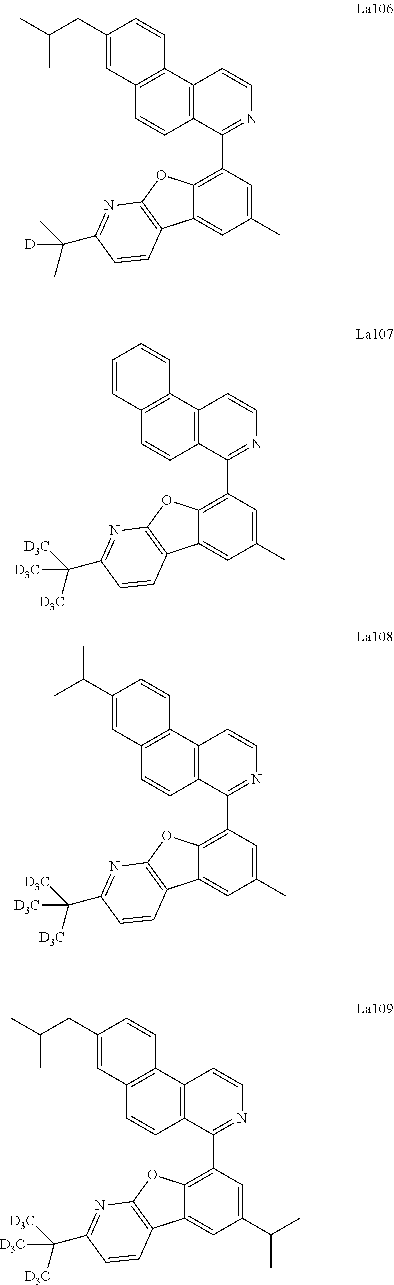

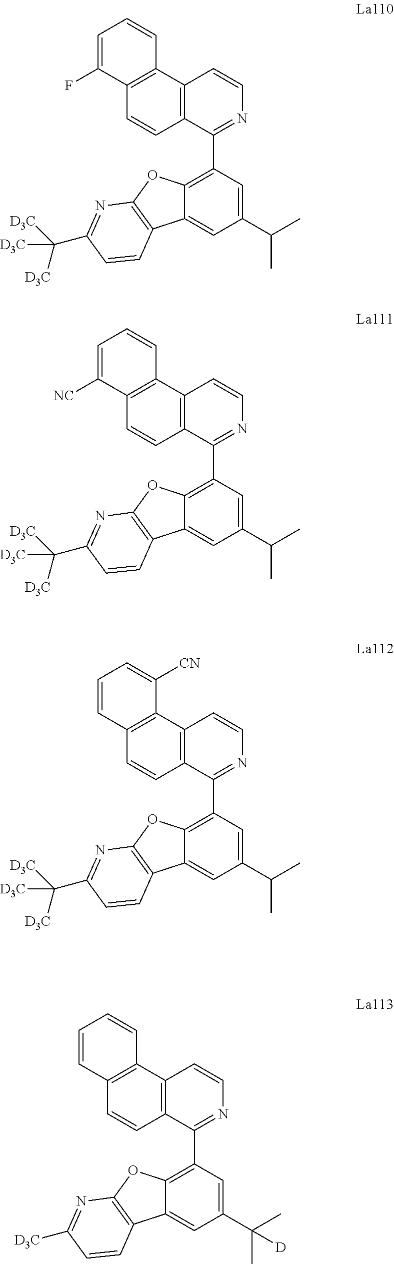 [SMILES: [2H]C([2H])([2H])C(c1ccc2c(n1)oc1c(-c3nccc4c3ccc3c(F)cccc34)cc(C(C)C)cc12)(C([2H])([2H])[2H])C([2H])([2H])[2H] ; [2H]C([2H])([2H])C(c1ccc2c(n1)oc1c(-c3nccc4c3ccc3c(C#N)cccc34)cc(C(C)C)cc12)(C([2H])([2H])[2H])C([2H])([2H])[2H] ; [2H]C([2H])([2H])C(c1ccc2c(n1)oc1c(-c3nccc4c3ccc3cccc(C#N)c34)cc(C(C)C)cc12)(C([2H])([2H])[2H])C([2H])([2H])[2H] ; [2H]C([2H])([2H])c1ccc2c(n1)oc1c(-c3nccc4c3ccc3ccccc34)cc(C([2H])(C)C)cc12]

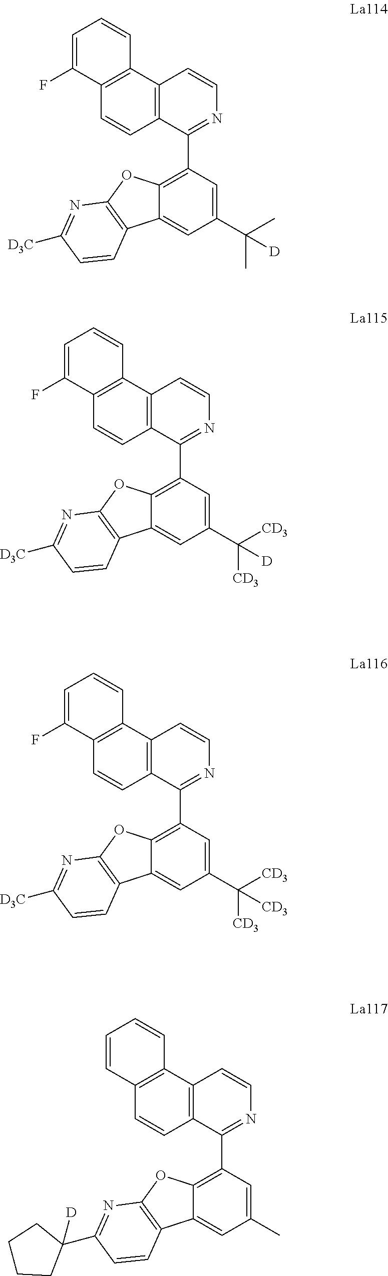 [SMILES: [2H]C([2H])([2H])c1ccc2c(n1)oc1c(-c3nccc4c3ccc3c(F)cccc34)cc(C([2H])(C)C)cc12 ; [2H]C([2H])([2H])c1ccc2c(n1)oc1c(-c3nccc4c3ccc3c(F)cccc34)cc(C([2H])(C([2H])([2H])[2H])C([2H])([2H])[2H])cc12 ; [2H]C([2H])([2H])c1ccc2c(n1)oc1c(-c3nccc4c3ccc3c(F)cccc34)cc(C(C([2H])([2H])[2H])(C([2H])([2H])[2H])C([2H])([2H])[2H])cc12 ; [2H]C1(c2ccc3c(n2)oc2c(-c4nccc5c4ccc4ccccc45)cc(C)cc23)CCCC1]

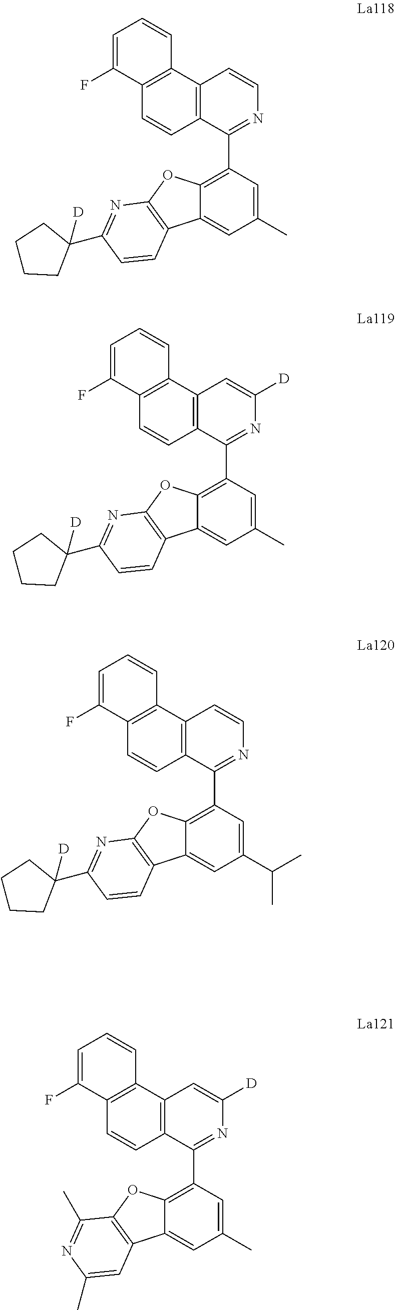 [SMILES: [2H]C1(c2ccc3c(n2)oc2c(-c4nccc5c4ccc4c(F)cccc45)cc(C)cc23)CCCC1 ; [2H]c1cc2c(ccc3c(F)cccc32)c(-c2cc(C)cc3c2oc2nc(C4([2H])CCCC4)ccc23)n1 ; [2H]C1(c2ccc3c(n2)oc2c(-c4nccc5c4ccc4c(F)cccc45)cc(C(C)C)cc23)CCCC1 ; [2H]c1cc2c(ccc3c(F)cccc32)c(-c2cc(C)cc3c2oc2c(C)nc(C)cc23)n1]

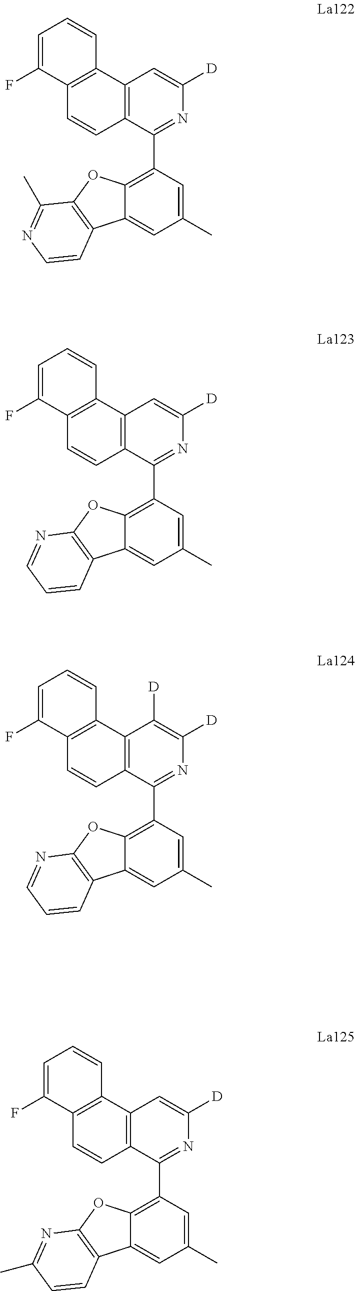 [SMILES: [2H]c1cc2c(ccc3c(F)cccc32)c(-c2cc(C)cc3c2oc2c(C)nccc23)n1 ; [2H]c1cc2c(ccc3c(F)cccc32)c(-c2cc(C)cc3c2oc2ncccc23)n1 ; [2H]c1nc(-c2cc(C)cc3c2oc2ncccc23)c2ccc3c(F)cccc3c2c1[2H] ; [2H]c1cc2c(ccc3c(F)cccc32)c(-c2cc(C)cc3c2oc2nc(C)ccc23)n1]

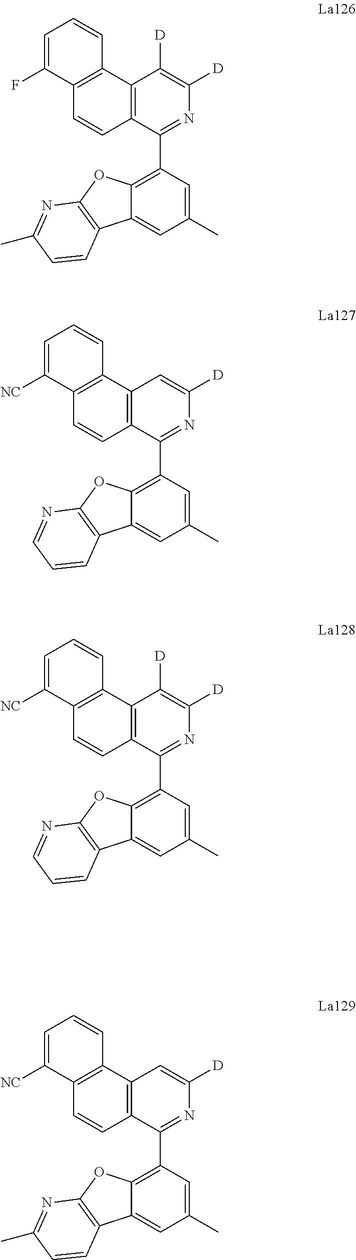 [SMILES: [2H]c1nc(-c2cc(C)cc3c2oc2nc(C)ccc23)c2ccc3c(F)cccc3c2c1[2H] ; [2H]c1cc2c(ccc3c(C#N)cccc32)c(-c2cc(C)cc3c2oc2ncccc23)n1 ; [2H]c1nc(-c2cc(C)cc3c2oc2ncccc23)c2ccc3c(C#N)cccc3c2c1[2H] ; [2H]c1cc2c(ccc3c(C#N)cccc32)c(-c2cc(C)cc3c2oc2nc(C)ccc23)n1]

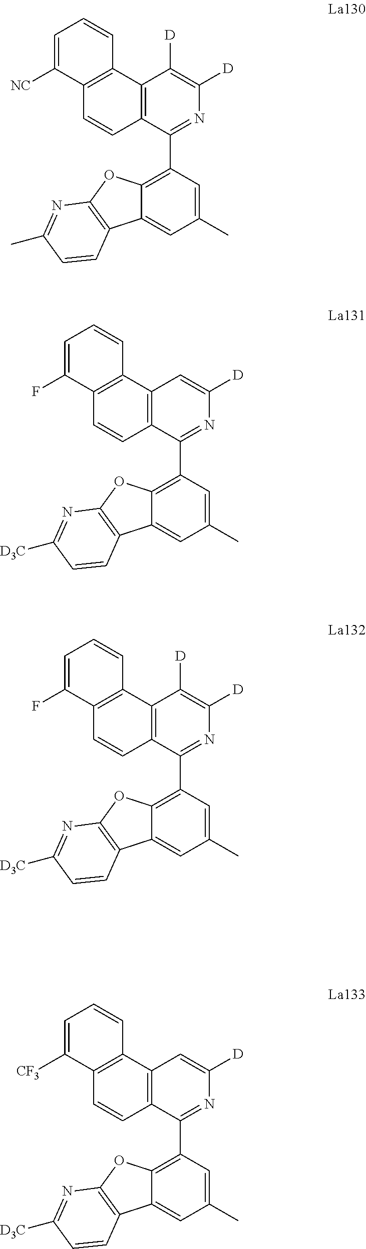 [SMILES: [2H]c1nc(-c2cc(C)cc3c2oc2nc(C)ccc23)c2ccc3c(C#N)cccc3c2c1[2H] ; [2H]c1cc2c(ccc3c(F)cccc32)c(-c2cc(C)cc3c2oc2nc(C([2H])([2H])[2H])ccc23)n1 ; [2H]c1nc(-c2cc(C)cc3c2oc2nc(C([2H])([2H])[2H])ccc23)c2ccc3c(F)cccc3c2c1[2H] ; [2H]c1cc2c(ccc3c(C(F)(F)F)cccc32)c(-c2cc(C)cc3c2oc2nc(C([2H])([2H])[2H])ccc23)n1]

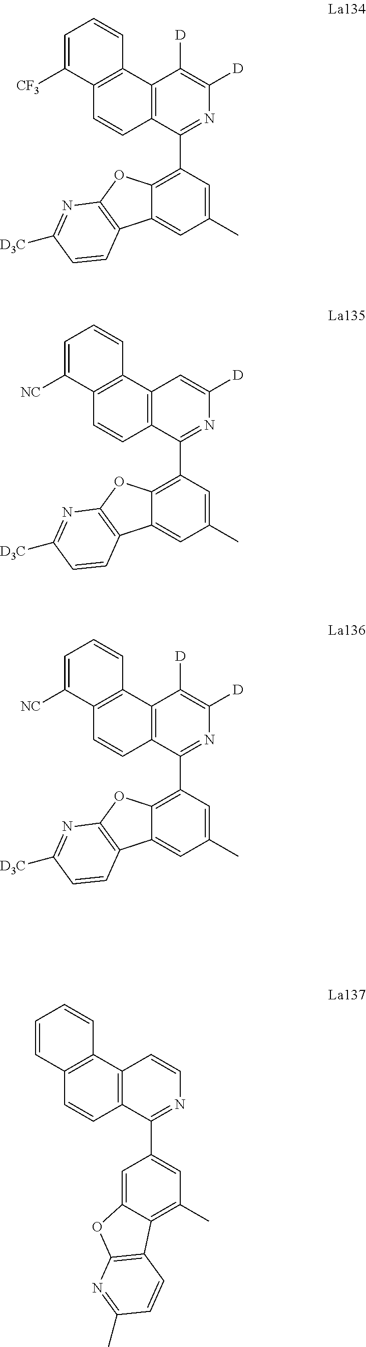 [SMILES: [2H]c1nc(-c2cc(C)cc3c2oc2nc(C([2H])([2H])[2H])ccc23)c2ccc3c(C(F)(F)F)cccc3c2c1[2H] ; [2H]c1cc2c(ccc3c(C#N)cccc32)c(-c2cc(C)cc3c2oc2nc(C([2H])([2H])[2H])ccc23)n1 ; [2H]c1nc(-c2cc(C)cc3c2oc2nc(C([2H])([2H])[2H])ccc23)c2ccc3c(C#N)cccc3c2c1[2H] ; Cc1ccc2c(n1)oc1cc(-c3nccc4c3ccc3ccccc34)cc(C)c12]

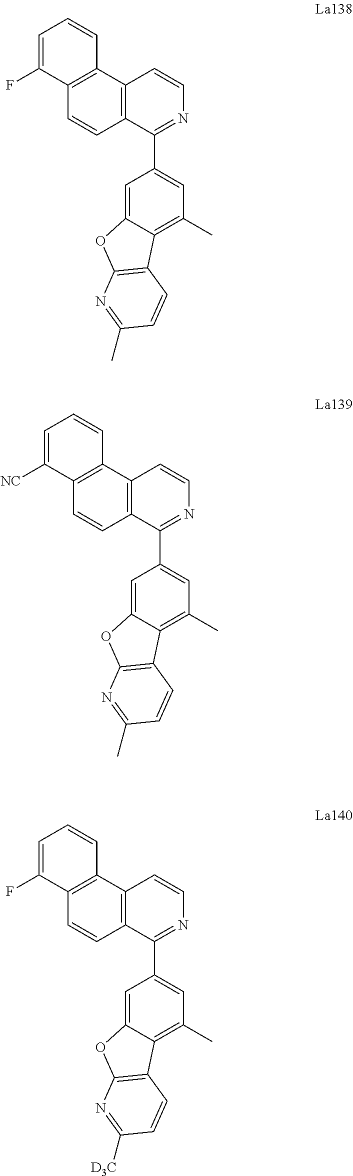 [SMILES: Cc1ccc2c(n1)oc1cc(-c3nccc4c3ccc3c(F)cccc34)cc(C)c12 ; Cc1ccc2c(n1)oc1cc(-c3nccc4c3ccc3c(C#N)cccc34)cc(C)c12 ; [2H]C([2H])([2H])c1ccc2c(n1)oc1cc(-c3nccc4c3ccc3c(F)cccc34)cc(C)c12]

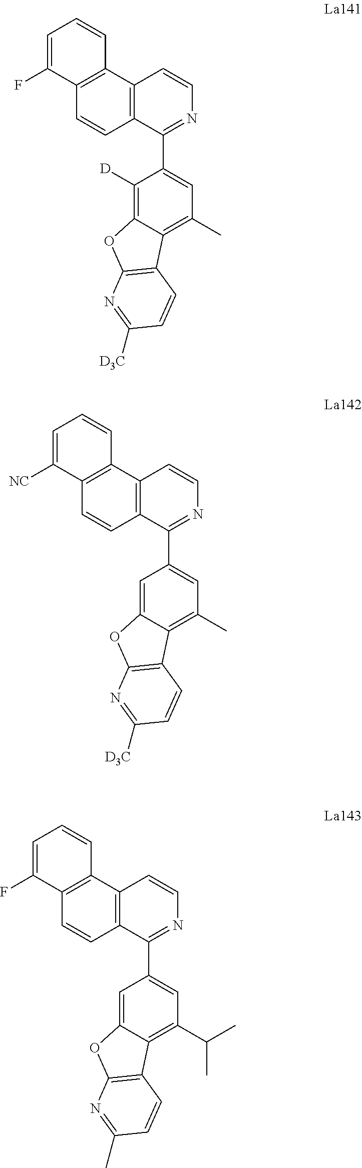 [SMILES: [2H]c1c(-c2nccc3c2ccc2c(F)cccc23)cc(C)c2c1oc1nc(C([2H])([2H])[2H])ccc12 ; [2H]C([2H])([2H])c1ccc2c(n1)oc1cc(-c3nccc4c3ccc3c(C#N)cccc34)cc(C)c12 ; Cc1ccc2c(n1)oc1cc(-c3nccc4c3ccc3c(F)cccc34)cc(C(C)C)c12]

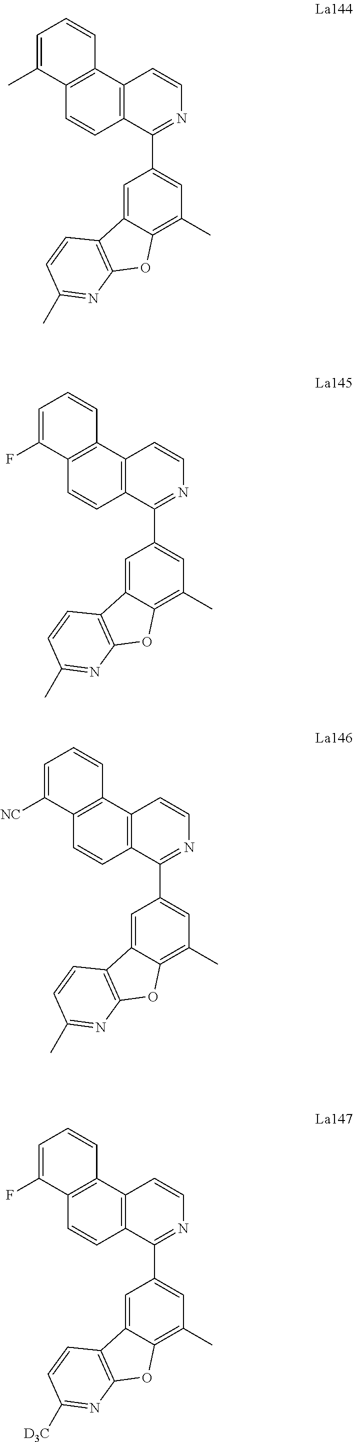

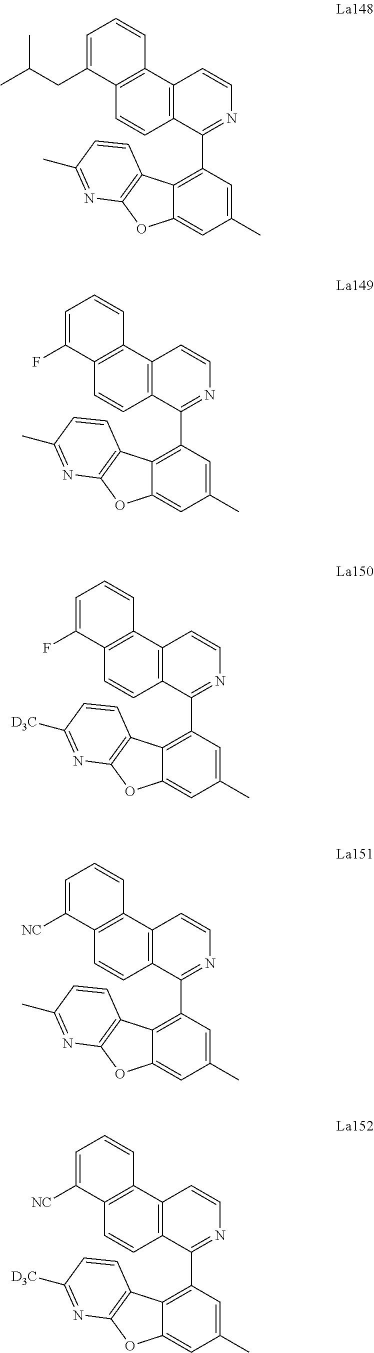

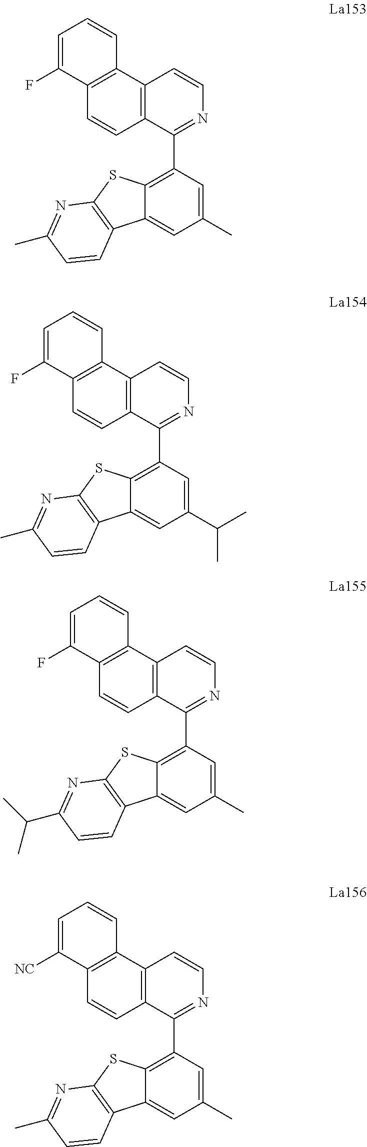

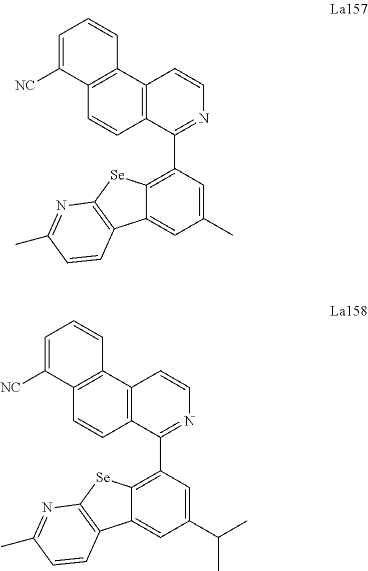

As a preferred metal complex, Lb is independently selected from one of the following structural formulas or corresponding partial or complete deuterated or fluorinated compounds thereof:

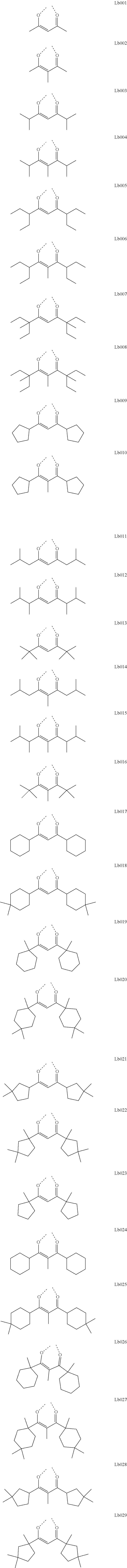

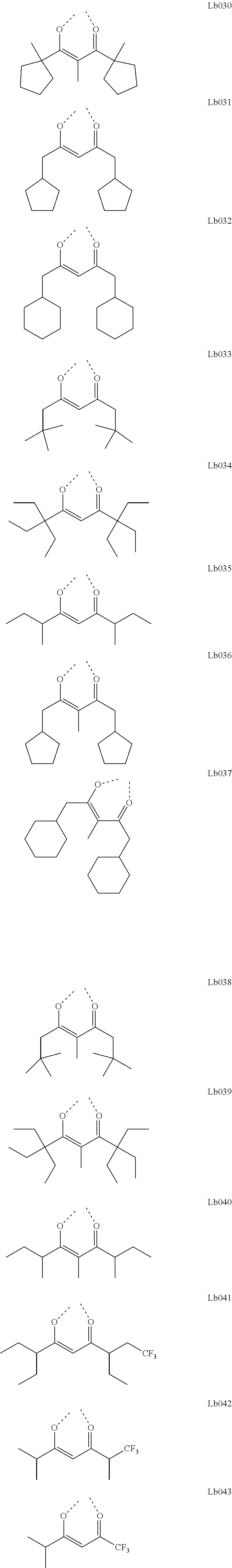

Another objective of the present disclosure is to provide an electroluminescent device comprising a cathode, an anode and an organic layer arranged between the cathode and the anode, wherein the organic layer includes the metal complex described above.

The organic layer is a light-emitting layer, and the metal complex serves as a red light-emitting doping material for the light-emitting layer;

The material of the present disclosure has the advantages of a low evaporation temperature, high photochemical and electrochemical stability, a narrow full width at half maximum, a high color saturation, a high light-emitting efficiency, and a long service life of device, and the like The material of the present disclosure, as a phosphorescent material, can convert triplet excited states into light, therefore it can improve the light-emitting efficiency of the organic electroluminescent device and reduce the energy consumption.

### BRIEF DESCRIPTION OF DRAWINGS

FIG. 1 shows the ¹HNMR spectrum of compound La034, and

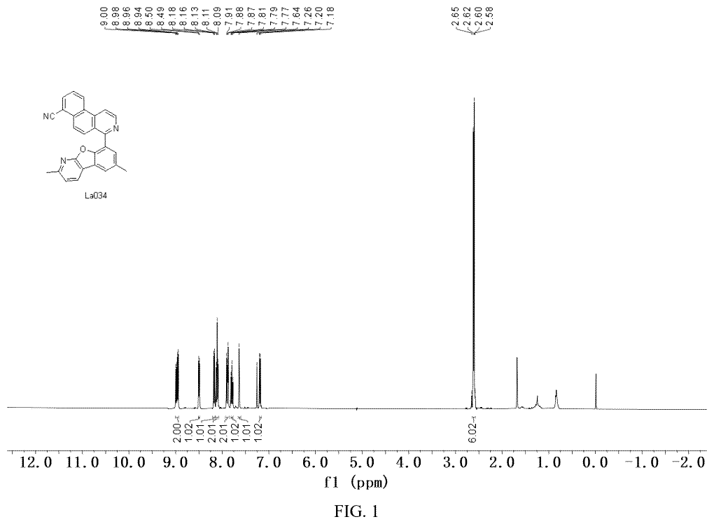

FIG. 2 shows the ¹HNMR spectrum of compound Ir(La034)₂(Lb007).

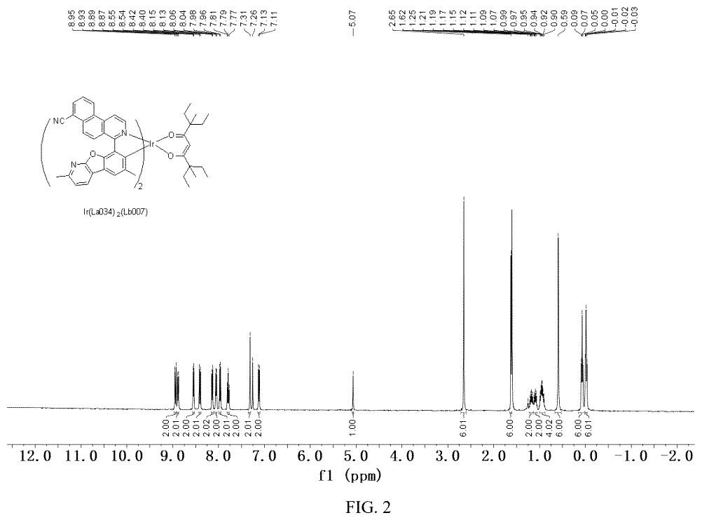

### DETAILED DESCRIPTION

A metal complex has a general formula of Ir(La)(Lb)(Lc), and includes a structure represented by formula (1),

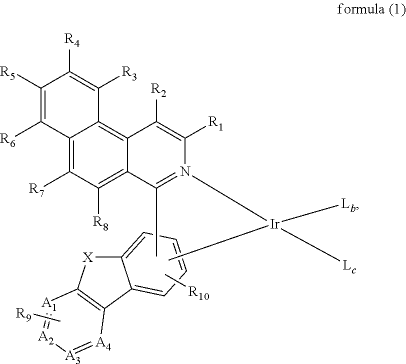

wherein

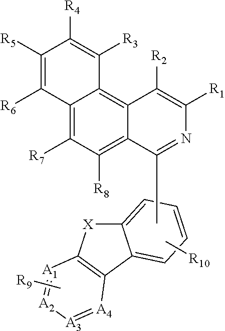

is a ligand La;
wherein X is independently selected from O, S, or Se;
wherein one of A₁ to A₄ is CR₉, the other three of A₁ to A₄ are independently CR₀ or N, and at least one of the other three of A₁ to A₄ is N;
wherein R₀ and R₁-R₁₀ are independently selected from the group consisting of hydrogen, deuterium, halogen, a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, a substituted or unsubstituted heterocycloalkyl with 3-20 ring-forming carbon atoms, a substituted or unsubstituted C3-C30 alkylsilyl, a substituted or unsubstituted C1-C10 alkoxy, a substituted or unsubstituted C7-C30 aralkyl, a substituted or unsubstituted C6-C30 aryloxy, a substituted or unsubstituted C2-C20 alkenyl, a substituted or unsubstituted C2-C20 alkynyl, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano and phosphino;
wherein the substitution is substituted with deuterium, F, Cl, Br, C1-C4 alkyl, C1-C4 alkoxy, C3-C6 cycloalkyl, C1-C4 alkyl substituted amino, C6-C10 aryl, C1-C4 alkyl substituted C6-C10 aryl, cyano, isocyano or phosphino;
wherein the heteroatom in the heteroalkyl, heterocycloalkyl or heteroaryl is at least one of S, O and N;
wherein each of Lb and Lc is a monoanionic bidentate ligand, and two of La, Lb and Lc are arbitrarily connected to each other to form a multidentate ligand, or La, Lb and Lc are connected through a single group; and
wherein at least two of La, Lb and Lc are the same.

In some embodiments, in accordance with the metal complex of the present disclosure, La has the following structure:

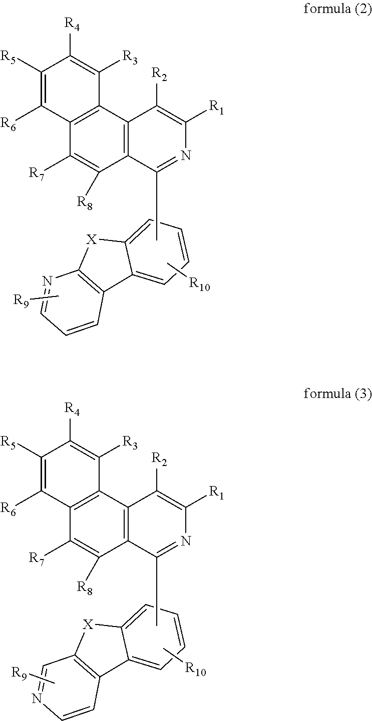

wherein R₁-R₉ are as defined above, and R₁₀ is independently a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, or a substituted or unsubstituted heterocycloalkyl with 3-20 ring-forming carbon atoms.

In some embodiments, in accordance with the metal complex of the present disclosure, Lb has a structure represented by formula (4):

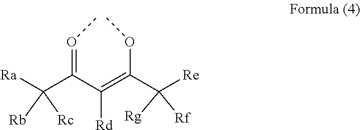

wherein a dotted line represents a position of connection to the metal iridium Ir;
wherein Rₐ-R_{g} are independently selected from the group consisting of hydrogen, deuterium, halogen, a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, and a substituted or unsubstituted heterocycloalkyl with 3-20 ring-forming carbon atoms; or two of Rₐ, R_{b} and R_{c} are connected to each other to form an aliphatic cyclic structure, and two of Rₑ, R_{f} and R_{g} are connected to each other to form an aliphatic cyclic structure; wherein the substitution is substituted with deuterium, F, Cl, Br, C1-C4 alkyl, C1-C4 alkoxy, C3-C6 cycloalkyl, and C1-C4 alkyl substituted amino, cyano, isocyano, or phosphino.

In some embodiments, in accordance with the metal complex of the present disclosure, Lc and La have the same structure and are formed a (La)₂Ir(Lb) structure.

Rₐ, R_{b}, and R_{c} are the same as Rₑ, R_{f}, and R_{g}, respectively.

Rₐ, R_{b}, R_{c}, Rₑ, R_{f} and R_{g} are independently selected from the group consisting of hydrogen, deuterium, halogen, a substituted or unsubstituted alkyl with 1-10 main-chain carbon atoms, and a substituted or unsubstituted cycloalkyl with 3-20 ring-forming carbon atoms; or two of Rₐ, R_{b} and R_{c} are connected to each other to form an aliphatic cyclic structure, and two of Rₑ, R_{f} and R_{g} are connected to each other to form an aliphatic cyclic structure; wherein the substitution is substituted with deuterium, F, Cl, Br, C1-C4 alkyl, and C3-C6 cycloalkyl; and R_{d} is selected from hydrogen, deuterium, halogen, or a substituted or unsubstituted alkyl with 1-10 main-chain carbon atoms.

In some embodiments, in accordance with the metal complex of the present disclosure, La has the following structure:

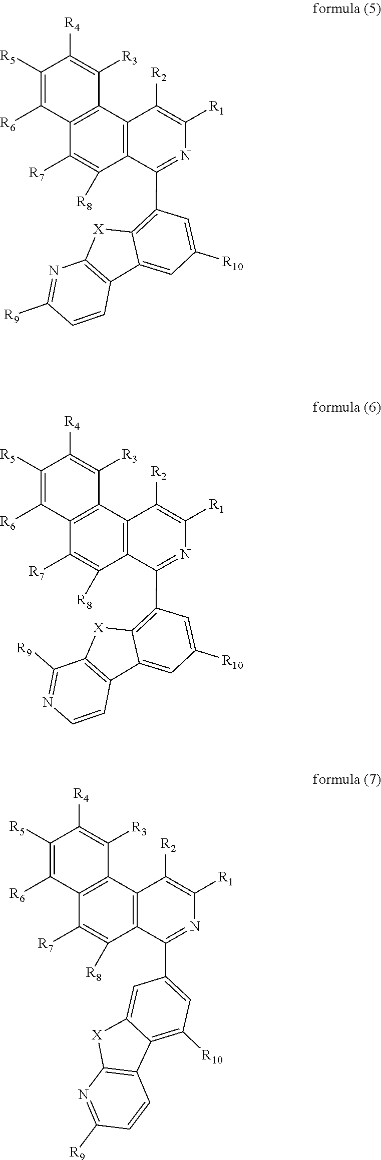

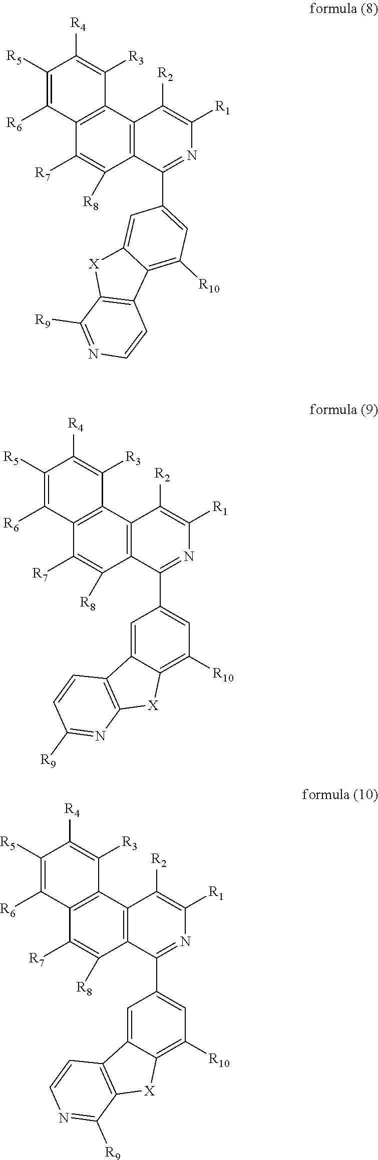

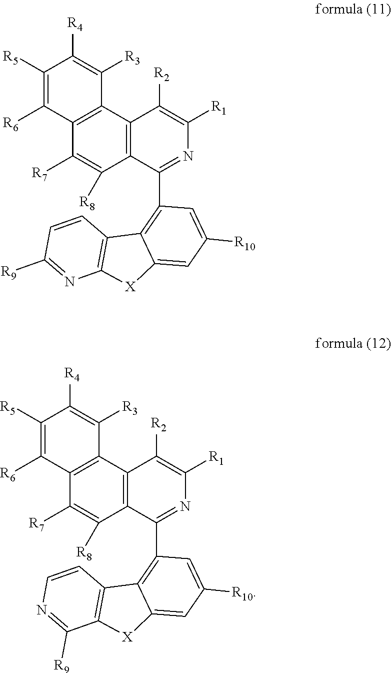

In some embodiments, in accordance with the metal complex of the present disclosure, at least one of R₁-R₈ is not hydrogen, and R₉ and R₁₀ are a substituted or unsubstituted alkyl with a number of carbon atoms in the main chain of no more than 4, or a substituted or unsubstituted cycloalkyl with a number of ring-forming carbon atoms of no more than 6.

In some embodiments, in accordance with the metal complex of the present disclosure, X is an oxygen atom O.

In some embodiments, in accordance with the metal complex of the present disclosure, R₁-R₈ include an electron-withdrawing group, such as F, F substituted C1-C4 alkyl, cyano, pyridyl, and the others are not all hydrogen; or gi in R₁-R₈ includes an electron-withdrawing group.

Hereinafter, examples of each group of the compound represented by formula (1) will be described.

It should be noted that in this specification, the “a carbon number of a to b” in the expression “a substituted or unsubstituted X group having a carbon number of a to b” refers to the carbon number when the X group is unsubstituted, and does not include the carbon number of the substituent when the X group is substituted.

The C1-C10 alkyl group is a linear or branched alkyl group, specifically is methyl, ethyl, propyl, isopropyl, n-butyl, isobutyl, sec-butyl, tert-butyl, n-pentyl and its isomers, n-hexyl and its isomers, n-heptyl and its isomers, n-octyl and its isomers, n-nonyl and its isomers, n-decyl and its isomers, and the like, and preferably methyl, ethyl, propyl, isopropyl, n-butyl, isobutyl, sec-butyl, tert-butyl, and more preferably propyl, isopropyl, isobutyl, sec-butyl, and tert-butyl.

As examples of the C3-C20 cycloalkyl, cyclopropyl, cyclobutyl, cyclopentyl, cyclohexyl, 1-adamantyl, 2-adamantyl, 1-norbornanyl, and 2-norbornanyl, and the like, and preferably cyclopentyl and cyclohexyl can be listed.

As examples of the C2-C10 alkenyl, vinyl, propenyl, allyl, 1-butadienyl, 2-butadienyl, 1-hexatrienyl, 2-hexatrienyl, and 3-hexatrienyl, and preferably propenyl and allyl can be listed.

The C1-C10 heteroalkyl is a linear or branched alkyl and cycloalkyl, and the like, containing atoms other than carbon and hydrogen, and examples thereof include mercaptomethylmethanyl, methoxymethanyl, ethoxymethanyl, tert-butoxymethanyl, N,N-dimethylmethanyl, epoxybutanyl, epoxypentanyl, and epoxyhexanyl, and the like, and preferably methoxymethanyl and epoxypentanyl.

As specific examples of the aryl, phenyl, naphthyl, anthryl, phenanthryl, naphthacenyl, pyrenyl, chrysenyl, benzo[c]phenanthrenyl, benzo[g]chrysenyl, fluorenyl, benzofluorenyl, dibenzofluorenyl, biphenyl, terphenyl, quaterphenyl, fluoranthenyl, and the like, and preferably phenyl and naphthyl can be listed.

As specific examples of the heteroaryl, pyrrolyl, pyrazinyl, pyridyl, pyrimidinyl, triazinyl, indolyl, isoindolyl, imidazolyl, furyl, benzofuryl, isobenzofuryl, dibenzofuryl, dibenzothiophenyl, azadibenzofuryl, azadibenzothiophenyl, diazadibenzofuryl, diazadibenzothiophenyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furazanyl, thienyl, benzothienyl, dihydroacridinyl, azacarbazolyl, diazacarbazolyl, quinazolinyl, and the like, and preferably pyridyl, pyrimidinyl, triazinyl, dibenzofuryl, dibenzothienyl, azadibenzofuryl, azadibenzothienyl, diazadibenzofuryl, diazadibenzothienyl, carbazolyl, azacarbazolyl, and diazacarbazolyl can be listed.

The following examples are only for facilitating the understanding of the technical features and should not be regarded as specific limitations of the present disclosure.

The raw materials and solvents, and the like, involved in the synthesis of the compounds in the present disclosure were purchased from suppliers well known to those skilled in the art, such as Alfa and Acros, and the like.

### Synthesis of Ligand La004

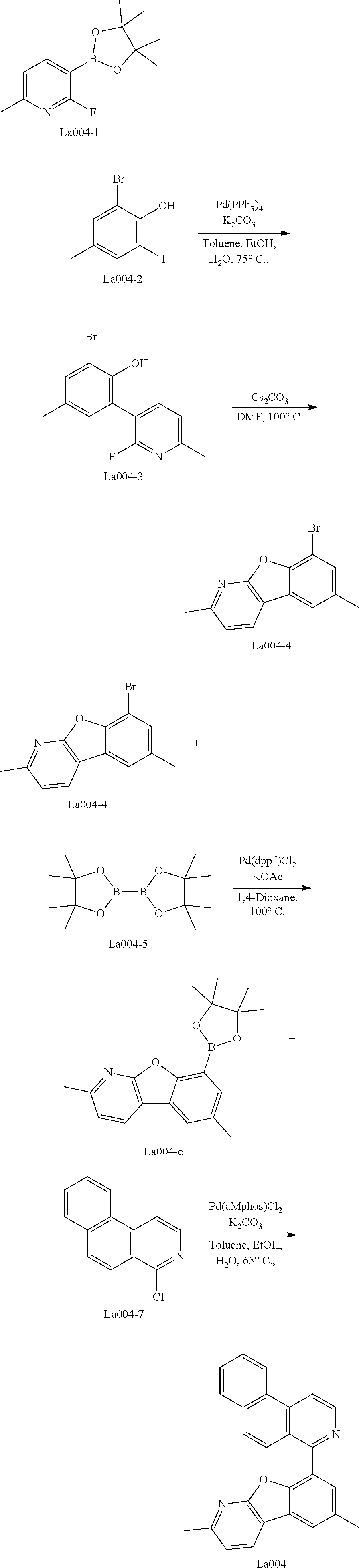

### Synthesis of Compound La004-3

Compound La004-1 (40.00 g, 168.72 mmol), La004-2 (52.80 g, 168.72 mmol), tetrakistriphenylphosphine palladium (3.89 g, 3.37 mmol), potassium carbonate (34.98 g, 253.08 mmol), toluene (600 ml), ethanol (200 ml) and deionized water (200 ml) were added to a 2000 ml three-necked round-bottom flask, and the system was replaced with nitrogen under vacuum for three times, then the mixture was stirred at 75° C. for 6 hours under the protection of nitrogen. The raw material La004-1 was reacted completely via TLC monitoring (with developing solvent of ethyl acetate:n-hexane=1:10).

The mixture was cooled to room temperature, the organic solvent was removed by concentrating under reduced pressure, then ethyl acetate (300 ml) was added and washed with deionized water (3*200 ml), the liquids were separated, the organic phase was concentrated and then subjected to silica gel column chromatography (200-300 mesh silica gel, with an eluent of ethyl acetate: n-hexane=1:20), after elution, it was concentrated under reduced pressure at 65° C. for 2 hours to obtain compound La004-3 as a colorless oily liquid (41.03 g, purity: 99.01%, yield: 82.11%), with a mass spectrum: 296.02 (M+H).

### Synthesis of Compound La004-4

Compound La004-3 (38.00 g, 128.32 mmol), cesium carbonate (83.62 g, 256.64 mmol), and N,N-dimethylformamide (570 ml) were added into a 1000 ml three-necked round-bottom flask, and the system was replaced with nitrogen under vacuum for three times, then the mixture was stirred at 100° C. for 4 hours under the protection of nitrogen. The raw material La004-3 was reacted completely via TLC monitoring (with developing solvent of ethyl acetate:n-hexane=1:20).

The mixture was directly concentrated to remove N,N-dimethylformamide, then ethyl acetate (500 ml) was added and washed with deionized water (3*200 ml), the liquids were separated, the organic phase was concentrated and then subjected to silica gel column chromatography (200-300 mesh silica gel, with an eluent of ethyl acetate:n-hexane=1:30), after elution, it was concentrated under reduced pressure at 65° C. for 2 hours to obtain compound La004-4 as a white solid (31.42 g, purity: 99.68%, yield: 88.67%), with a mass spectrum: 276.22 (M+H).

### Synthesis of Compound La004-6

La004-4 (30.00 g, 108.64 mmol), La004-5 (33.11 g, 130.37 mmol), 1,1-bis(diphenylphosphino)ferrocene palladium dichloride (1.58 g, 2.17 mmol), potassium acetate (15.99 g, 162.96 mmol), and 1,4-dioxane (450 ml) were added to a 1000 ml three-necked round-bottom flask, and the system was replaced with nitrogen under vacuum for three times, then heated to 100° C. and reacted for 2 hours. The reaction was monitored via TLC (with ethyl acetate:n-hexane=1:10 as developing agent) until the raw material La004-4 was consumed completely.

The temperature was lowered to 60° C., and the solvent was removed by concentrating under reduced pressure, then ethyl acetate (700 ml) was added and washed with deionized water three times (300 ml*3), the liquids were separated, and the sample was mixed with silica gel and dry-loaded onto a column to be purified by silica gel column chromatography (200-300 mesh silica gel, ethyl acetate: n-hexane=1:15 as eluent), after elution, it was concentrated under reduced pressure at 70° C. for 1 hour to obtain La004-6 as a white solid (27.53 g, purity: 98.33%, yield: 78.41%), with a mass spectrum: 324.17 (M+H).

### Synthesis of Compound La004

Compound La004-6 (15.00 g, 46.41 mmol), La004-7 (9.92 g, 46.41 mmol), bis(4-dimethylaminophenyldi-tert-butylphosphino)palladium dichloride (0.66 g, 0.93 mmol), potassium carbonate (9.62 g, 69.62 mol), toluene (225 ml), ethanol (75 ml) and deionized water (75 ml) were added to a 1000 ml three-necked flask, and the system was replaced with nitrogen under vacuum for three times, then the mixture was stirred at 65° C. for 2 hours under the protection of nitrogen. The raw material La004-6 was reacted completely via TLC monitoring (with developing solvent of ethyl acetate:n-hexane=1:8).

The mixture was cooled to room temperature, the organic solvent was removed by concentrating under reduced pressure, then ethyl acetate (500 ml) was added and washed with deionized water (3*150 ml), the liquids were separated, the organic phase was concentrated and then subjected to silica gel column chromatography (200-300 mesh silica gel, with an eluent of ethyl acetate:n-hexane=1:15), after elution, it was concentrated under reduced pressure at 65° C. for 2 hours to obtain compound La004 as a white solid (15.02 g, purity: 99.85%, yield: 86.41%), with a mass spectrum: 375.14 (M+H).

### Synthesis of Compound Ir(La004)₂(Lb005)

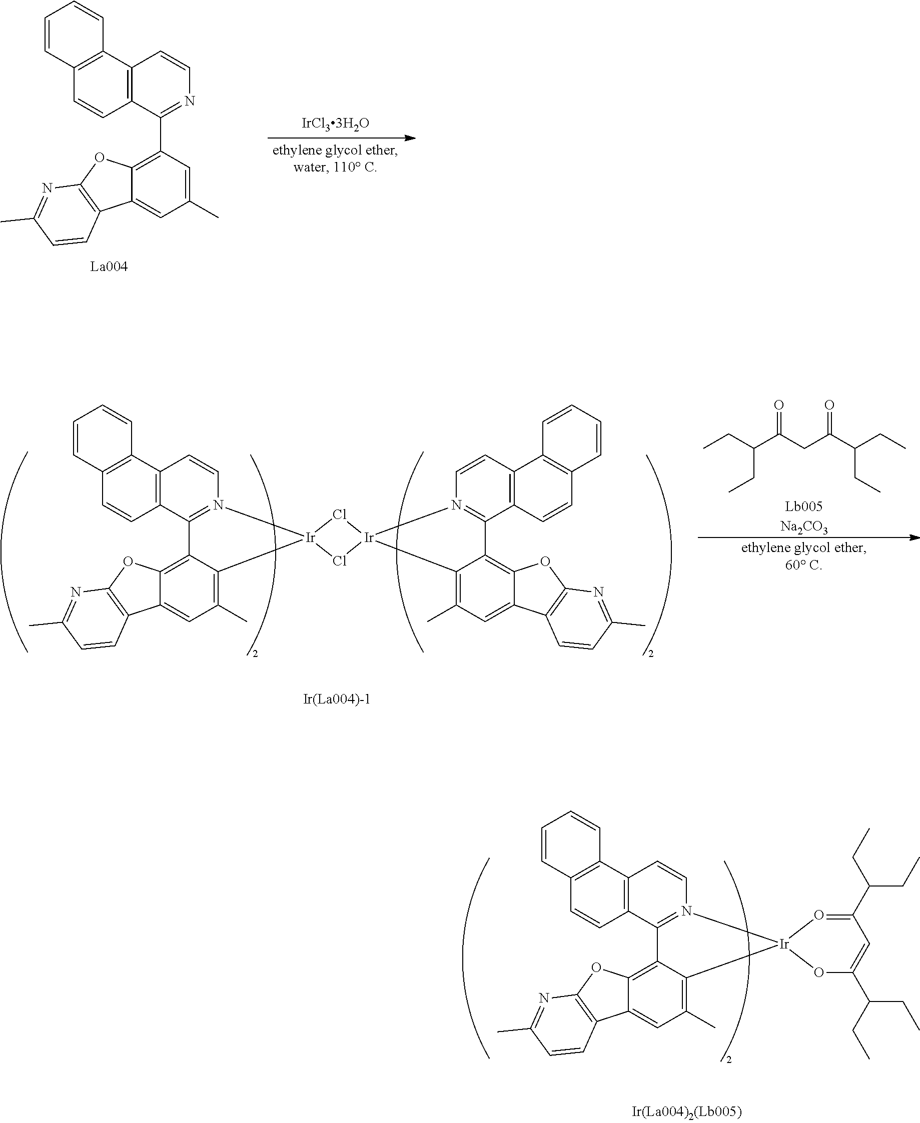

### Synthesis of Compound Ir(La004)-1

Compound La004 (12.62 g, 33.69 mmol) and iridium trichloride trihydrate (3.96 g, 11.23 mmol) were added to a 1000 ml three-necked round-bottom flask, then ethylene glycol ether (150 ml) and deionized water (50 ml) were added, and the system was replaced with nitrogen under vacuum for three times, and then heated to 110° C. and stirred under reflux for 24 hours.

After the mixture was cooled to room temperature, methanol (200 ml) was added, the mixture was triturated at room temperature for 1 hour, and suction filtered, the filter cake was washed with methanol (50 ml), and the solid was vacuum dried at 100° C. to obtain compound Ir(La004)-1 (8.55 g, yield: 78.12%). The obtained compound was used directly in the next step without purification.

### Synthesis of Compound Ir(La004)₂(Lb005)

Compound Ir(La004)-1 (8.50 g, 4.36 mmol), Lb005 (4.63 g, 21.81 mmol), sodium carbonate (4.62 g, 43.61 mmol), and ethylene glycol ether (85 ml) were added to a 250 ml single-necked round-bottom flask, and the system was replaced with nitrogen under vacuum for three times, then the mixture was stirred at 60° C. for 24 hours, and monitored by TLC (with developing solvent of methanol:dichloromethane=1:100) until Ir(La004)-1 was reacted completely.

After the mixture was cooled to room temperature, methanol (120 ml) was added, the mixture was triturated at room temperature for 2 hours and suction filtered, the filter cake was dissolved in dichloromethane (150 ml), and filtered through 300-400 mesh silica gel (50 g), the filtrate was washed with deionized water (3*80 ml) and concentrated at 60° C. for 1 hour to obtain a red solid, which was crystallized twice using tetrahydrofuran and methanol to obtain compound Ir(La004)₂(Lb005) as a red solid (6.05 g, purity: 99.89%, yield: 60.33%). 6.05 g of crude Ir(La004)₂(Lb005) was purified by sublimation to obtain sublimation-purified Ir(La004)₂(Lb005) (4.71 g, purity: 99.75%, yield: 77.86%), with a mass spectrum: 1151.40 (M+H).

¹H NMR (400 MHz, CDCl₃) δ 8.48 (d, J=4.6 Hz, 2H), 8.42-8.37 (m, 2H), 8.32 (d, J=8.6 Hz, 2H), 8.14 (d, J=7.8 Hz, 2H), 8.00 (d, J=8.6 Hz, 2H), 7.96 (d, J=0.9 Hz, 2H), 7.92-7.86 (m, 2H), 7.70 (d, J=4.5 Hz, 2H), 7.56-7.46 (m, 4H), 7.19-7.17 (m, 2H), 4.77 (s, 1H), 2.75-2.71 (m, 1H), 2.47-2.42 (m, 7H), 2.27 (s, 6H), 1.74-1.56 (m, 4H), 1.50-1.30 (m, 4H), 0.92-0.88 (m, 12H).

### Synthesis of Ligand La021

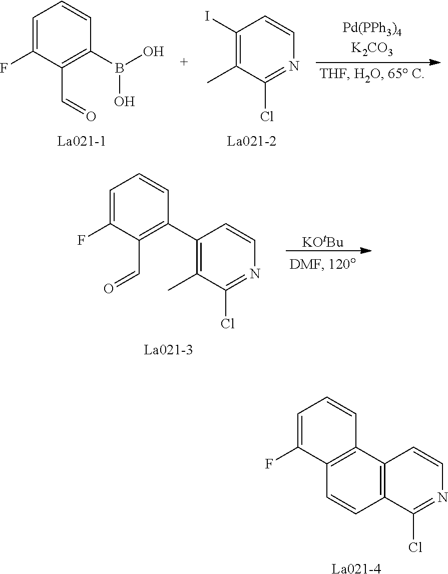

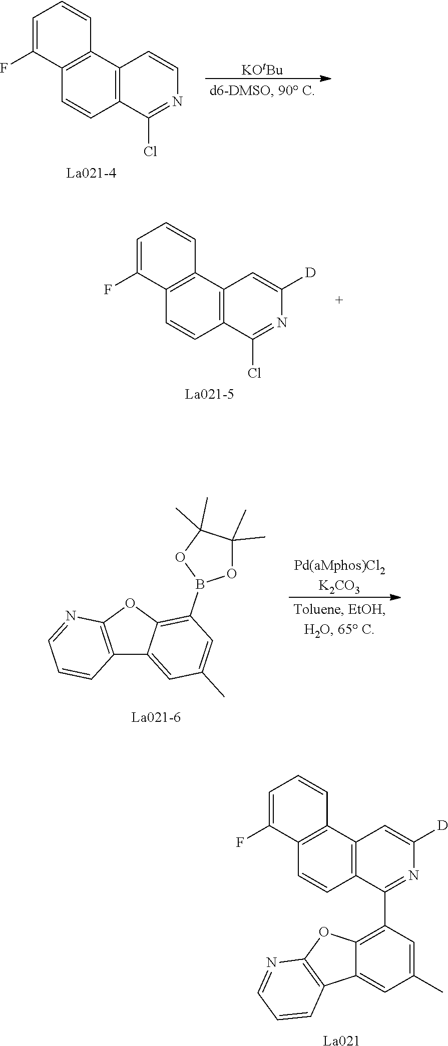

### Synthesis of Compound La021-3

Compound La021-1 (40.00 g, 238.19 mmol), La021-2 (60.37 g, 238.19 mmol), tetrakis(triphenylphosphine)palladium (5.50 g, 4.76 mmol), potassium carbonate (49.34 g, 357.28 mmol) tetrahydrofuran (600 ml) and deionized water (180 ml) were added to a 2000 ml three-necked round-bottom flask, and the system was replaced with nitrogen under vacuum for three times, then the mixture was stirred at 65° C. for 4 hours under the protection of nitrogen. The raw material La021-2 was reacted completely via TLC monitoring (with developing solvent of ethyl acetate:n-hexane=1:20).

The mixture was cooled to room temperature, the organic solvent was removed by concentrating under reduced pressure, then dichloromethane (600 ml) was added and washed with deionized water (200 ml*3), the liquids were separated, the organic phase was concentrated and then subjected to silica gel column chromatography (200-300 mesh silica gel, with an eluent of ethyl acetate:n-hexane=1:40), after elution, it was concentrated at 65° C. for 2 hours to obtain compound La021-3 as a white solid (49.44 g, purity: 99.40%, yield: 83.13%), with a mass spectrum: 250.04 (M+H).

### Synthesis of Compound La021-4

Compound La021-3 (47.00 g, 188.25 mmol), potassium tert-butoxide (31.69 g, 282.37 mmol), and N,N-dimethylformamide (470 ml) were added into a 1000 ml three-necked round-bottom flask, and the system was replaced with nitrogen under vacuum for three times, then the mixture was stirred at 120° C. for 6 hours under the protection of nitrogen. The raw material La021-3 was reacted completely via TLC monitoring (with developing solvent of ethyl acetate:n-hexane=1:10).

The mixture was directly concentrated to remove N,N-dimethylformamide, then ethyl acetate (500 ml) was added and washed with deionized water (200 ml*3), the liquids were separated, the organic phase was concentrated and then subjected to silica gel column chromatography (200-300 mesh silica gel, with an eluent of ethyl acetate:n-hexane=1:25), after elution, it was concentrated at 65° C. for 2 hours to obtain compound La021-4 as a white solid (28.59 g, purity: 99.73%, yield: 65.55%), with a mass spectrum: 232.04 (M+H).

### Synthesis of Compound La021-5

La021-4 (27 g, 116.55 mmol), potassium tert-butoxide (26.16 g, 233.11 mmol), and deuterated dimethyl sulfoxide (270 ml) were added to a 1000 ml three-necked round-bottom flask, and the system was replaced with nitrogen under vacuum for three times, then the mixture was heated to 90° C. and reacted overnight for 24 hours, the La021-4 was monitored to be completed by nuclear magnetic resonance.

The reaction solution was added dropwise to deionized water (500 ml), and ethyl acetate (500 ml) was added, the mixture was stirred at room temperature for 30 minutes, the liquids were separated, the organic phase was washed with deionized water (150 ml*3), and the liquids were separated, the organic phase was concentrated and then subjected to silica gel column chromatography (200-300 mesh silica gel, with an eluent of ethyl acetate:n-hexane=1:10), after elution, it was concentrated at 65° C. for 2 hours to obtain compound La021-5 as a white solid (26.23 g, purity: 99.80%, deuterated ratio: 99.55%, yield: 96.74%), with a mass spectrum: 233.04 (M+H).

### Synthesis of Compound La021

Referring to the synthesis and purification methods of compound La004, it was only necessary to change the corresponding raw materials to obtain the target compound La021 (17.63 g, purity: 99.90%, yield: 84.65%), with a mass spectrum: 380.22 (M+H).

### Synthesis of Compound Ir(La021)₂(Lb005)

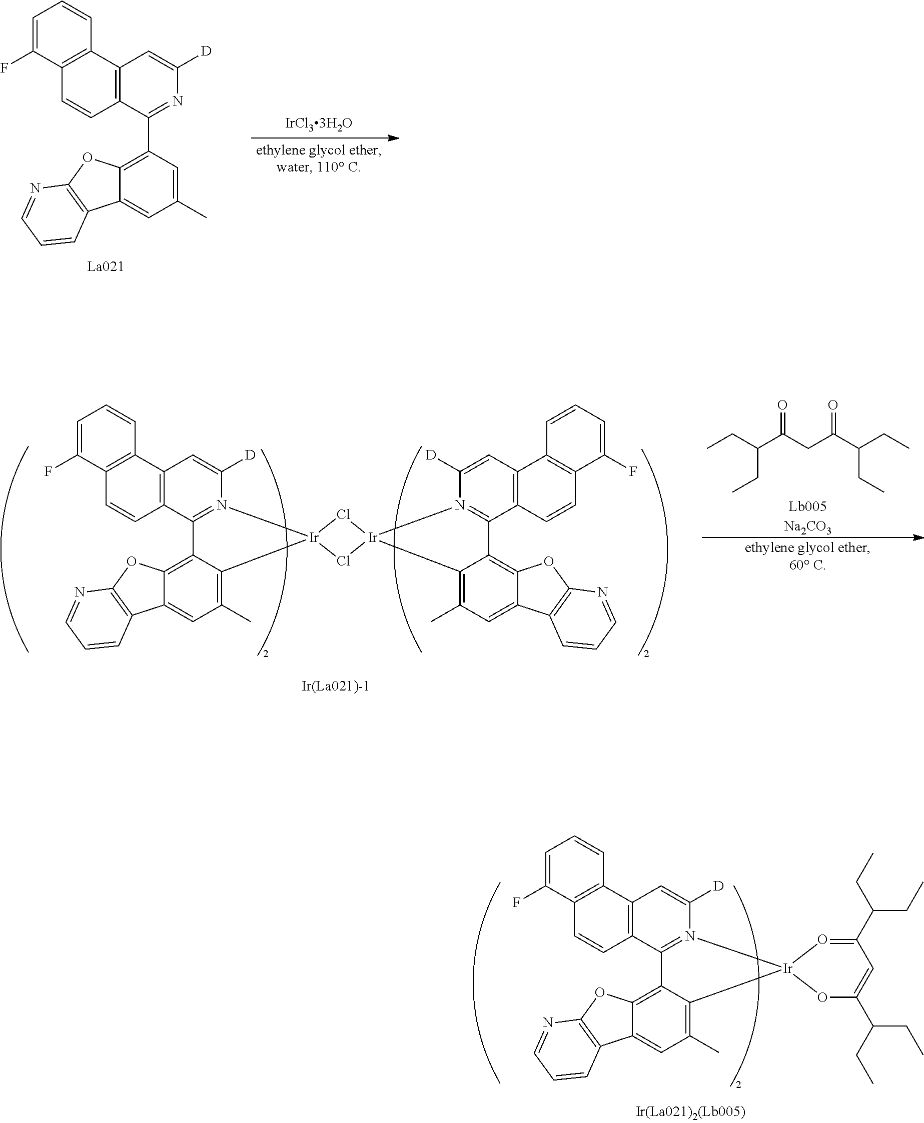

### Synthesis of Compound Ir(La021)-1

Referring to the synthesis and purification methods of compound Ir(La004)-1, it was only necessary to change the corresponding raw materials to obtain the compound Ir(La021)-1 (10.23 g, yield: 76.88%). The obtained compound was used directly in the next step without purification.

### Synthesis of Compound Ir(La021)₂(Lb005)

Referring to the synthesis and purification methods of compound Ir(La004)₂(Lb005), it was only necessary to change the corresponding raw materials to obtain the compound Ir(La021)₂(Lb005) as a red solid (7.33 g, purity: 99.86%, yield: 50.63%). 7.33 g of crude Ir(La021)₂(Lb005) was purified by sublimation to obtain sublimation-purified Ir(La021)₂(Lb005) (5.54 g, purity: 99.84%, yield: 75.58%), with a mass spectrum: 1161.36 (M+H).

¹H NMR (400 MHz, CDCl₃) δ 8.48 (dd, J=5.6, 2.1 Hz, 2H), 8.35-8.30 (m, 2H), 8.21-8.09 (m, 8H), 7.64 (s, 2H), 7.53 (t, J=7.5 Hz, 2H), 7.47 (dd, J=9.1, 5.6 Hz, 2H), 7.28-7.23 (m, 2H), 4.81 (m, 1H), 2.74-2.68 (m, 2H), 2.27 (s, 6H), 1.68-1.54 (m, 4H), 1.43-1.28 (m, 4H), 0.92-0.86 (m, 12H).

### Synthesis of Ligand La028

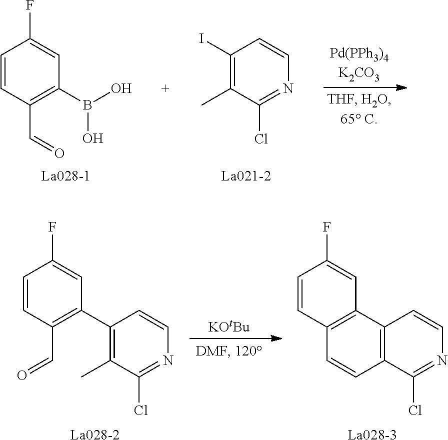

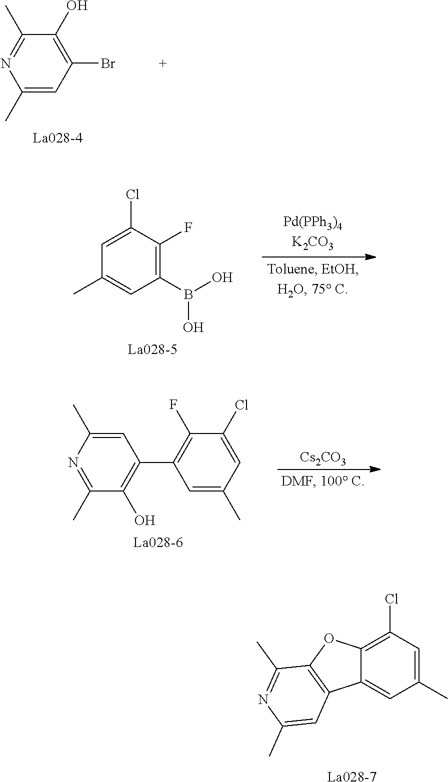

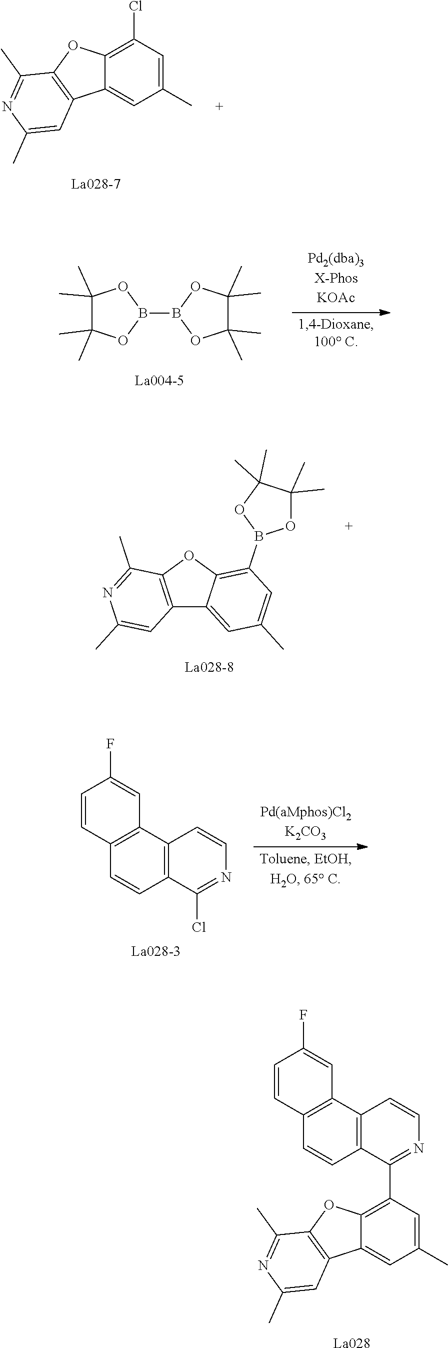

### Synthesis of Compound La028-2

Referring to the synthesis and purification methods of compound La021-3, it was only necessary to change the corresponding raw materials to obtain the target compound La028-2 (30.50 g, purity: 99.71%, yield: 80.08%), with a mass spectrum: 250.04 (M+H).

### Synthesis of Compound La028-3

Referring to the synthesis and purification methods of compound La021-4, it was only necessary to change the corresponding raw materials to obtain the target compound La028-3 (27.01 g, purity: 99.82%, yield: 68.86%), with a mass spectrum: 232.04 (M+H).

### Synthesis of Compound La028-6

Referring to the synthesis and purification methods of compound La004-3, it was only necessary to change the corresponding raw materials to obtain the target compound La028-6 (28.65 g, purity: 99.12%, yield: 80.00%), with a mass spectrum: 266.12 (M+H).

### Synthesis of Compound La028-7

Referring to the synthesis and purification methods of compound La004-4, it was only necessary to change the corresponding raw materials to obtain the target compound La028-7 (20.05 g, purity: 99.53%, yield: 84.63%), with a mass spectrum: 246.22 (M+H).

### Synthesis of Compound La028-8

Referring to the synthesis and purification methods of compound La004-6, it was only necessary to change the corresponding raw materials and replace the catalyst with a combination of tris(dibenzylideneacetone)dipalladium and 2-dicyclohexylphosphino-2′,4′,6′-triisopropylbiphenyl at the same time to obtain the target compound La028-8 (17.63 g, purity: 98.88%, yield: 77.09%), with a mass spectrum: 378.18 (M+H).

### Synthesis of Compound La028

Referring to the synthesis and purification methods of compound La004, it was only necessary to change the corresponding raw materials to obtain the target compound La028 (13.33 g, purity: 99.83%, yield: 82.52%), with a mass spectrum: 407.12 (M+H).

### Synthesis of Compound Ir(La028)₂(Lb005)

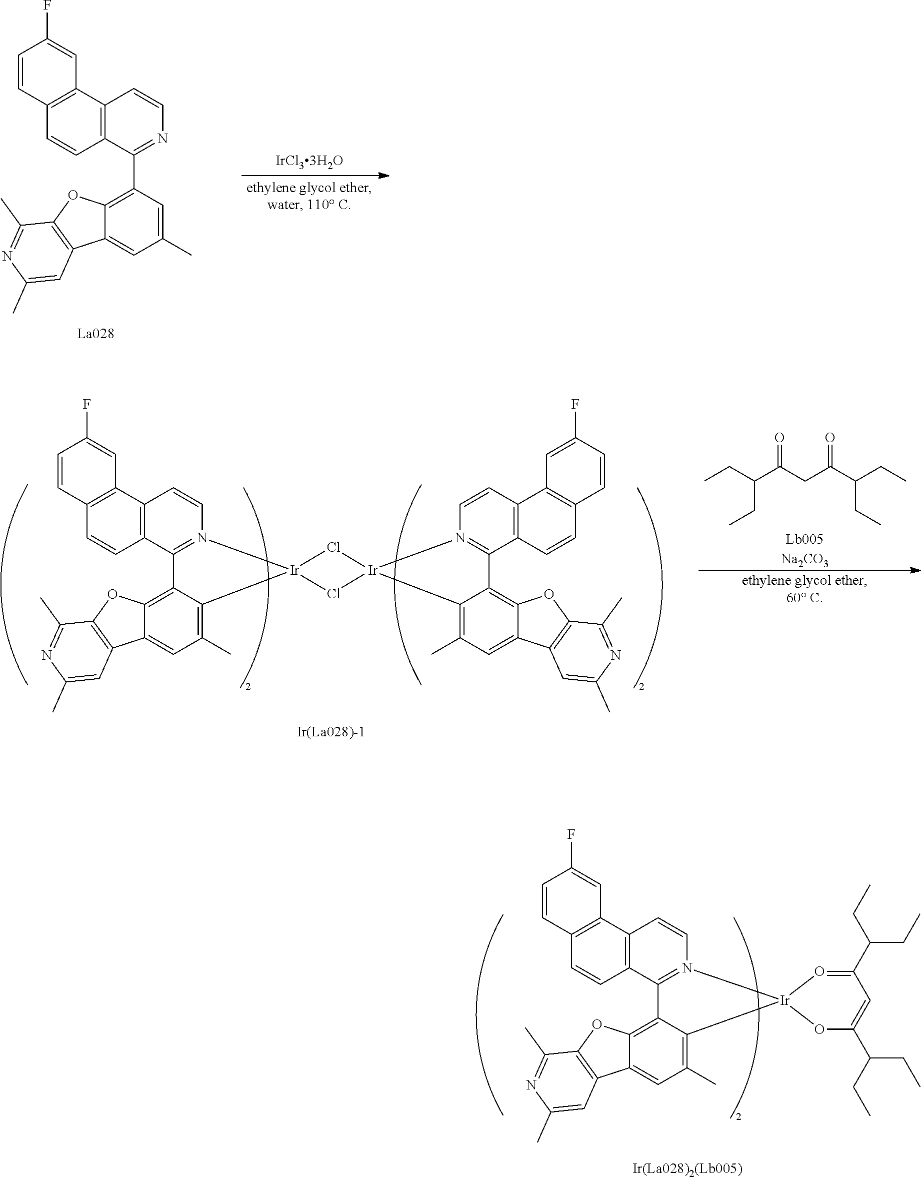

### Synthesis of Compound Ir(La0281)-1

Referring to the synthesis and purification methods of compound Ir(La004)-1, it was only necessary to change the corresponding raw materials to obtain the compound Ir(La028)-1 (9.52 g, yield: 75.62%). The obtained compound was used directly in the next step without purification.

### Synthesis of Compound Ir(La028)₂(Lb005)

Referring to the synthesis and purification methods of compound Ir(La004)₂(Lb005), it was only necessary to change the corresponding raw materials to obtain the compound Ir(La028)₂(Lb005) as a red solid (5.63 g, purity: 99.82%, yield: 47.86%). 5.63 g of crude Ir(La028)₂(Lb005) was purified by sublimation to obtain sublimation-purified Ir(La028)₂(Lb005) (3.25 g, purity: 99.80%, yield: 57.72%), with a mass spectrum: 1215.42 (M+H).

¹H NMR (400 MHz, CDCl₃) δ 8.20 (d, J=9.6 Hz, 2H), 8.12 (d, J=0.8 Hz, 2H), 8.03 (d, J=8.6 Hz, 2H), 8.00-7.91 (m, 4H), 7.79 (d, J=3.0 Hz, 2H), 7.48 (d, J=0.8 Hz, 2H), 7.23-7.13 (m, 4H), 4.79 (s, 1H), 2.74-2.68 (m, 2H), 2.45 (d, J=16.3 Hz, 12H), 2.27 (s, 6H), 1.68-1.54 (m, 4H), 1.43-1.28 (m, 4H), 0.90-0.86 (m, 12H).

### Synthesis of Ligand La034

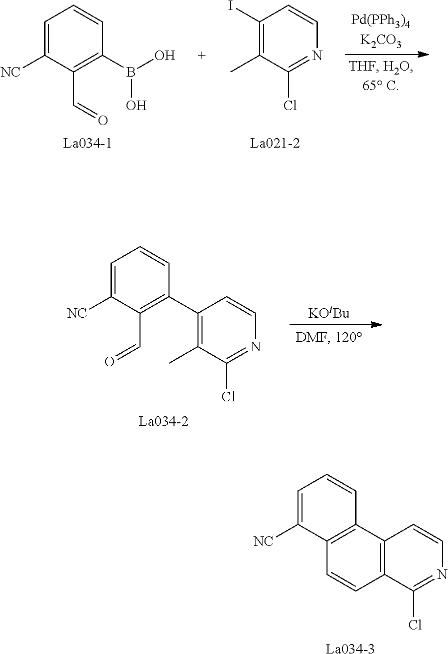

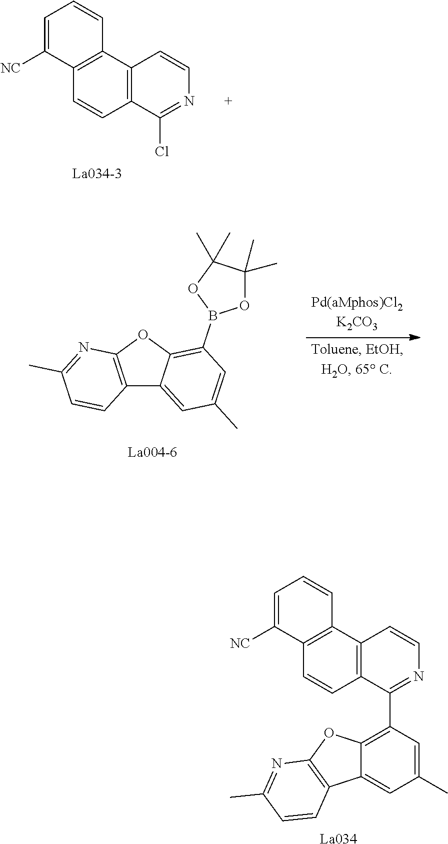

### Synthesis of Compound La034-2

Referring to the synthesis and purification methods of compound La021-3, it was only necessary to change the corresponding raw materials to obtain the target compound La034-2 (28.41 g, purity: 99.51%, yield: 78.62%), with a mass spectrum: 257.06 (M+H).

### Synthesis of Compound La034-3

Referring to the synthesis and purification methods of compound La021-4, it was only necessary to change the corresponding raw materials to obtain the target compound La034-3 (21.91 g, purity: 99.63%, yield: 65.36%), with a mass spectrum: 239.14 (M+H).

### Synthesis of Compound La034

Referring to the synthesis and purification methods of compound La004, it was only necessary to change the corresponding raw materials to obtain the target compound La034 (17.11 g, purity: 99.86%, yield: 85.62%), with a mass spectrum: 400.23 (M+H).

¹H NMR (400 MHz, CDCl₃) 8.97 (dd, J=13.7, 7.1 Hz, 2H), 8.50 (d, J=5.7 Hz, 1H), 8.17 (d, J=7.8 Hz, 1H), 8.11 (t, J=7.7 Hz, 2H), 7.94-7.85 (m, 2H), 7.81-7.77 (m, 1H), 7.64 (s, 1H), 7.19 (d, J=7.7 Hz, 1H), 2.62 (s, 3H), 2.60 (s, 3H).

### Synthesis of Compound Ir(La034)₂(Lb005)

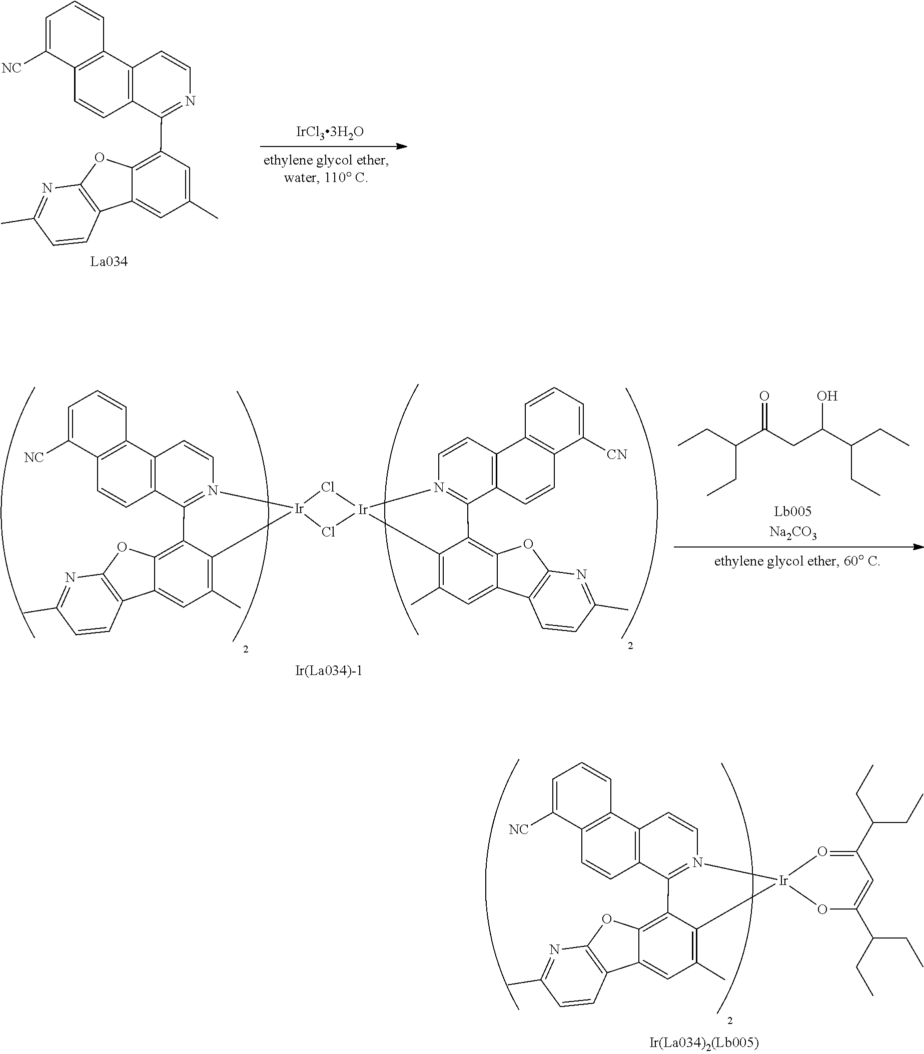

### Synthesis of Compound Ir(La034)-1

Referring to the synthesis and purification methods of compound Ir(La004)-1, it was only necessary to change the corresponding raw materials to obtain the compound Ir(La034)-1 (15.55 g, yield: 78.69%). The obtained compound was used directly in the next step without purification.

### Synthesis of Compound Ir(La034)₂(Lb005)

Referring to the synthesis and purification methods of compound Ir(La004)₂(Lb005), it was only necessary to change the corresponding raw materials to obtain the compound Ir(La034)₂(Lb005) as a red solid (5.21 g, purity: 99.87%, yield: 56.89%). 5.21 g of crude Ir(La034)₂(Lb005) was purified by sublimation to obtain sublimation-purified Ir(La034)₂(Lb005) (3.63 g, purity: 99.68%, yield: 69.67%), with a mass spectrum: 1201.30 (M+H).

¹H NMR (400 MHz, CDCl₃) δ 8.41 (dd, J=6.6, 1.1 Hz, 2H), 8.23-8.08 (m, 8H), 8.04 (d, J=8.6 Hz, 2H), 7.75-7.70 (m, 2H), 7.52 (t, J=6.6 Hz, 2H), 7.21-7.13 (m, 4H), 4.80 (s, 1H), 2.74-2.71 (m, 2H), 2.45 (d, J=0.7 Hz, 6H), 2.27 (s, 6H), 1.68-1.54 (m, 4H), 1.43-1.28 (m, 4H), 0.88-0.86 (m, 12H).

### Synthesis of Compound Ir(La034)₂(Lb007)

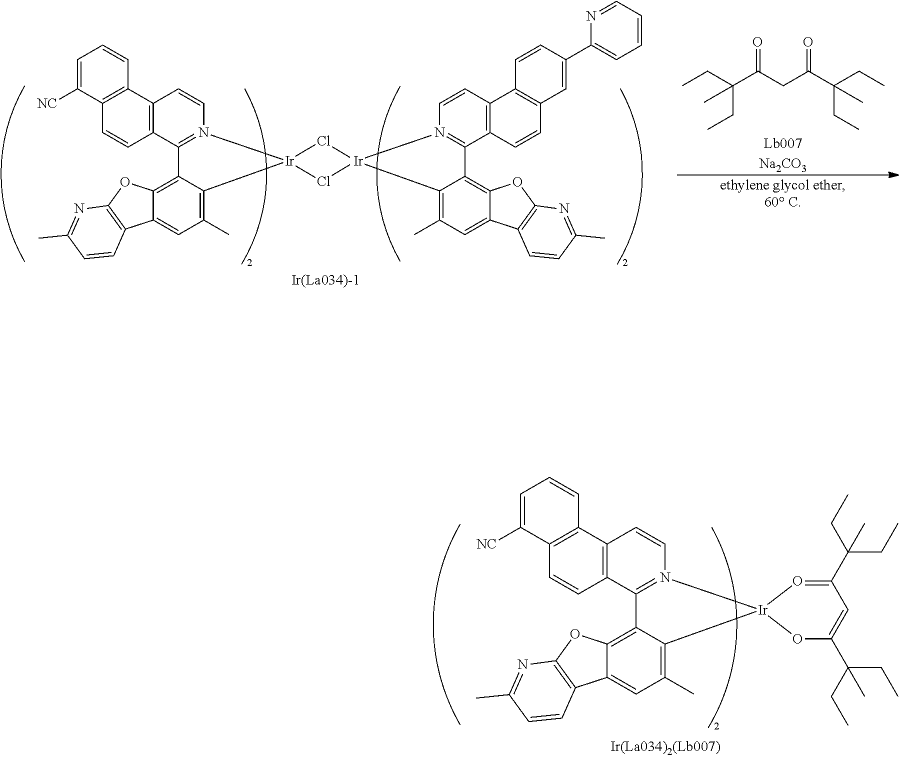

### Synthesis of Compound Ir(La034)₂(Lb007)

Referring to the synthesis and purification methods of compound Ir(La004)₂(Lb005), it was only necessary to change the corresponding raw materials to obtain the compound Ir(La034)₂(Lb007) as a red solid (6.52 g, purity: 99.80%, yield: 53.67%). 6.52 g of crude Ir(La034)₂(Lb007) was purified by sublimation to obtain sublimation-purified Ir(La034)₂(Lb007) (4.54 g, purity: 99.78%, yield: 69.63%), with a mass spectrum: 1229 (M+H).

¹H NMR (400 MHz, CDCl₃) δ 8.94 (d, J=9.5 Hz, 2H), 8.88 (d, J=8.4 Hz, 2H), 8.55 (d, J=6.3 Hz, 2H), 8.41 (d, J=9.4 Hz, 2H), 8.14 (d, J=7.4 Hz, 2H), 8.05 (d, J=6.4 Hz, 2H), 7.97 (d, J=7.6 Hz, 2H), 7.79 (t, J=7.9 Hz, 2H), 7.31 (s, 2H), 7.12 (d, J=7.7 Hz, 2H), 5.07 (s, 1H), 2.65 (s, 6H), 1.62 (s, 6H), 1.18 (dd, J=13.9, 7.4 Hz, 2H), 1.10 (dd, J=13.6, 7.2 Hz, 2H), 0.99-0.90 (m, 4H), 0.59 (s, 6H), 0.07 (t, J=7.2 Hz, 6H), 0.01-−0.04 (m, 6H).

### Synthesis of Ligand La050

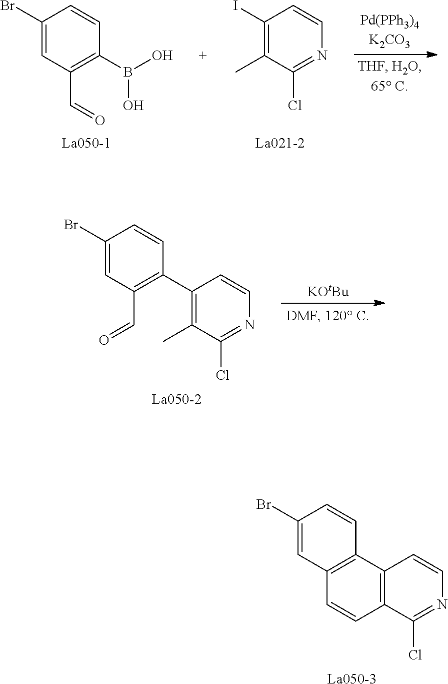

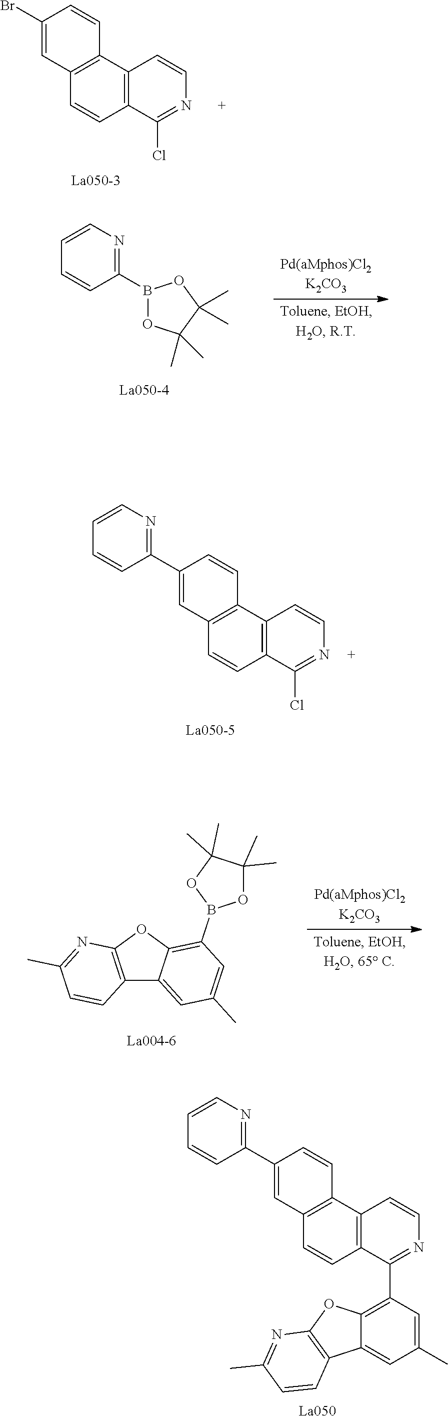

### Synthesis of Compound La050-2

Referring to the synthesis and purification methods of compound La021-3, it was only necessary to change the corresponding raw materials to obtain the target compound La050-2 (25.96 g, purity: 99.75%, yield: 76.59%), with a mass spectrum: 310.04 (M+H).

### Synthesis of Compound La050-3

Referring to the synthesis and purification methods of compound La021-4, it was only necessary to change the corresponding raw materials to obtain the target compound La050-3 (23.74 g, purity: 99.70%, yield: 64.85%), with a mass spectrum: 292.26 (M+H).

### Synthesis of Compound La050-5

Referring to the synthesis and purification methods of compound La004, it was only necessary to change the corresponding raw materials and the reaction temperature was at room temperature, to obtain the target compound La050-5 (19.86 g, purity: 99.73%, yield: 84.43%), with a mass spectrum: 291.02 (M+H).

### Synthesis of Compound La050

Referring to the synthesis and purification methods of compound La004, it was only necessary to change the corresponding raw materials to obtain the target compound La050 (15.11 g, purity: 99.73%, yield: 82.63%), with a mass spectrum: 452.17 (M+H).

### Synthesis of Compound Ir(La050)₂(Lb005)

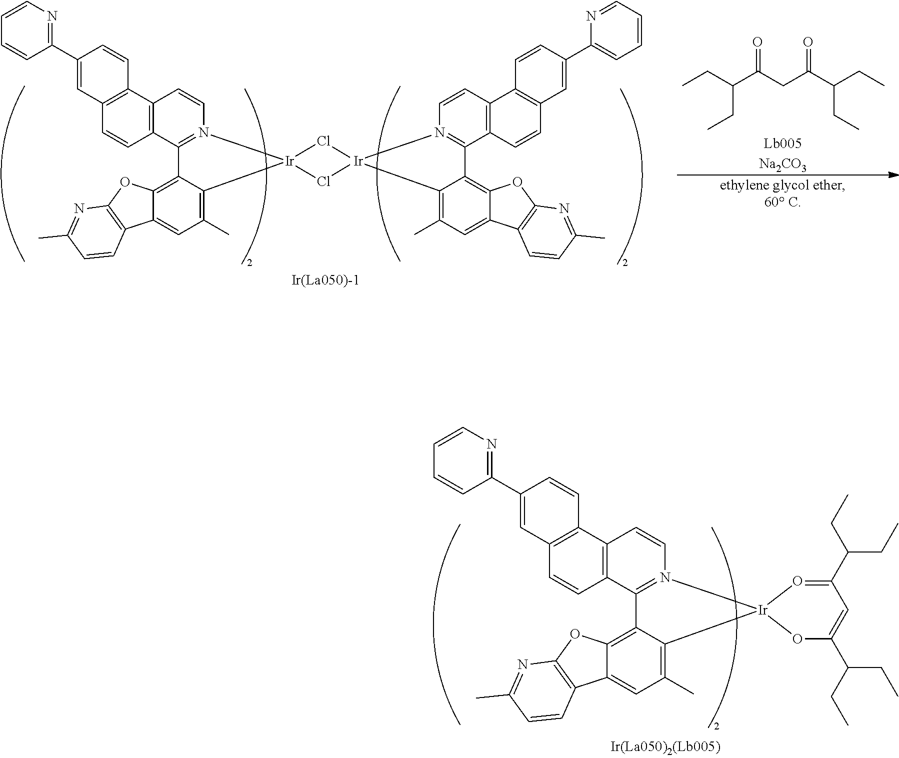

### Synthesis of Compound Ir(La050)-1

Referring to the synthesis and purification methods of compound Ir(La004)-1, it was only necessary to change the corresponding raw materials to obtain the compound Ir(La050)-1 (15.55 g, yield: 78.69%). The obtained compound was used directly in the next step without purification.

### Synthesis of Compound Ir(La050)₂(Lb005)

Referring to the synthesis and purification methods of compound Ir(La004)₂(Lb005), it was only necessary to change the corresponding raw materials to obtain the compound Ir(La050)₂(Lb005) as a red solid (7.65 g, purity: 99.87%, yield: 46.86%). 7.65 g of crude Ir(La050)₂(Lb005) was purified by sublimation to obtain sublimation-purified Ir(La050)₂(Lb005) (5.55 g, purity: 99.75%, yield: 72.55%), with a mass spectrum: 1305.25 (M+H).

¹H NMR (400 MHz, CDCl₃) δ 8.58 (dd, J=4.1, 1.7 Hz, 2H), 8.31 (d, J=9.1 Hz, 2H), 8.19-8.12 (m, 6H), 8.09-8.07 (m, 2H), 8.04-7.97 (m, 4H), 7.77-7.75 (m, 2H), 7.74-7.64 (m, 4H), 7.30-7.28 (m, 2H), 7.21-7.13 (m, 4H), 4.79 (m, 1H), 2.73-2.67 (m, 2H), 2.45 (d, J=0.7 Hz, 6H), 2.27 (s, 6H), 1.68-1.54 (m, 4H), 1.43-1.28 (m, 4H), 0.89-0.85 (m, 12H).

### Synthesis of Ligand La055

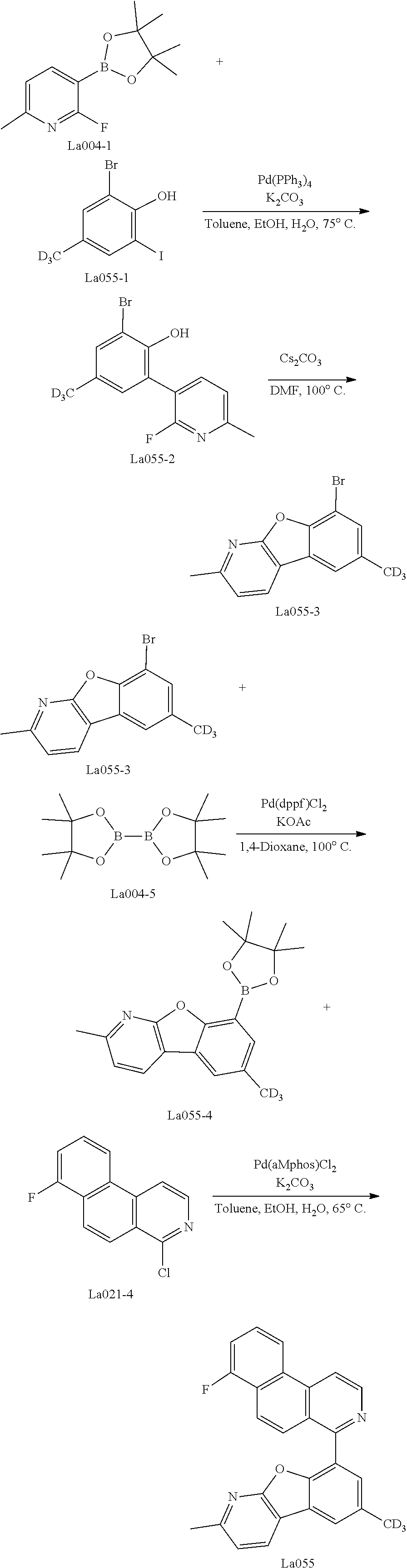

### Synthesis of Compound La055-2

Referring to the synthesis and purification methods of compound La004-3, it was only necessary to change the corresponding raw materials to obtain the target compound La055-2 (22.44 g, purity: 99.46%, yield: 78.87%), with a mass spectrum: 299.02 (M+H).

### Synthesis of Compound La055-3

Referring to the synthesis and purification methods of compound La004-4, it was only necessary to change the corresponding raw materials to obtain the target compound La055-3 (19.99 g, purity: 99.82%, yield: 65.05%), with a mass spectrum: 279.01 (M+H).

### Synthesis of Compound La055-4

Referring to the synthesis and purification methods of compound La004-6, it was only necessary to change the corresponding raw materials to obtain the target compound La055-4 (15.86 g, purity: 99.02%, yield: 80.00%), with a mass spectrum: 327.24 (M+H).

### Synthesis of Compound La055

Referring to the synthesis and purification methods of compound La004, it was only necessary to change the corresponding raw materials to obtain the target compound La055 (13.15 g, purity: 99.85%, yield: 83.47%), with a mass spectrum: 396.16 (M+H).

### Synthesis of Compound Ir(La055)₂(Lb005)

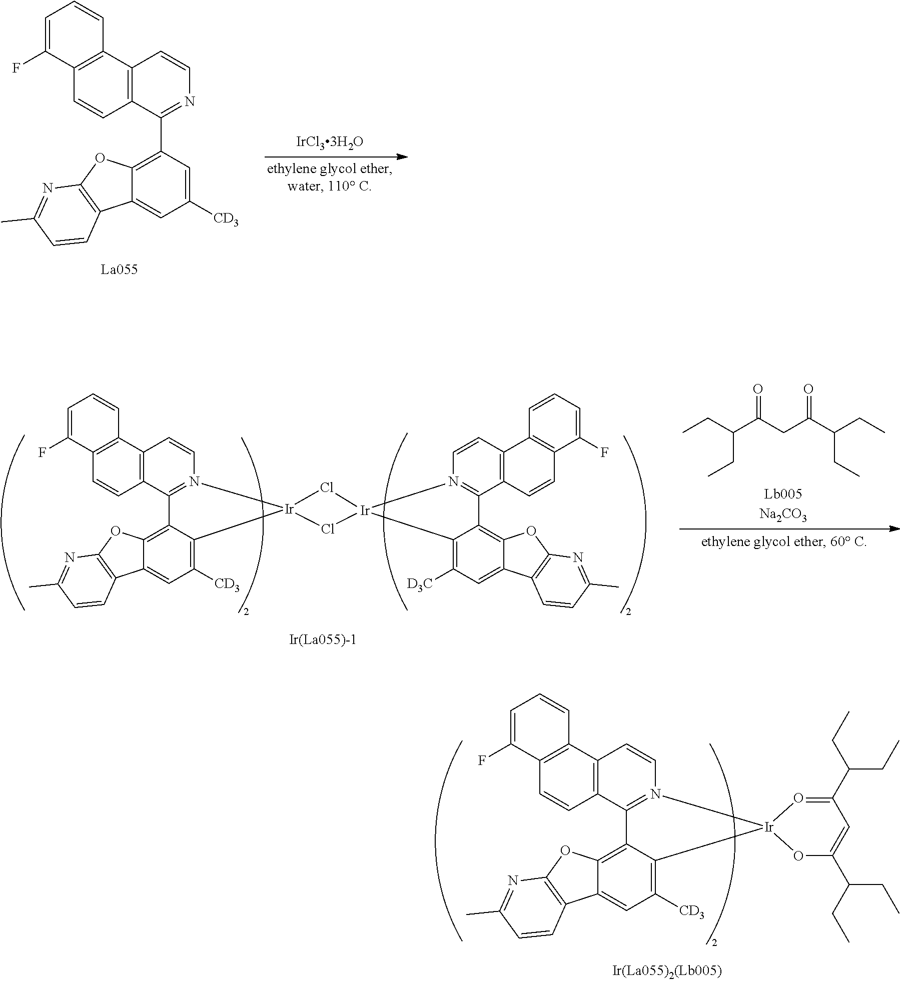

### Synthesis of Compound Ir(La055)-1

Referring to the synthesis and purification methods of compound Ir(La004)-1, it was only necessary to change the corresponding raw materials to obtain the compound Ir(La055)-1 (12.77 g, yield: 77.01%). The obtained compound was used directly in the next step without purification.

### Synthesis of Compound Ir(La055)₂(Lb005)

Referring to the synthesis and purification methods of compound Ir(La004)₂(Lb005), it was only necessary to change the corresponding raw materials to obtain the compound Ir(La055)₂(Lb005) as a red solid (4.86 g, purity: 99.85%, yield: 50.55%). 4.86 g of crude Ir(La055)₂(Lb005) was purified by sublimation to obtain sublimation-purified Ir(La055)₂(Lb005) (3.35 g, purity: 99.81%, yield: 68.93%), with a mass spectrum: 1193.42 (M+H).

¹H NMR (400 MHz, CDCl₃) δ 8.40 (s, 2H), 8.25 (dd, J=7.5, 0.7 Hz, 2H), 8.20 (d, J=9.5 Hz, 2H), 8.15 (dd, J=8.8, 6.0 Hz, 4H), 8.02 (d, J=9.7 Hz, 2H), 7.56-7.49 (m, 2H), 7.28-7.23 (m, 2H), 7.21-7.13 (m, 4H), 4.80 (s, 1H), 2.71-2.68 (m, 2H), 2.45 (d, J=0.7 Hz, 6H), 1.68-1.54 (m, 4H), 1.43-1.28 (m, 4H), 0.88-0.86 (m, 12H).

### Synthesis of Compound Ir(La055)₂(Lb031)

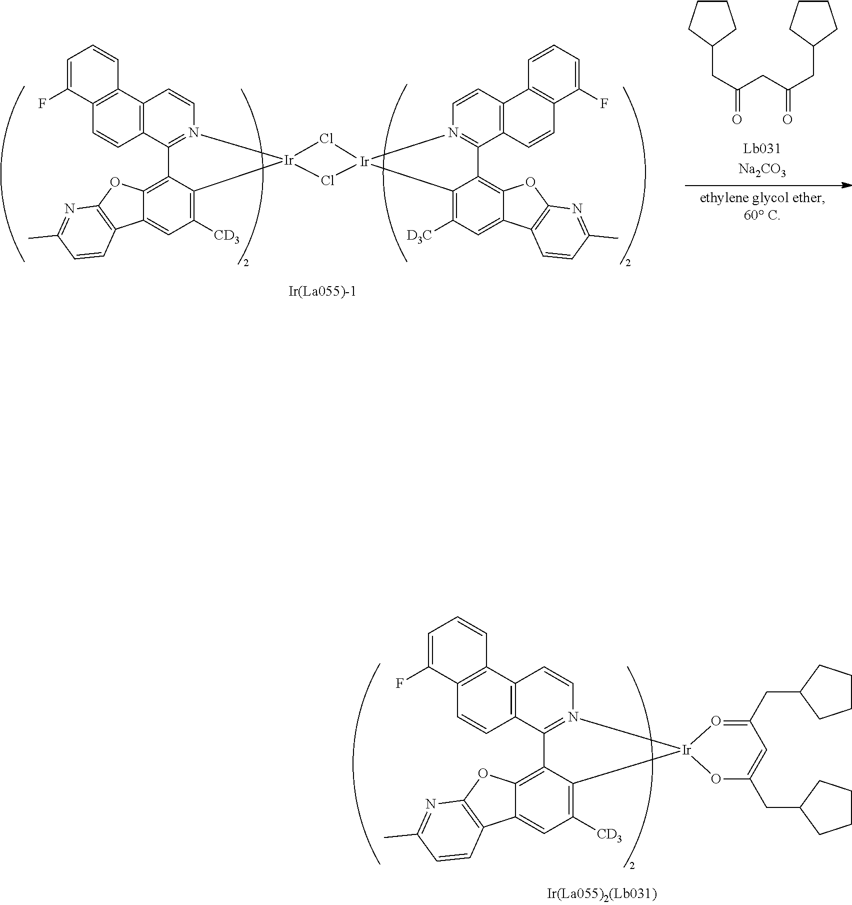

### Synthesis of Compound Ir(La055)₂(Lb031)

Referring to the synthesis and purification methods of compound Ir(La004)₂(Lb005), it was only necessary to change the corresponding raw materials to obtain the compound Ir(La055)₂(Lb031) as a red solid (4.12 g, purity: 99.87%, yield: 52.36%). 4.12 g of crude Ir(La055)₂(Lb031) was purified by sublimation to obtain sublimation-purified Ir(La055)₂(Lb031) (3.01 g, purity: 99.85%, yield: 73.09%), with a mass spectrum: 1217.40 (M+H).

¹H NMR (400 MHz, CDCl₃) δ 8.40 (s, 2H), 8.25 (dd, J=7.5, 0.7 Hz, 2H), 8.20 (d, J=9.5 Hz, 2H), 8.15 (dd, J=8.8, 6.0 Hz, 4H), 8.02 (d, J=9.7 Hz, 2H), 7.56-7.49 (m, 2H), 7.28-7.23 (m, 2H), 7.21-7.13 (m, 4H), 4.39 (s, 1H), 2.50 (dd, J=4.8, 0.9 Hz, 2H), 2.44 (dd, J=9.1, 1.0 Hz, 8H), 1.89-1.75 (m, 2H), 1.60-1.51 (m, 7H), 1.51-1.46 (m, 1H), 1.44-1.39 (m, 4H), 1.35-1.21 (m, 4H).

### Synthesis of Ligand La067

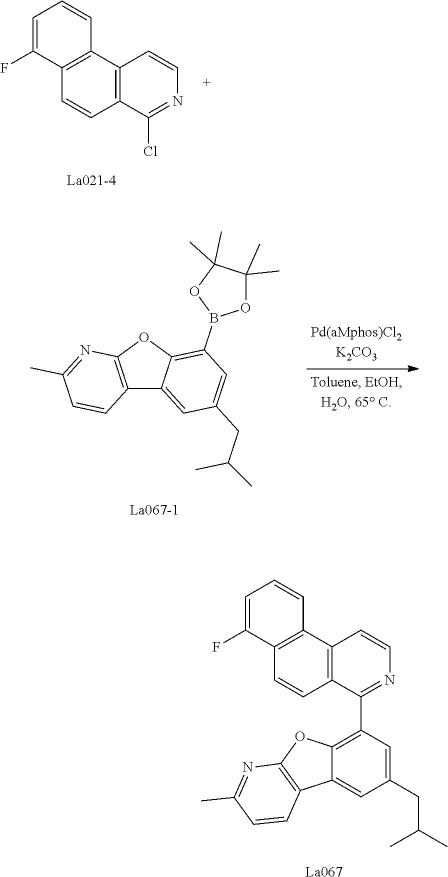

### Synthesis of Compound La067

Referring to the synthesis and purification methods of compound La004, it was only necessary to change the corresponding raw materials to obtain the target compound La067 (16.65 g, purity: 99.89%, yield: 82.44%), with a mass spectrum: 435.18 (M+H).

### Synthesis of Compound Ir(La067)₂(Lb005)

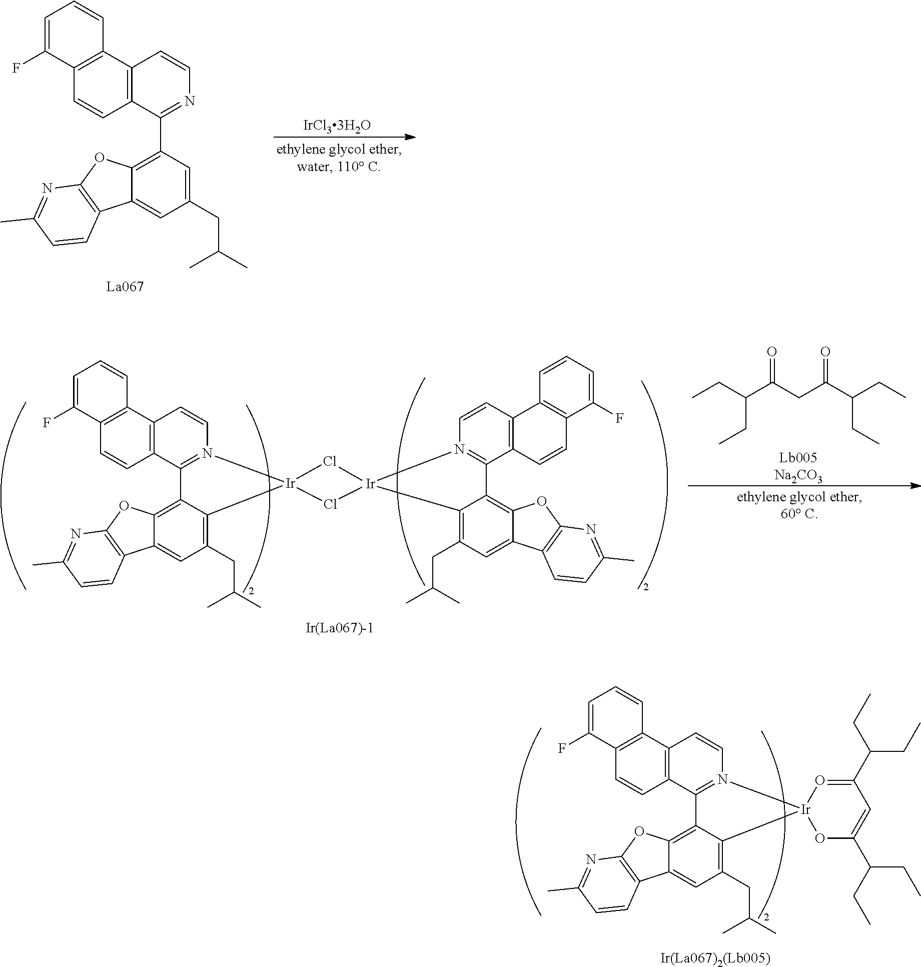

### Synthesis of Compound Ir(La067)-1

Referring to the synthesis and purification methods of compound Ir(La004)-1, it was only necessary to change the corresponding raw materials to obtain the compound Ir(La067)-1 (10.25 g, yield: 76.08%). The obtained compound was used directly in the next step without purification.

### Synthesis of Compound Ir(La067)₂(Lb005)

Referring to the synthesis and purification methods of compound Ir(La004)₂(Lb005), it was only necessary to change the corresponding raw materials to obtain the compound Ir(La067)₂(Lb005) as a red solid (5.02 g, purity: 99.80%, yield: 52.62%). 5.02 g of crude Ir(La067)₂(Lb005) was purified by sublimation to obtain sublimation-purified Ir(La067)₂(Lb005) (3.98 g, purity: 99.81%, yield: 79.29%), with a mass spectrum: 1271.48 (M+H).

¹H NMR (400 MHz, CDCl₃) δ 8.27-8.12 (m, 8H), 8.02 (d, J=9.7 Hz, 2H), 7.64 (d, J=1.1 Hz, 2H), 7.56-7.49 (m, 2H), 7.28-7.23 (m, 2H), 7.21-7.13 (m, 4H), 4.79 (s, 1H), 2.81 (dd, J=6.8, 0.9 Hz, 4H), 2.74-2.68 (m, 2H), 2.45 (d, J=0.7 Hz, 6H), 1.97-1.88 (m, 2H), 1.68-1.54 (m, 4H), 1.43-1.28 (m, 4H), 0.92-0.84 (m, 24H).

### Synthesis of Ligand La083

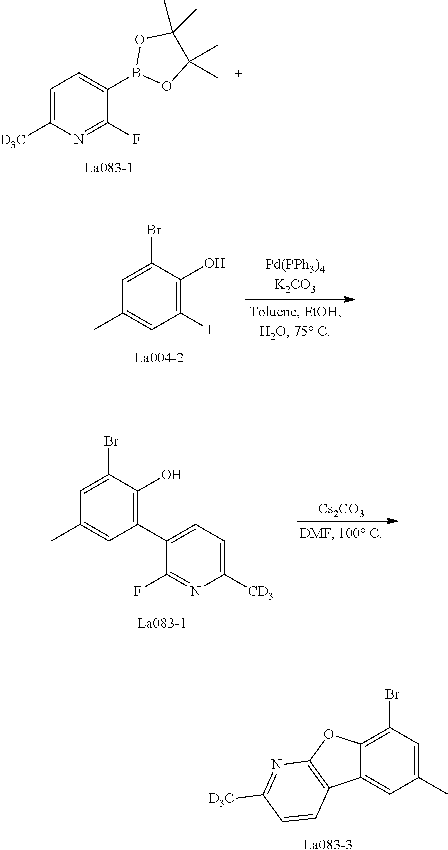

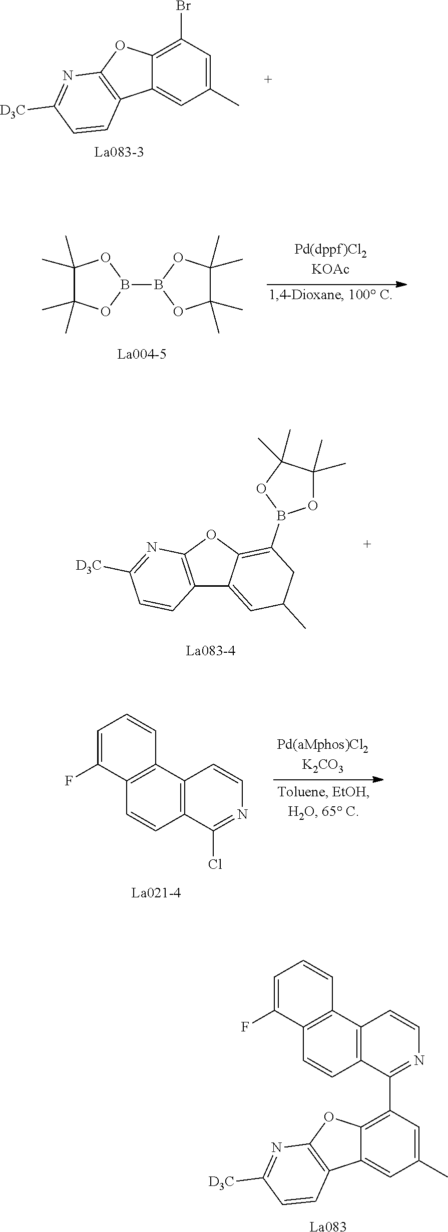

### Synthesis of Compound La083-2

Referring to the synthesis and purification methods of compound La004-3, it was only necessary to change the corresponding raw materials to obtain the target compound La083-2 (25.36 g, purity: 99.85%, yield: 77.85%), with a mass spectrum: 299.02 (M+H).

### Synthesis of Compound La083-3

Referring to the synthesis and purification methods of compound La004-4, it was only necessary to change the corresponding raw materials to obtain the target compound La083-3 (22.11 g, purity: 99.80%, yield: 66.83%), with a mass spectrum: 279.01 (M+H).

### Synthesis of Compound La083-4

Referring to the synthesis and purification methods of compound La004-6, it was only necessary to change the corresponding raw materials to obtain the target compound La083-4 (17.05 g, purity: 99.05%, yield: 78.06%), with a mass spectrum: 327.24 (M+H).

### Synthesis of Compound La083

Referring to the synthesis and purification methods of compound La004, it was only necessary to change the corresponding raw materials to obtain the target compound La083 (14.63 g, purity: 99.90%, yield: 84.26%), with a mass spectrum: 396.16 (M+H).

### Synthesis of Compound Ir(La083)₂(Lb005)

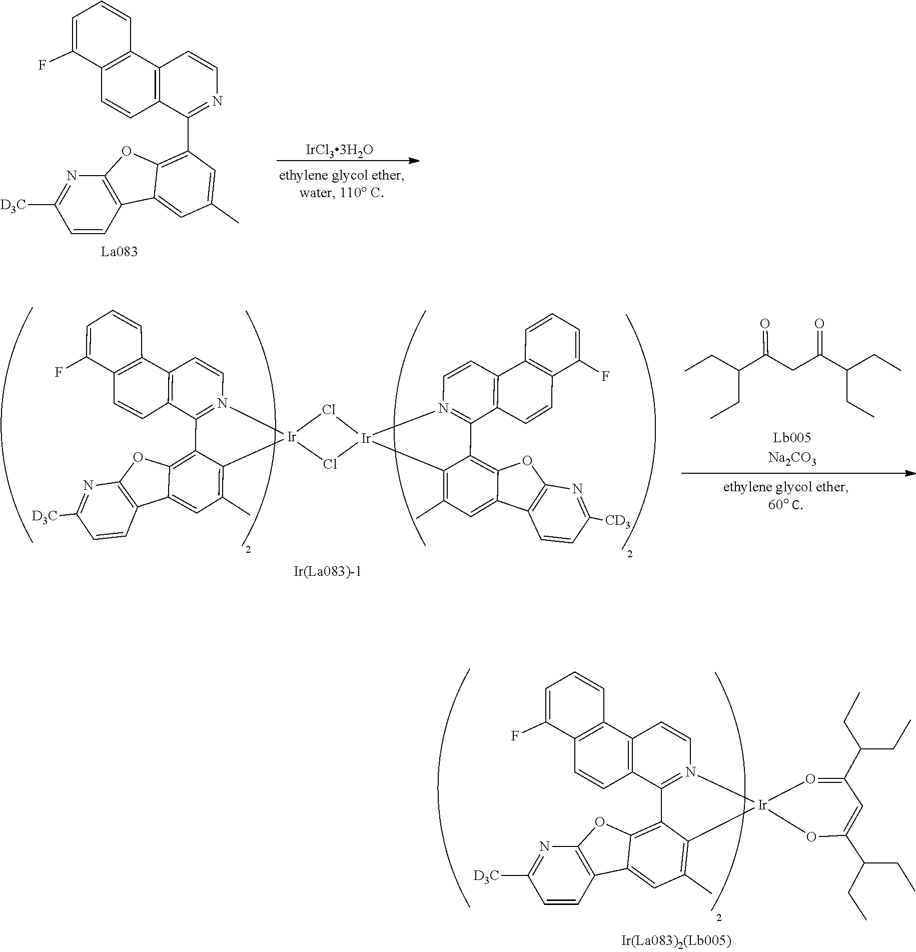

### Synthesis of Compound Ir(La083)-1

Referring to the synthesis and purification methods of compound Ir(La083)-1, it was only necessary to change the corresponding raw materials to obtain the compound Ir(La083)-1 (12.77 g, yield: 77.01%). The obtained compound was used directly in the next step without purification.

### Synthesis of Compound Ir(La083)₂(Lb005)

Referring to the synthesis and purification methods of compound Ir(La004)₂(Lb005), it was only necessary to change the corresponding raw materials to obtain the compound Ir(La083)₂(Lb005) as a red solid (4.51 g, purity: 99.81%, yield: 52.11%). 4.51 g of crude Ir(La083)₂(Lb005) was purified by sublimation to obtain sublimation-purified Ir(La083)₂(Lb005) (2.83 g, purity: 99.78%, yield: 62.75%), with a mass spectrum: 1193.42 (M+H).

¹H NMR (400 MHz, CDCl₃) δ 8.25 (dd, J=7.5, 0.7 Hz, 2H), 8.20 (d, J=9.6 Hz, 2H), 8.17 (d, J=4.3 Hz, 3H), 8.15 (s, 1H), 8.05-7.99 (m, 4H), 7.56-7.49 (m, 2H), 7.28-7.23 (m, 2H), 7.16 (d, J=9.5 Hz, 2H), 6.66 (d, J=7.7 Hz, 2H), 4.79 (s, 1H), 2.73-2.63 (m, 2H), 2.27 (s, 6H), 1.76-1.51 (m, 4H), 1.51-1.26 (m, 4H), 0.90-0.80 (m, 12H).

### Synthesis of Ligand La096

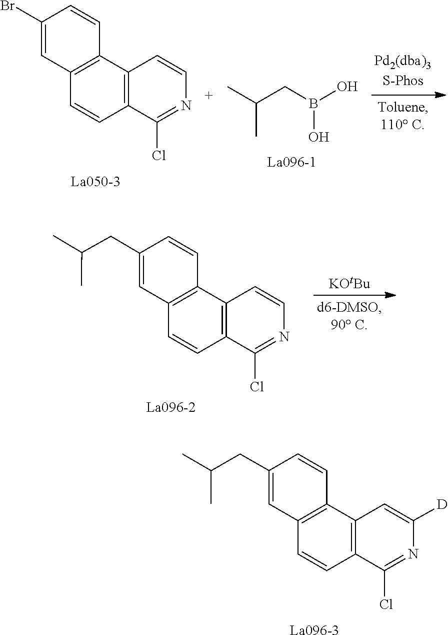

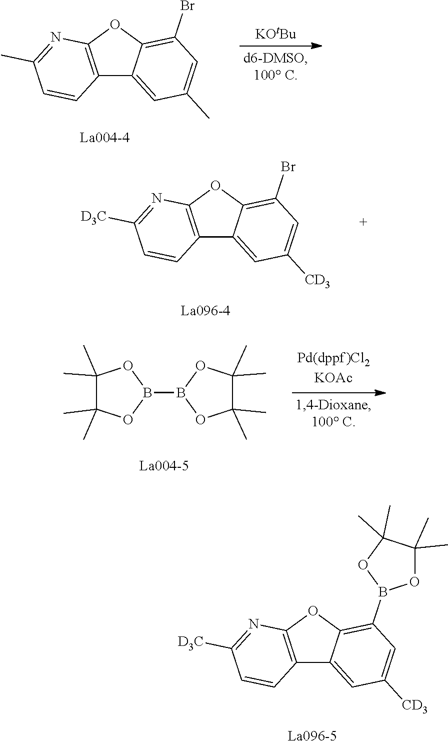

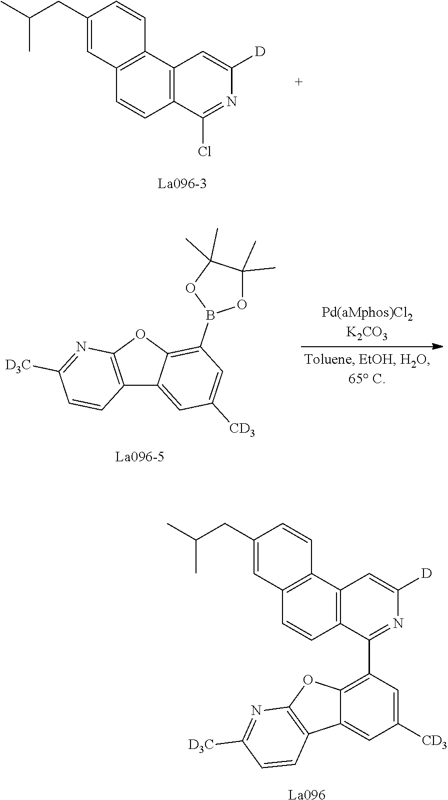 [SMILES: [2H]c1cc2c(ccc3cc(CC(C)C)ccc32)c(Cl)n1 ; "La096-3" ; [2H]C([2H])([2H])c1cc(B2OC(C)(C)C(C)(C)O2)c2oc3nc(C([2H])([2H])[2H])ccc3c2c1 ; "La096-5" ; [2H]c1cc2c(ccc3cc(CC(C)C)ccc32)c(-c2cc(C([2H])([2H])[2H])cc3c2oc2nc(C([2H])([2H])[2H])ccc23)n1 ; "La096"]

### Synthesis of Compound La096-2

Compound La050-3 (20.00 g, 68.36 mmol), La096-1 (13.94 g, 136.72 mmol), tris(dibenzylideneacetone)dipalladium (1.25 g, 1.37 mmol), 2-dicyclohexylphosphino-2′,6′-dimethoxy-biphenyl (1.13 g, 2.74 mmol), potassium phosphate (29.02 g, 136.72 mmol), and toluene (400 ml) were added to a 1000 ml three-necked round-bottom flask, and the system was replaced with nitrogen under vacuum for three times, then the mixture was stirred at 110° C. for 4 hours under the protection of nitrogen. The raw material La050-3 was reacted completely via TLC monitoring (with developing solvent of ethyl acetate:n-hexane=1:10).

The mixture was cooled to room temperature, then ethyl acetate (300 ml) was added and washed with deionized water (3*250 ml), the liquids were separated, the organic phase was concentrated and then subjected to silica gel column chromatography (200-300 mesh silica gel, with an eluent of ethyl acetate:n-hexane=1:20), after elution, it was concentrated under reduced pressure at 65° C. for 2 hours to obtain compound La096-2 as a white sugar-like solid (13.10 g, purity: 99.73%, yield: 71.01%), with a mass spectrum: 270.12 (M+H).

### Synthesis of Compound La096-3

Referring to the synthesis and purification methods of compound La021-5, it was only necessary to change the corresponding raw materials to obtain the target compound La096-3 (12.11 g, purity: 99.87%, deuterated ratio: 99.46%, yield: 95.78%), with a mass spectrum: 271.10 (M+H).

### Synthesis of Compound La096-4

Referring to the synthesis and purification methods of compound La021-5, it was only necessary to change the corresponding raw materials, the temperature was at 100° C., and reacted in a closed state for 48 hours, to obtain the target compound La096-4 (18.88 g, purity: 99.72%, deuterated ratio of six Ds: 99.21%, yield: 94.62%), with a mass spectrum: 282.03 (M+H).

### Synthesis of Compound La096-5

Referring to the synthesis and purification methods of compound La004-6, it was only necessary to change the corresponding raw materials to obtain the target compound La096-5 (17.05 g, purity: 99.00%, yield: 79.06%), with a mass spectrum: 330.22 (M H).

### Synthesis of Compound La096

Referring to the synthesis and purification methods of compound La004, it was only necessary to change the corresponding raw materials to obtain the target compound La096 (10.88 g, purity: 99.90%, yield: 84.66%), with a mass spectrum: 438.16 (M+H).

### Synthesis of Compound Ir(La096)₂(Lb005)

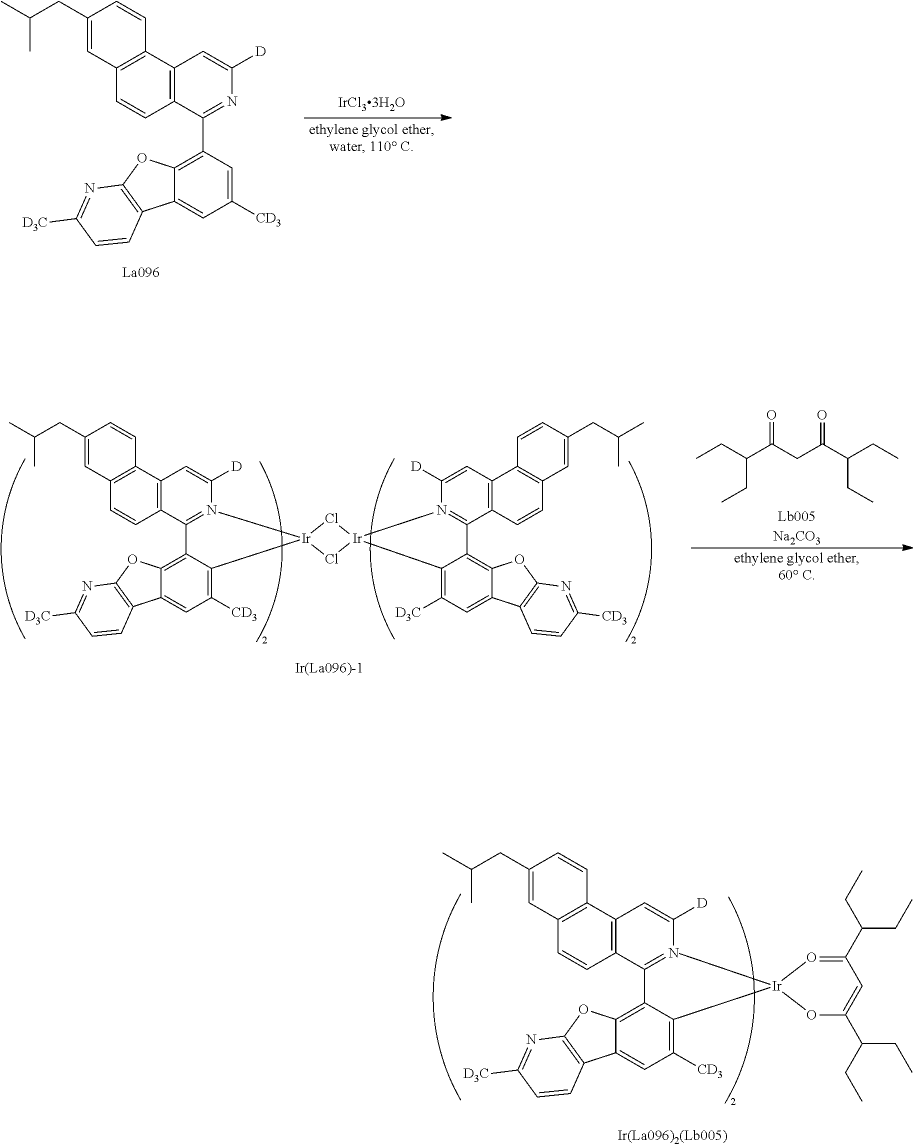

### Synthesis of Compound Ir(La096)-1

Referring to the synthesis and purification methods of compound Ir(La004)-1, it was only necessary to change the corresponding raw materials to obtain the compound Ir(La096)-1 (10.52 g, yield: 79.85%). The obtained compound was used directly in the next step without purification.

### Synthesis of Compound Ir(La096)₂(Lb005)

Referring to the synthesis and purification methods of compound Ir(La004)₂(Lb005), it was only necessary to change the corresponding raw materials to obtain the compound Ir(La096)₂(Lb005) as a red solid (4.12 g, purity: 99.88%, yield: 53.54%). 4.12 g of crude Ir(La096)₂(Lb005) was purified by sublimation to obtain sublimation-purified Ir(La096)₂(Lb005) (2.41 g, purity: 99.86%, yield: 58.50%), with a mass spectrum: 1277.61 (M+H).

¹H NMR (400 MHz, CDCl₃) δ 8.40 (s, 2H), 8.00 (dd, J=14.9, 8.1 Hz, 4H), 7.89-7.79 (m, 4H), 7.60 (s, 2H), 7.49-7.47 (m, 2H), 7.22-7.19 (m, 2H), 6.66 (d, J=7.7 Hz, 2H), 4.81 (s, 1H), 2.74-2.66 (m, 2H), 2.62 (dt, J=7.1, 0.9 Hz, 4H), 1.96-1.88 (m, 2H), 1.68-1.54 (m, 4H), 1.43-1.28 (m, 4H), 0.92-0.84 (m, 24H).

### Synthesis of Ligand La121

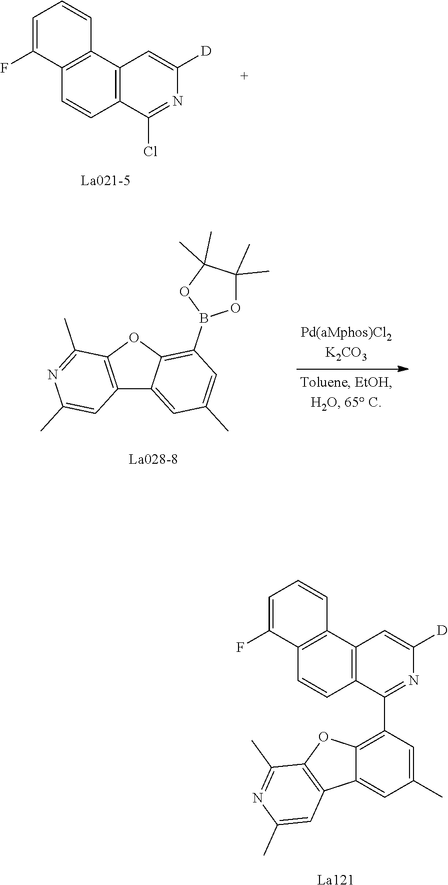

### Synthesis of Compound La121

Referring to the synthesis and purification methods of compound La004, it was only necessary to change the corresponding raw materials to obtain the target compound La121 (15.77 g, purity: 99.86%, yield: 85.82%), with a mass spectrum: 408.25 (M+H).

### Synthesis of Compound Ir(La121)₂(Lb005)

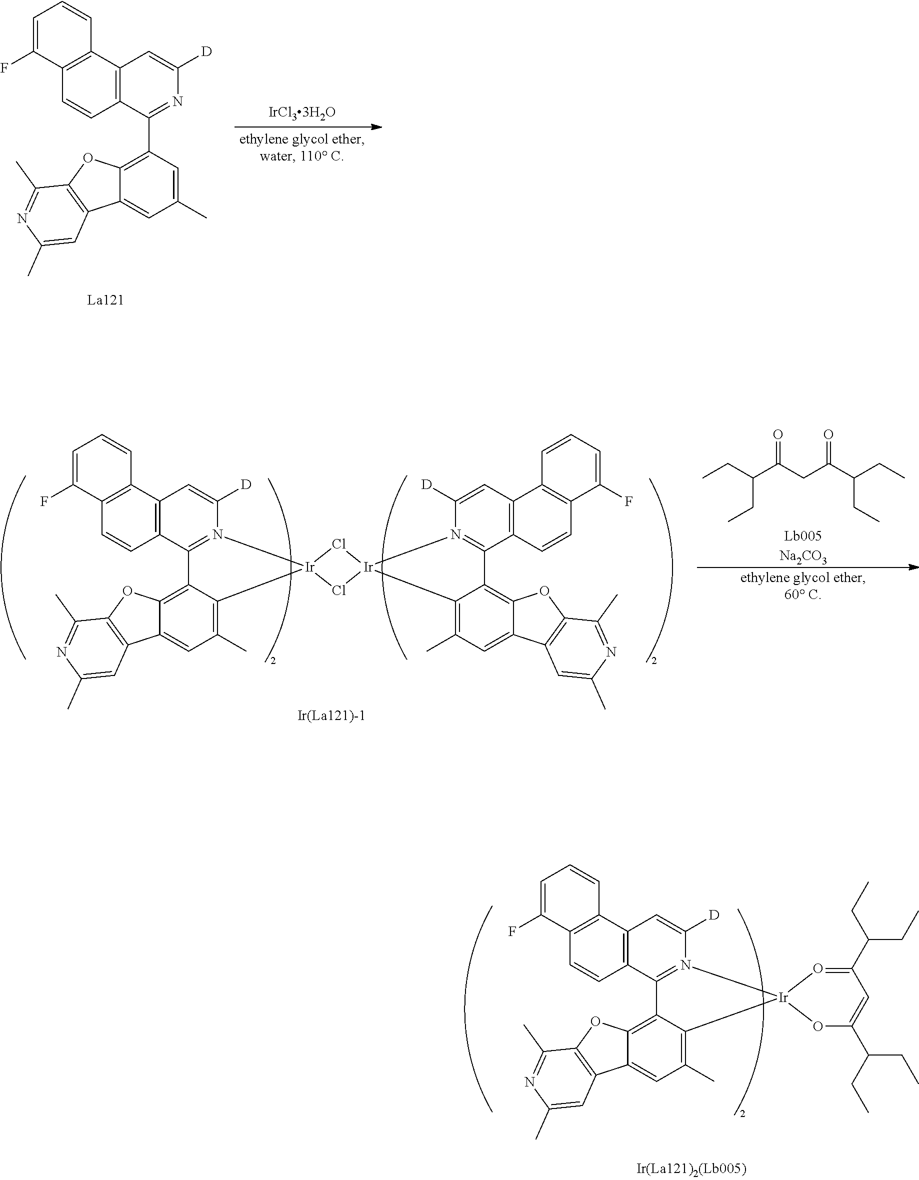

### Synthesis of Compound Ir(La121)-1

Referring to the synthesis and purification methods of compound Ir(La004)-1, it was only necessary to change the corresponding raw materials to obtain the compound Ir(La121)-1 (14.622 g, yield: 79.52%). The obtained compound was used directly in the next step without purification.

### Synthesis of Compound Ir(La121)₂(Lb005)

Referring to the synthesis and purification methods of compound Ir(La004)₂(Lb005), it was only necessary to change the corresponding raw materials to obtain the compound Ir(La121)₂(Lb005) as a red solid (5.95 g, purity: 99.76%, yield: 50.63%). 5.93 g of crude Ir(La121)₂(Lb005) was purified by sublimation to obtain sublimation-purified Ir(La121)₂(Lb005) (3.88 g, purity: 99.74%, yield: 65.43%), with a mass spectrum: 1217.44 (M+H).

¹H NMR (400 MHz, CDCl₃) δ 8.35-8.30 (m, 2H), 8.23-8.13 (m, 4H), 8.12 (d, J=0.8 Hz, 2H), 7.64 (s, 2H), 7.53 (t, J=7.5 Hz, 2H), 7.48 (d, J=0.8 Hz, 2H), 7.30-7.23 (m, 2H), 4.79 (s, 1H), 2.76-2.67 (m, 2H), 2.45 (d, J=16.3 Hz, 12H), 2.27 (s, 6H), 1.68-1.52 (m, 4H), 1.44-1.25 (m, 4H), 0.89-0.85 (m, 12H).

### Synthesis of Compound Ir(La121)₂(Lb043)

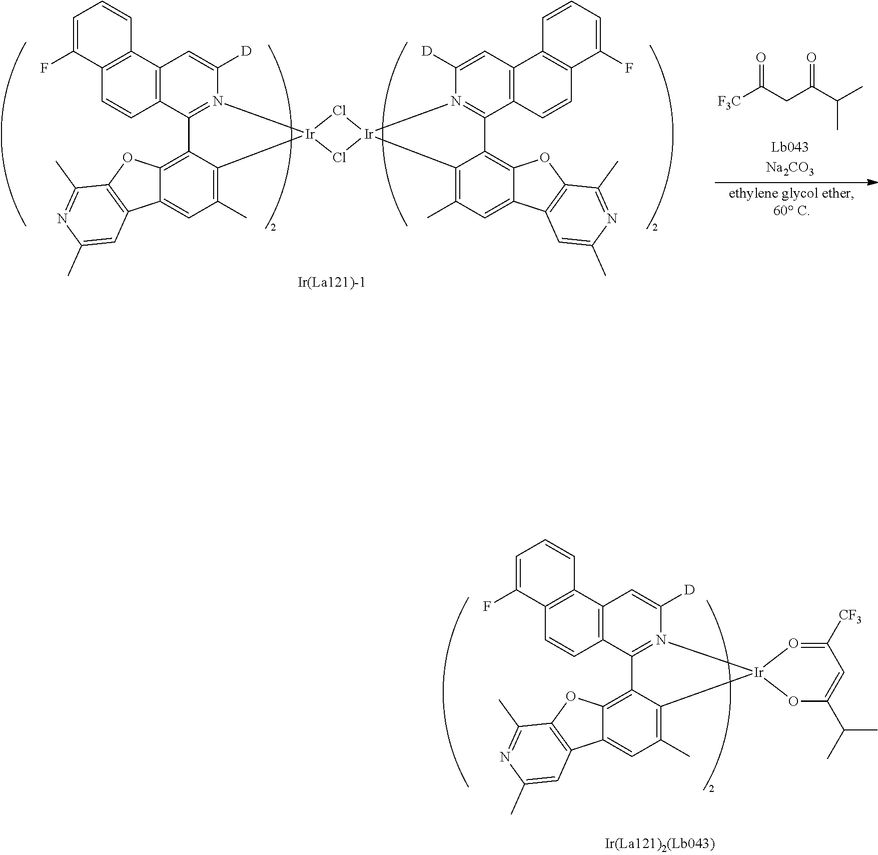

### Synthesis of Compound Ir(La121)₂(Lb043)

Referring to the synthesis and purification methods of compound Ir(La004)₂(Lb005), it was only necessary to change the corresponding raw materials to obtain the compound Ir(La121)₂(Lb043) as a red solid (5.24 g, purity: 99.80%, yield: 52.22%). 5.24 g of crude Ir(La121)₂(Lb043) was purified by sublimation to obtain sublimation-purified Ir(La121)₂(Lb043) (4.00 g, purity: 99.79%, yield: 76.34%), with a mass spectrum: 1187.30 (M+H).

¹H NMR (400 MHz, CDCl₃) δ 8.34-8.30 (m, 2H), 8.21-8.14 (m, 4H), 8.12 (d, J=0.8 Hz, 2H), 7.64 (s, 2H), 7.53 (t, J=7.5 Hz, 2H), 7.48 (d, J=0.8 Hz, 2H), 7.28-7.23 (m, 2H), 4.64 (s, 1H), 2.78-2.73 (m, 1H), 2.45 (d, J=16.3 Hz, 12H), 2.27 (s, 6H), 1.05 (d, J=6.8 Hz, 6H).

### Synthesis of Ligand La132

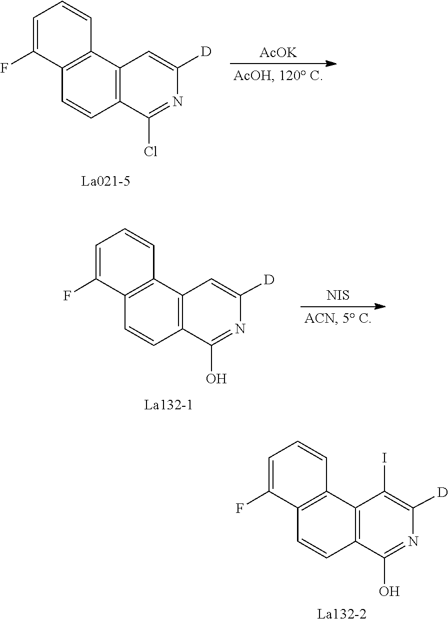

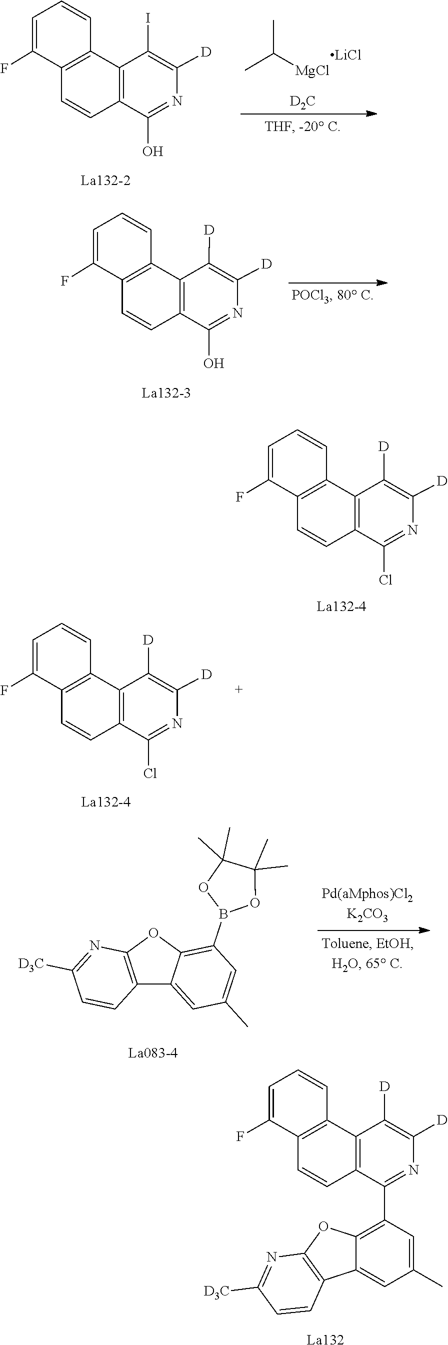

### Synthesis of Compound La132-1

Compound La021-5 (30.00 g, 128.94 mmol), potassium acetate (25.31 g, 257.89 mmol), and glacial acetic acid (450 ml) were added into a 1000 ml three-necked round-bottom flask, and the system was replaced with nitrogen under vacuum for three times, then the mixture was stirred at an oil temperature of 120° C. for 12 hours under the protection of nitrogen. The raw material La021-5 was reacted completely via TLC monitoring (with developing solvent of ethyl acetate:n-hexane=1:10).

The mixture was cooled to room temperature, and deionized water (600 ml) was added to precipitate a white solid. The mixture was stirred at room temperature for 1 hour, suction filtered, the filter cake was washed with deionized water (500 ml), then vacuum dried at 80° C. for 2 hours to obtain 27 g of a light yellow solid, which was crystallized twice with toluene and methanol and vacuum dried at 80° C. for 12 hours to obtain compound La132-1 as a white solid (23.29 g, purity: 99.43%, yield: 84.33%), with a mass spectrum: 215.20 (M+H).

### Synthesis of Compound La132-2

Compound La132-1 (20.00 g, 93.36 mmol) and acetonitrile (300 ml) were added to a 1000 ml three-necked round-bottom flask, and the system was replaced with nitrogen under vacuum for three times, the inner temperature of the system was reduced to 5° C. with an ice bath under the protection of nitrogen, then N-iodosuccinimide (23.10 g, 102.69 mmol) was slowly added over 5 minutes, the temperature was maintained at 5° C. in an ice bath and reacted for 1 hour, the raw material La132-1 was monitored to react completely by TLC (with developing solvent: ethyl acetate:n-hexane=1:1).

After the reaction was completed, the mixture was directly suction filtered, and the filter cake was crystallized twice with ethanol and vacuum dried at 70° C. for 12 hours to obtain compound La132-2 as a light yellow solid (27.54 g, purity: 99.23%, yield: 86.74%), with a mass spectrum: 341.11 (M+H).

### Synthesis of Compound La132-3

Compound La132-2 (20.00 g, 58.80 mmol) and dry tetrahydrofuran (300 ml) were added to a 1000 ml three-necked round-bottom flask, and the system was replaced with nitrogen under vacuum for three times, the inner temperature of the system was reduced to −20° C. with a liquid nitrogen ethanol bath under the protection of nitrogen, then isopropylmagnesium chloride·lithium chloride solution (54.30 ml, 70.56 mmol, 1.3 mol/L of tetrahydrofuran solution) was slowly added dropwise over 10 minutes, the inner temperature was maintained at −20° C. and stirred for 1 hour, then deuterated water (2.36 g, 117.60 mmol) was added, and the temperature was naturally raised to room temperature and stirred for 1 hour, the raw material La132-2 was monitored to react completely by TLC (with developing solvent: ethyl acetate:n-hexane=1:10). 20 g of diatomaceous earth was laid, and the reaction solution was suction filtered, the filter cake was rinsed with dichloromethane (500 ml), and the filtrates were combined and concentrated under reduced pressure to remove the solvent, a large amount of white solid was precipitated, which was suction filtered on a filter paper, the filter cake was washed with deionized water (500 ml) and crystallized twice with toluene and methanol, then vacuum dried at 80° C. for 12 hours to obtain compound La132-3 as a white solid (11.21 g, purity: 99.75%, yield: 88.54%), with a mass spectrum: 216.06 (M+H).

### Synthesis of Compound La132-4

Compound La132-3 (10.00 g, 46.46 mmol) and phosphorus oxychloride (70 ml) were added to a 250 ml three-necked round-bottom flask, and the system was replaced with nitrogen under vacuum for three times, then the system was raised to 80° C. under the protection of nitrogen and reacted for 3 hours, the raw material La132-3 was monitored to react completely by TLC (with developing solvent: ethyl acetate:n-hexane=1:15).

The reaction solution was then slowly added dropwise to 1000 ml of deionized water at 50° C., after the quenching was completed, a large amount of solid was precipitated, which was suction filtered to obtain a light yellow solid; then, it was subjected to silica gel column chromatography (200-300 mesh silica gel, with an eluent of ethyl acetate:n-hexane=1:25), after elution, it was concentrated at 65° C. for 2 hours to obtain compound La132-4 as a white solid (9.23 g, purity: 99.80%, yield: 85.00%), with a mass spectrum: 234.67 (M+H).

### Synthesis of Compound La132

Referring to the synthesis and purification methods of compound La004, it was only necessary to change the corresponding raw materials to obtain the target compound La132 (12.66 g, purity: 99.82%, yield: 81.87%), with a mass spectrum: 398.16 (M+H).

### Synthesis of Compound Ir(La132)₂(Lb005)

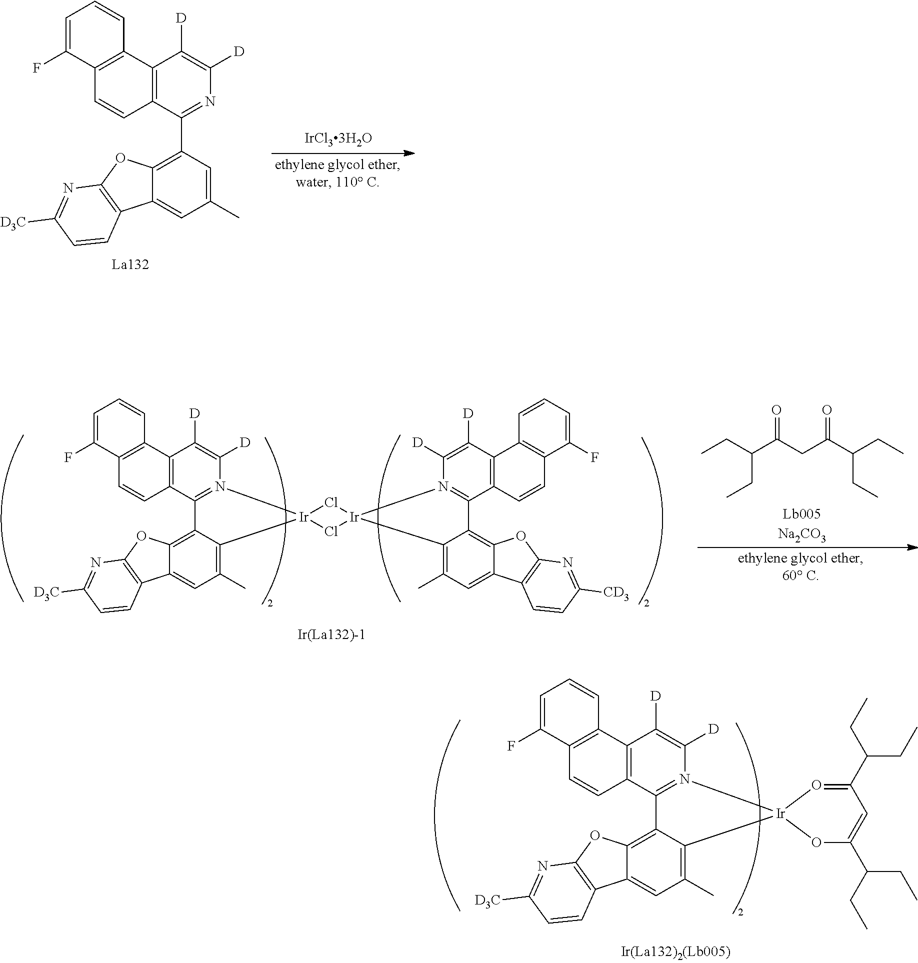

### Synthesis of Compound Ir(La132)-1

Referring to the synthesis and purification methods of compound Ir(La004)-1, it was only necessary to change the corresponding raw materials to obtain the compound Ir(La132)-1 (12.11 g, yield: 76.66%). The obtained compound was used directly in the next step without purification.

### Synthesis of Compound Ir(La132)₂(Lb005)

Referring to the synthesis and purification methods of compound Ir(La004)₂(Lb005), it was only necessary to change the corresponding raw materials to obtain the compound Ir(La132)₂(Lb005) as a red solid (5.00 g, purity: 99.85%, yield: 53.52%). 5.00 g of crude Ir(La132)₂(Lb005) was purified by sublimation to obtain sublimation-purified Ir(La132)₂(Lb005) (3.55 g, purity: 99.81%, yield: 71.00%), with a mass spectrum: 1197.20 (M+H).

¹H NMR (400 MHz, CDCl₃) δ 8.44 (dt, J=7.5, 0.6 Hz, 2H), 8.26 (d, J=9.7 Hz, 2H), 8.17 (d, J=0.8 Hz, 2H), 8.02 (d, J=7.7 Hz, 2H), 7.92 (d, J=9.7 Hz, 2H), 7.43-7.36 (m, 2H), 7.25 (dt, J=7.6, 0.7 Hz, 2H), 6.66 (d, J=7.7 Hz, 2H), 4.81 (s, 1H), 2.71-2.68 (m, 2H), 2.27 (s, 6H), 1.68-1.54 (m, 4H), 1.43-1.28 (m, 4H), 0.88-0.84 (m, 12H).

### Synthesis of Compound La133

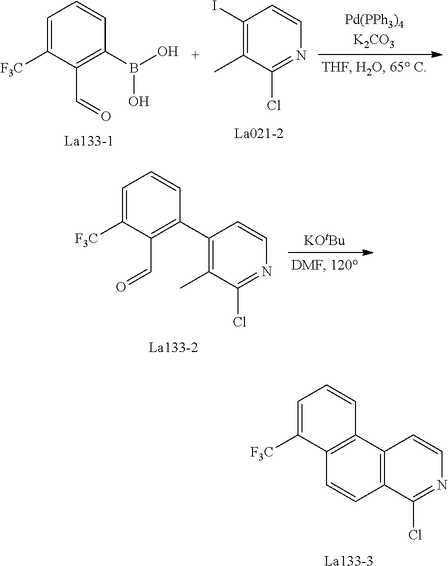

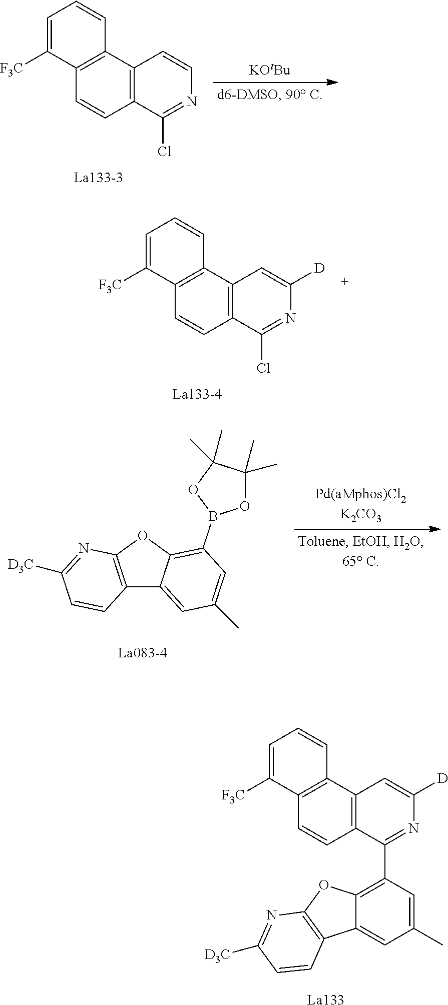

### Synthesis of Compound La133-2

Referring to the synthesis and purification methods of compound La021-3, it was only necessary to change the corresponding raw materials to obtain the target compound La133-2 (20.56 g, purity: 99.81%, yield: 85.82%), with a mass spectrum: 300.03 (M+H).

### Synthesis of Compound La133-3

Referring to the synthesis and purification methods of compound La021-4, it was only necessary to change the corresponding raw materials to obtain the target compound La133-3 (19.09 g, purity: 99.53%, yield: 67.08%), with a mass spectrum: 282.22 (M+H).

### Synthesis of Compound La133-4

Referring to the synthesis and purification methods of compound La021-5, it was only necessary to change the corresponding raw materials to obtain the target compound La133-4 (17.62 g, purity: 99.81%, deuterated ratio: 99.46%, yield: 95.63%), with a mass spectrum: 283.23 (M+H).

### Synthesis of Compound La133

Referring to the synthesis and purification methods of compound La004, it was only necessary to change the corresponding raw materials to obtain the target compound La133 (14.55 g, purity: 99.87%, yield: 82.41%), with a mass spectrum: 447.15 (M+H).

### Synthesis of Compound Ir(La133)₂(Lb005)

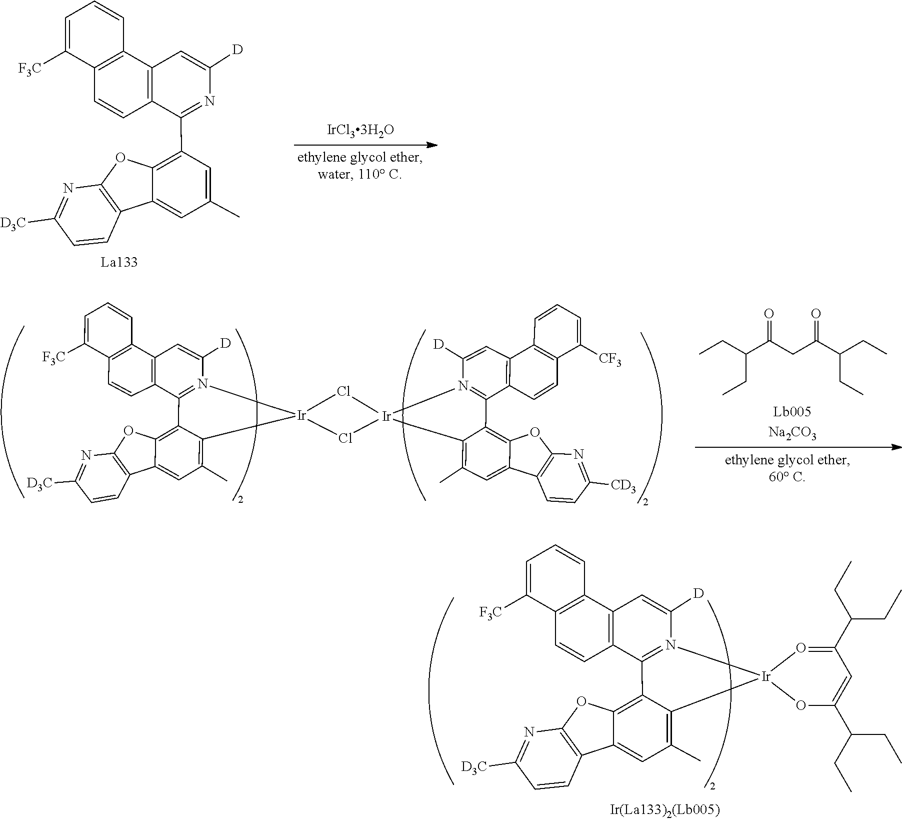

### Synthesis of Compound Ir(La133)-1

Referring to the synthesis and purification methods of compound Ir(La004)-1, it was only necessary to change the corresponding raw materials to obtain the compound Ir(La133)-1 (14.33 g, yield: 74.85%). The obtained compound was used directly in the next step without purification.

### Synthesis of Compound Ir(La133)₂(Lb005)

Referring to the synthesis and purification methods of compound Ir(La004)₂(Lb005), it was only necessary to change the corresponding raw materials to obtain the compound Ir(La133)₂(Lb005) as a red solid (6.52 g, purity: 99.80%, yield: 52.06%). 6.52 g of crude Ir(La133)₂(Lb005) was purified by sublimation to obtain sublimation-purified Ir(La133)₂(Lb005) (4.62 g, purity: 99.75%, yield: 70.86%), with a mass spectrum: 1295.43 (M+H).

¹H NMR (400 MHz, CDCl₃) δ 8.52-8.44 (m, 2H), 8.19-8.12 (m, 4H), 8.03 (dd, J=14.7, 7.8 Hz, 4H), 7.70-7.61 (m, 6H), 6.66 (d, J=7.7 Hz, 2H), 4.79 (s, 1H), 2.71-2.67 (m, 2H), 2.27 (s, 6H), 1.68-1.54 (m, 4H), 1.43-1.28 (m, 4H), 0.89-0.84 (m, 12H).

### Synthesis of Compound Ir(La133)₂(Lb007)

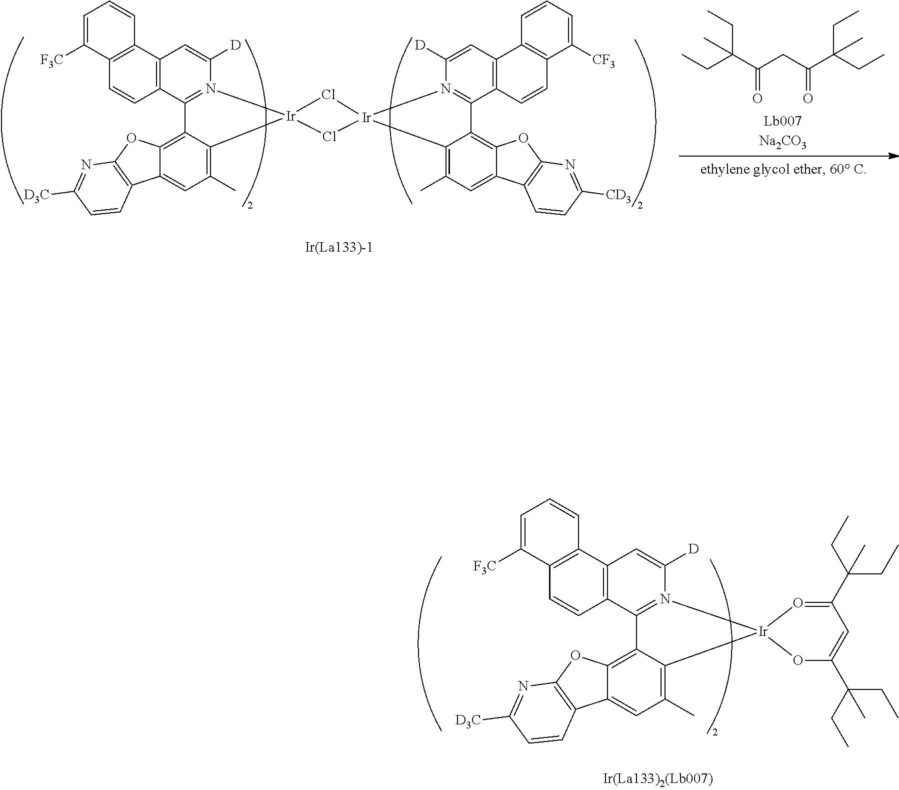

### Synthesis of Compound Ir(La133)₂(Lb007)

Referring to the synthesis and purification methods of compound Ir(La004)₂(Lb005), it was only necessary to change the corresponding raw materials to obtain the compound Ir(La133)₂(Lb007) as a red solid (4.77 g, purity: 99.85%, yield: 50.50%). 4.77 g of crude Ir(La133)₂(Lb007) was purified by sublimation to obtain sublimation-purified Ir(La133)₂(Lb007) (3.62 g, purity: 99.82%, yield: 75.89%), with a mass spectrum: 1323.46 (M+H).

¹H NMR (400 MHz, CDCl₃) δ 8.48 (dd, J=5.9, 2.7 Hz, 2H), 8.23-8.12 (m, 4H), 8.03 (dd, J=14.7, 7.8 Hz, 4H), 7.73-7.59 (m, 6H), 6.66 (d, J=7.7 Hz, 2H), 5.12 (s, 1H), 2.27 (s, 6H), 1.72-1.53 (m, 4H), 1.53-1.24 (m, 4H), 1.05 (d, J=15.2 Hz, 6H), 0.89-0.69 (m, 12H).

### Synthesis of Ligand La138

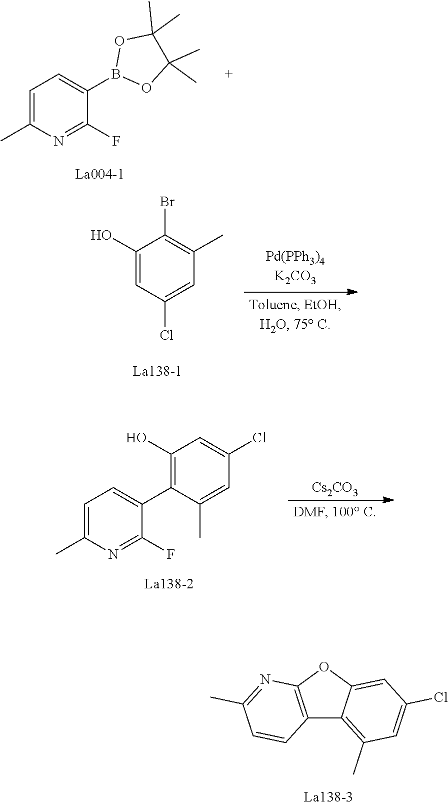

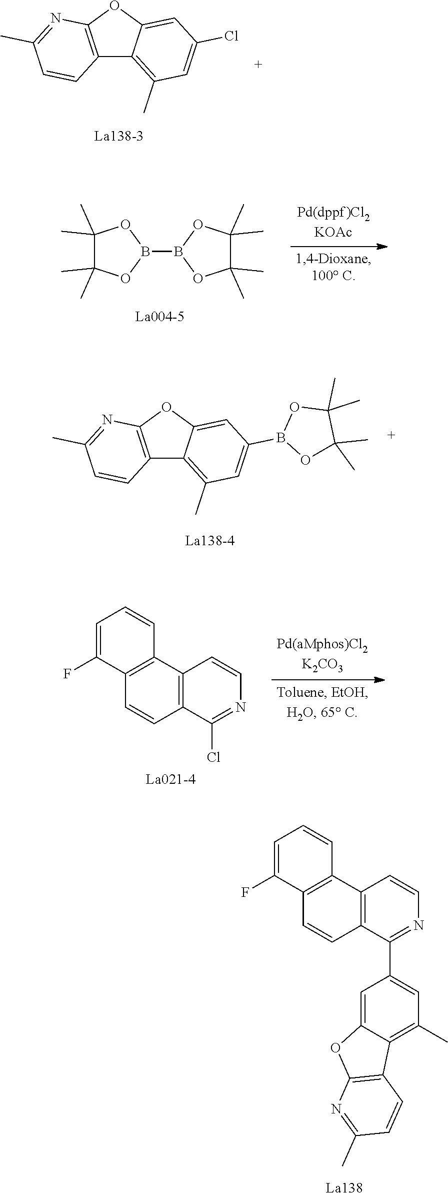

### Synthesis of Compound La138-2

Referring to the synthesis and purification methods of compound La004-3, it was only necessary to change the corresponding raw materials to obtain the target compound La138-2 (24.33 g, purity: 99.64%, yield: 75.05%), with a mass spectrum: 252.02 (M+H).

### Synthesis of Compound La138-3

Referring to the synthesis and purification methods of compound La004-4, it was only necessary to change the corresponding raw materials to obtain the target compound La183-3 (20.01 g, purity: 99.73%, yield: 67.77%), with a mass spectrum: 232.01 (M H).

### Synthesis of Compound La138-4

Referring to the synthesis and purification methods of compound La004-6, it was only necessary to change the corresponding raw materials to obtain the target compound La138-4 (17.86 g, purity: 99.21%, yield: 82.11%), with a mass spectrum: 324.24 (M+H).

### Synthesis of Compound La138

Referring to the synthesis and purification methods of compound La004, it was only necessary to change the corresponding raw materials to obtain the target compound La138 (12.06 g, purity: 99.87%, yield: 82.64%), with a mass spectrum: 393.20 (M+H).

### Synthesis of Compound Ir(La138)₂(Lb005)

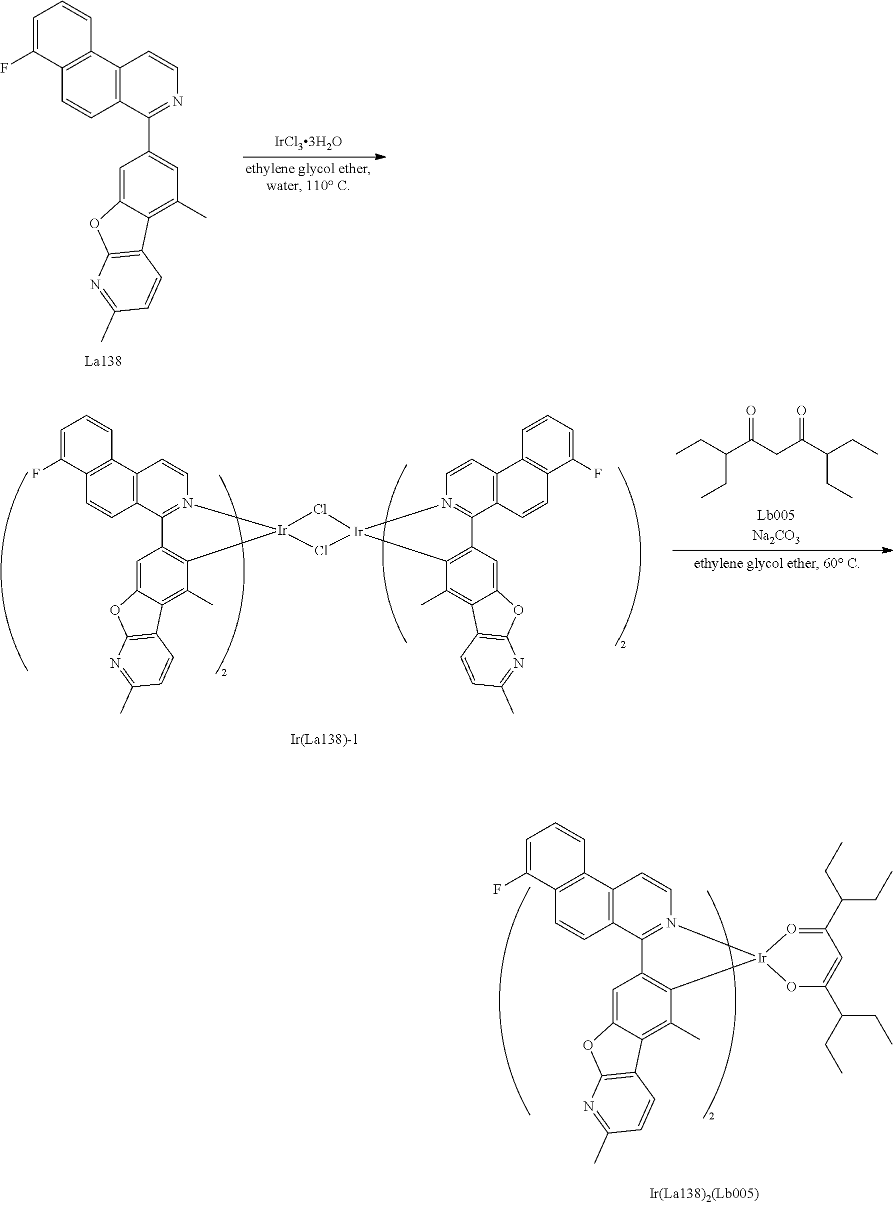

### Synthesis of Compound Ir(La138)-1

Referring to the synthesis and purification methods of compound Ir(La004)-1, it was only necessary to change the corresponding raw materials to obtain the compound Ir(La138)-1 (14.77 g, yield: 78.33%). The obtained compound was used directly in the next step without purification.

### Synthesis of Compound Ir(La138)₂(Lb005)

Referring to the synthesis and purification methods of compound Ir(La004)₂(Lb005), it was only necessary to change the corresponding raw materials to obtain the compound Ir(La138)₂(Lb005) as a red solid (4.52 g, purity: 99.87%, yield: 52.33%). 4.52 g of crude Ir(La138)₂(Lb005) was purified by sublimation to obtain sublimation-purified Ir(La138)₂(Lb005) (3.5 g, purity: 99.84%, yield: 77.44%), with a mass spectrum: 1187.40 (M+H).

¹H NMR (400 MHz, CDCl₃) δ 8.36 (s, 2H), 8.27-8.13 (m, 6H), 8.02 (d, J=9.7 Hz, 2H), 7.94 (d, J=7.9 Hz, 2H), 7.53 (t, J=7.6 Hz, 2H), 7.38 (d, J=9.3 Hz, 2H), 7.28-7.23 (m, 2H), 7.21-7.19 (m, 2H), 4.79 (s, 1H), 2.74-2.67 (m, 2H), 2.50-2.43 (m, 12H), 1.68-1.54 (m, 4H), 1.43-1.28 (m, 4H), 0.90-0.85 (m, 12H).

### Synthesis of Ligand La145

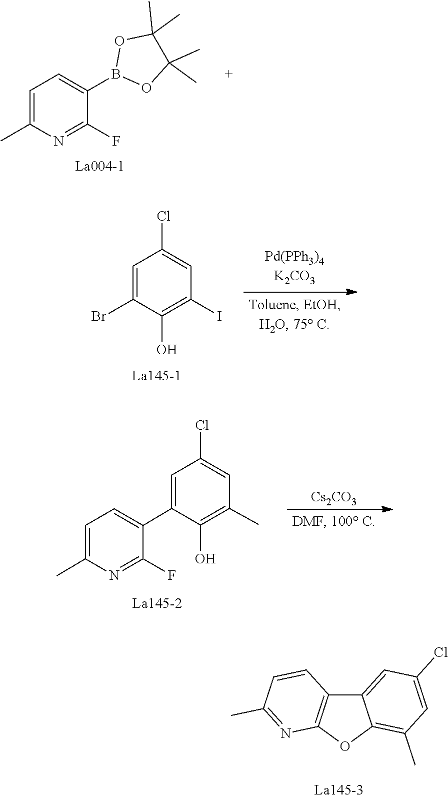

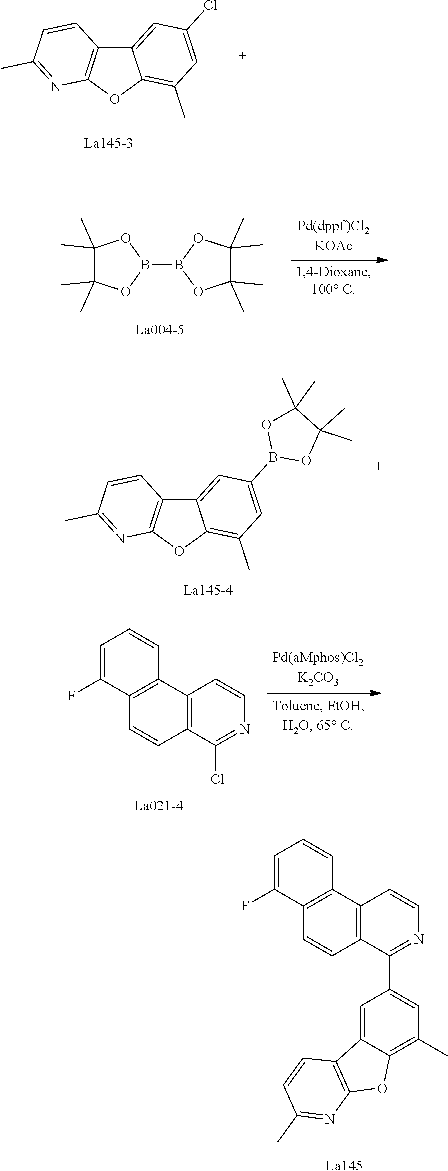

### Synthesis of Compound La145-2

Referring to the synthesis and purification methods of compound La004-3, it was only necessary to change the corresponding raw materials to obtain the target compound La145-2 (26.05 g, purity: 99.72%, yield: 76.33%), with a mass spectrum: 252.02 (M+H).

### Synthesis of Compound La145-3

Referring to the synthesis and purification methods of compound La004-4, it was only necessary to change the corresponding raw materials to obtain the target compound La145-3 (24.52 g, purity: 99.68%, yield: 67.98%), with a mass spectrum: 232.01 (M+H).

### Synthesis of Compound La145-4

Referring to the synthesis and purification methods of compound La004-6, it was only necessary to change the corresponding raw materials to obtain the target compound La145-4 (20.52 g, purity: 99.43%, yield: 83.41%), with a mass spectrum: 324.24 (M+H).

### Synthesis of Compound La145

Referring to the synthesis and purification methods of compound La004, it was only necessary to change the corresponding raw materials to obtain the target compound La145 (16.45 g, purity: 99.84%, yield: 83.33%), with a mass spectrum: 393.20 (M+H).

### Synthesis of Compound Ir(La145)₂(Lb005)

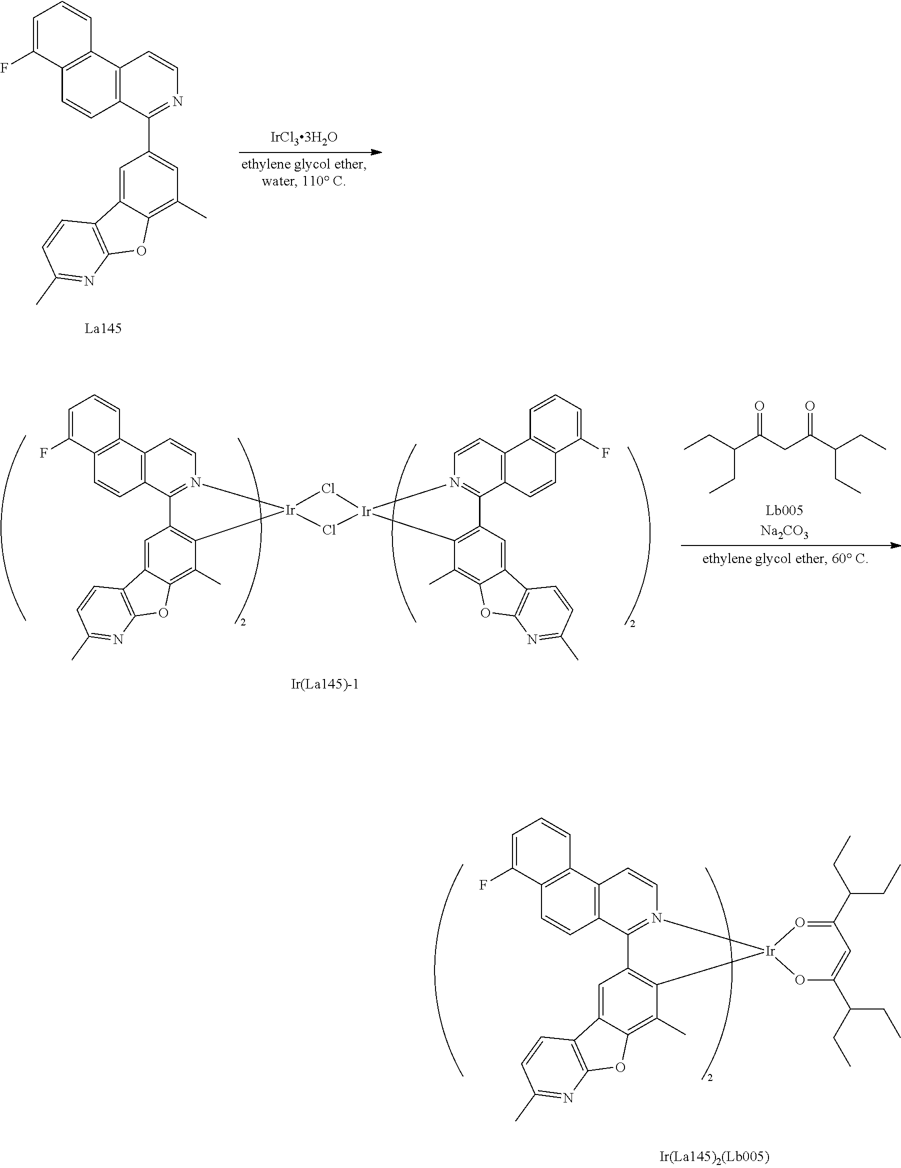

### Synthesis of Compound Ir(La145)-1

Referring to the synthesis and purification methods of compound Ir(La004)-1, it was only necessary to change the corresponding raw materials to obtain the compound Ir(La145)-1 (16.55 g, yield: 76.06%). The obtained compound was used directly in the next step without purification.

### Synthesis of Compound Ir(La145)₂(Lb005)

Referring to the synthesis and purification methods of compound Ir(La004)₂(Lb005), it was only necessary to change the corresponding raw materials to obtain the compound Ir(La145)₂(Lb005) as a red solid (5.63 g, purity: 99.86%, yield: 53.40%). 5.63 g of crude Ir(La145)₂(Lb005) was purified by sublimation to obtain sublimation-purified Ir(La145)₂(Lb005) (4.02 g, purity: 99.84%, yield: 71.41%), with a mass spectrum: 1187.40 (M+H).

¹H NMR (400 MHz, CDCl₃) δ 9.05 (s, 2H), 8.27-8.13 (m, 8H), 8.02 (d, J=9.7 Hz, 2H), 7.56-7.49 (m, 2H), 7.38 (d, J=9.3 Hz, 2H), 7.28-7.23 (m, 2H), 7.19-7.17 (m, 2H), 4.80 (s, 1H), 2.71-2.87 (m, 2H), 2.47-2.43 (m, 12H), 1.68-1.54 (m, 4H), 1.43-1.28 (m, 4H), 0.88-0.86 (m, 12H).

### Synthesis of Ligand La151

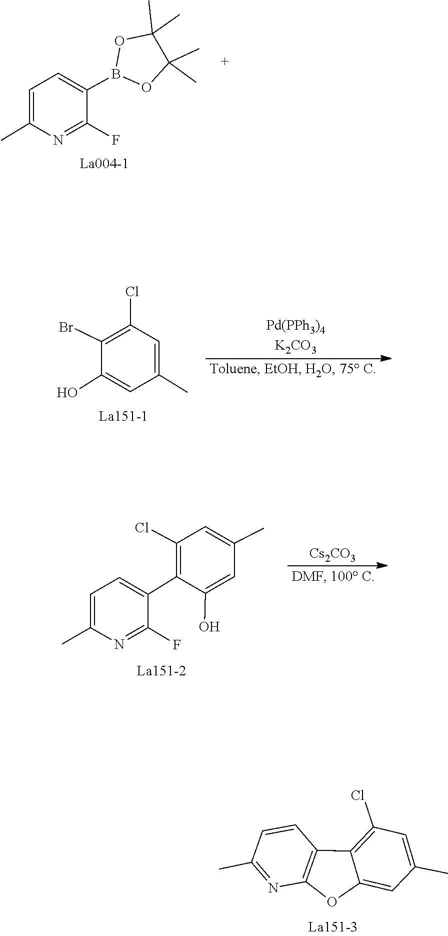

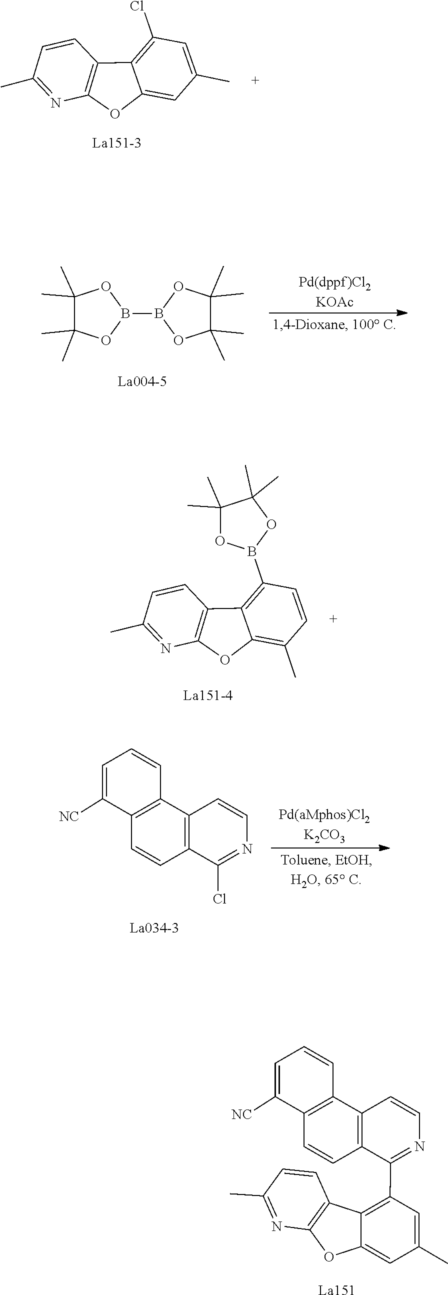

### Synthesis of Compound La151-2

Referring to the synthesis and purification methods of compound La004-3, it was only necessary to change the corresponding raw materials to obtain the target compound La151-2 (22.44 g, purity: 99.63%, yield: 75.06%), with a mass spectrum: 252.02 (M+H).

### Synthesis of Compound La151-3

Referring to the synthesis and purification methods of compound La004-4, it was only necessary to change the corresponding raw materials to obtain the target compound La151-3 (20.15 g, purity: 99.70%, yield: 68.08%), with a mass spectrum: 232.01 (M+H).

### Synthesis of Compound La151-4

Referring to the synthesis and purification methods of compound La004-6, it was only necessary to change the corresponding raw materials to obtain the target compound La151-4 (18.54 g, purity: 99.55%, yield: 80.15%), with a mass spectrum: 324.24 (M+H).

### Synthesis of Compound La151

Referring to the synthesis and purification methods of compound La004, it was only necessary to change the corresponding raw materials to obtain the target compound La151 (14.33 g, purity: 99.80%, yield: 84.15%), with a mass spectrum: 400.14 (M+H).

### Synthesis of Compound Ir(La151)₂(Lb005)

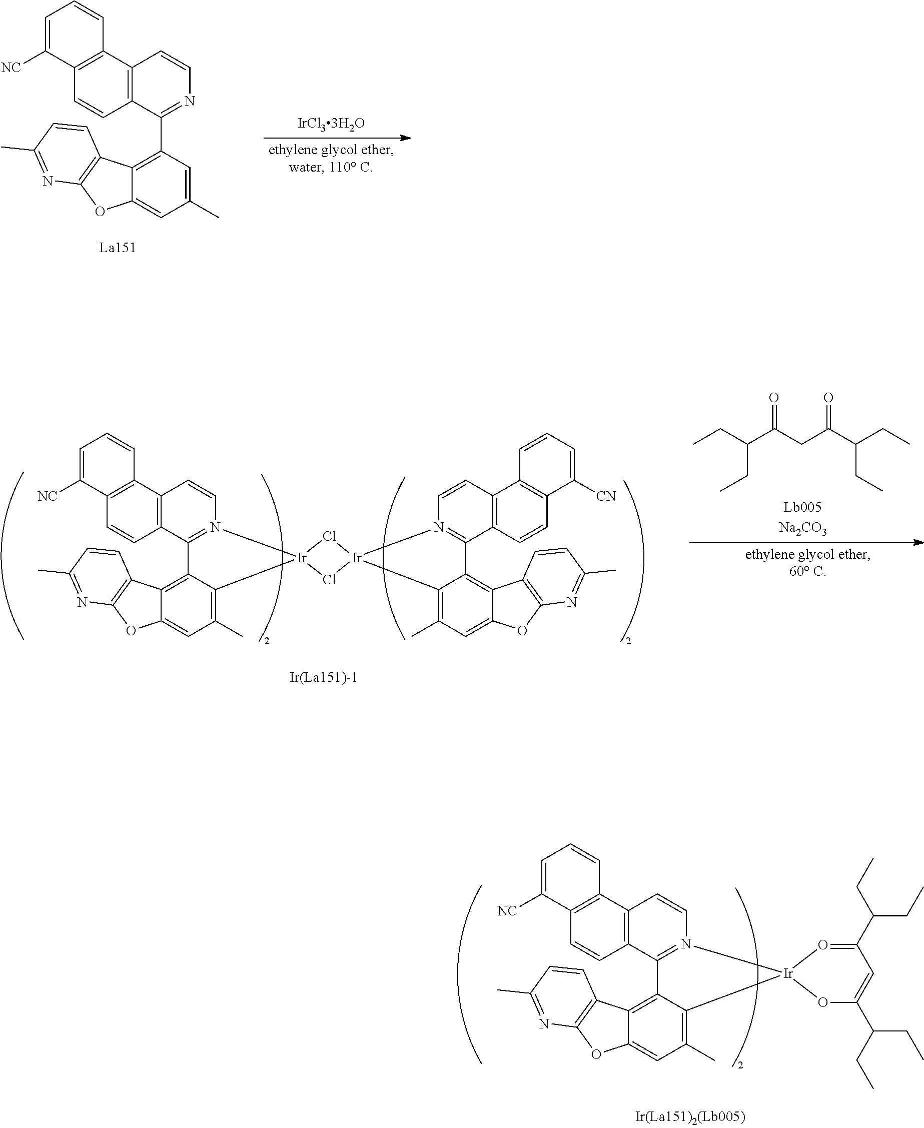

### Synthesis of Compound Ir(La151)-1

Referring to the synthesis and purification methods of compound Ir(La004)-1, it was only necessary to change the corresponding raw materials to obtain the compound Ir(La151)-1 (12.01 g, yield: 77.33%). The obtained compound was used directly in the next step without purification.

### Synthesis of Compound Ir(La151)₂(Lb005)

Referring to the synthesis and purification methods of compound Ir(La004)₂(Lb005), it was only necessary to change the corresponding raw materials to obtain the compound Ir(La151)₂(Lb005) as a red solid (4.21 g, purity: 99.83%, yield: 52.52%). 4.21 g of crude Ir(La151)₂(Lb005) was purified by sublimation to obtain sublimation-purified Ir(La151)₂(Lb005) (3.00 g, purity: 99.80%, yield: 71.26%), with a mass spectrum: 1199.42 (M+H).

¹H NMR (400 MHz, CDCl₃) δ 8.41 (dd, J=6.7, 1.1 Hz, 2H), 8.20 (d, J=9.4 Hz, 2H), 8.14-8.04 (m, 4H), 7.99 (d, J=8.2 Hz, 2H), 7.77-7.70 (m, 4H), 7.52 (t, J=6.6 Hz, 2H), 7.20-7.13 (m, 4H), 6.90-6.86 (m, 2H), 4.79 (s, 1H), 2.74-2.68 (m, 2H), 2.42 (s, 6H), 2.35 (d, J=0.9 Hz, 6H), 1.68-1.54 (m, 4H), 1.43-1.28 (m, 4H), 0.89-0.85 (m, 12H).

### Synthesis of Ligand La156

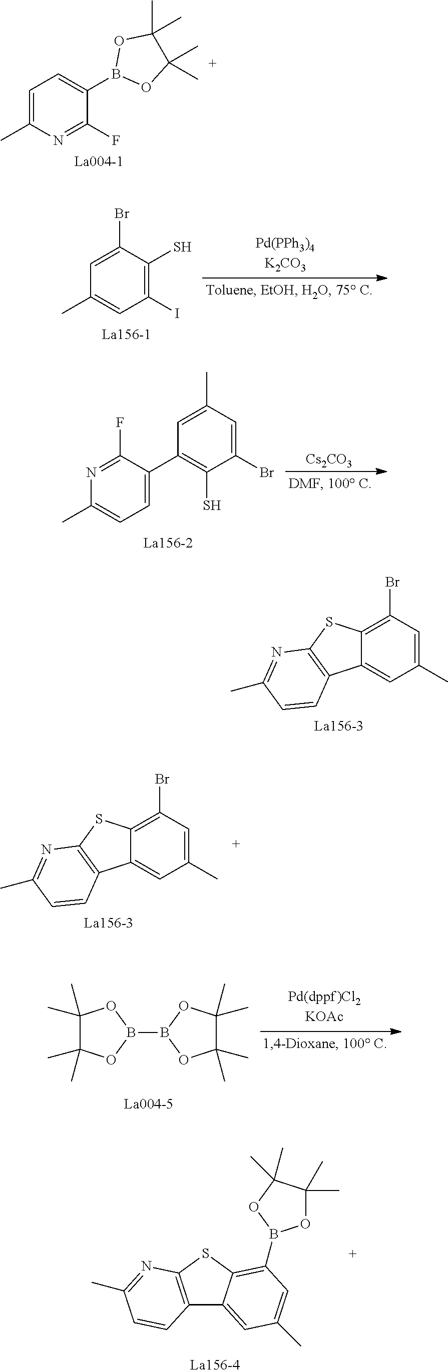

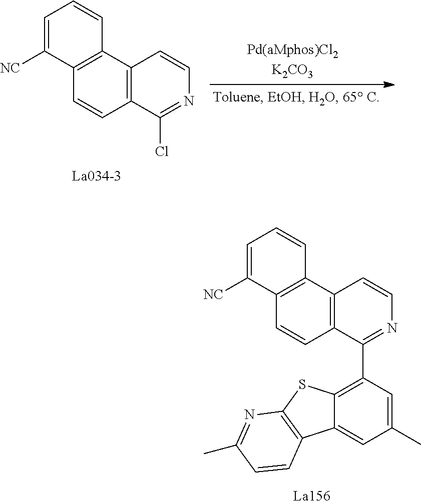

### Synthesis of Compound La156-2

Referring to the synthesis and purification methods of compound La004-3, it was only necessary to change the corresponding raw materials to obtain the target compound La156-2 (20.01 g, purity: 99.68%, yield: 72.85%), with a mass spectrum: 312.08 (M+H).

### Synthesis of Compound La156-3

Referring to the synthesis and purification methods of compound La004-4, it was only necessary to change the corresponding raw materials to obtain the target compound La156-3 (18.88 g, purity: 99.65%, yield: 69.98%), with a mass spectrum: 292.02 (M+H).

### Synthesis of Compound La156-4

Referring to the synthesis and purification methods of compound La004-6, it was only necessary to change the corresponding raw materials to obtain the target compound La156-4 (14.33 g, purity: 99.03%, yield: 78.88%), with a mass spectrum: 340.21 (M+H).

### Synthesis of Compound La156

Referring to the synthesis and purification methods of compound La004, it was only necessary to change the corresponding raw materials to obtain the target compound La156 (10.86 g, purity: 99.89%, yield: 81.09%), with a mass spectrum: 416.12 (M+H).

### Synthesis of Compound Ir(La156)₂(Lb005)

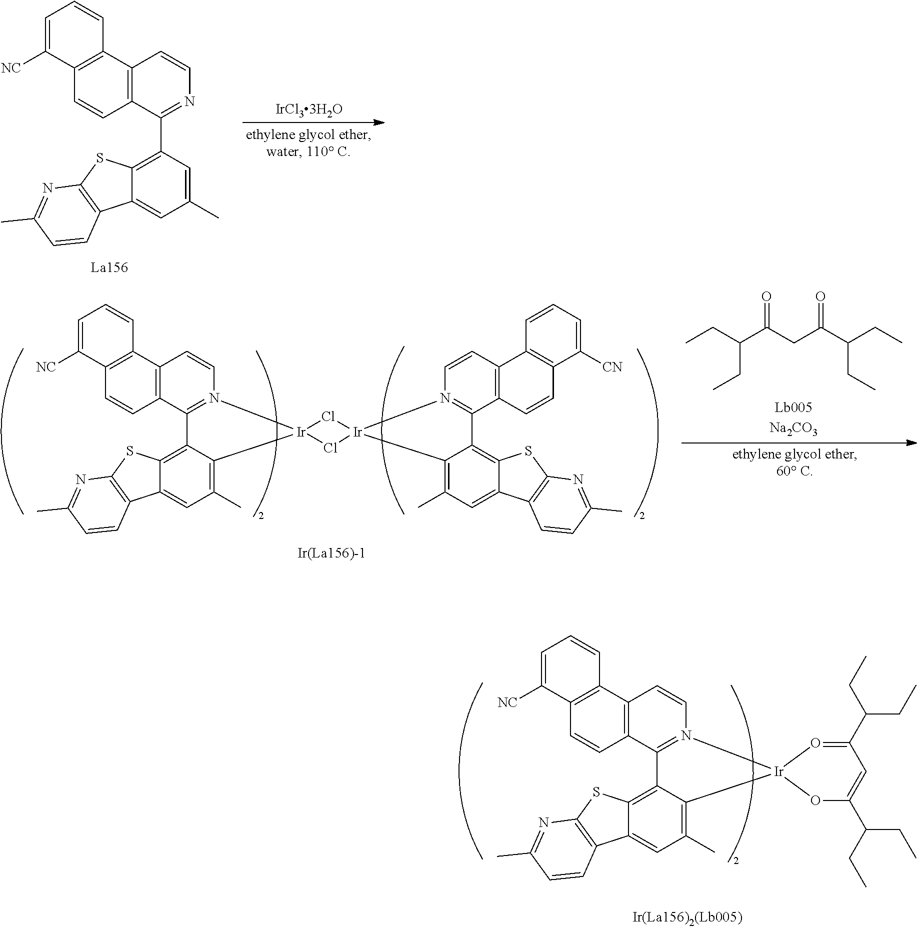

### Synthesis of Compound Ir(La156)-1

Referring to the synthesis and purification methods of compound Ir(La004)-1, it was only necessary to change the corresponding raw materials to obtain the compound Ir(La156)-1 (12.63 g, yield: 79.44%). The obtained compound was used directly in the next step without purification.

### Synthesis of Compound Ir(La156)₂(Lb005)

Referring to the synthesis and purification methods of compound Ir(La004)₂(Lb005), it was only necessary to change the corresponding raw materials to obtain the compound Ir(La156)₂(Lb005) as a red solid (4.00 g, purity: 99.85%, yield: 56.33%). 4.00 g of crude Ir(La156)₂(Lb005) was purified by sublimation to obtain sublimation-purified Ir(La156)₂(Lb005) (2.51 g, purity: 99.80%, yield: 62.75%), with a mass spectrum: 1233.24 (M+H).

¹H NMR (400 MHz, CDCl₃) δ 8.41 (dd, J=6.7, 1.1 Hz, 2H), 8.31 (d, J=0.8 Hz, 2H), 8.23-8.15 (m, 4H), 8.11 (d, J=8.6 Hz, 2H), 8.07 (d, J=8.6 Hz, 2H), 7.75-7.70 (m, 2H), 7.52 (t, J=6.6 Hz, 2H), 7.19-7.10 (m, 4H), 4.72 (s, 1H), 2.71-2.68 (m, 2H), 2.47 (d, J=0.7 Hz, 6H), 2.32 (s, 6H), 1.68-1.54 (m, 4H), 1.43-1.28 (m, 4H), 0.88-0.85 (m, 12H).

### Application Examples: Fabrication of Organic Electroluminescent Devices

A 50 mm*50 mm*1.0 mm of glass substrate with an ITO (1000 Å) anode electrode was ultrasonically cleaned in ethanol for 10 minutes, then oven dried at 150 degrees, and then treated with N₂ Plasma for 30 minutes. The washed glass substrate was mounted on the substrate holder of the vacuum evaporation device. First, the compound HTM1 and P-dopant (at a ratio of 97%:3%) were co-evaporated on the surface of the side where anode electrode lines were present in a way of covering the electrodes to form a film with a film thickness of 100 Å, followed by evaporation of a layer of HTM1 to form a film with a film thickness of about 600 Λ, and then evaporation of a layer of HTM2 on the HTM1 film to form a film with a film thickness of 100 Λ. Then, the host materials H1 and H2 and the dopant compound (at a ratio of 48.5%:48.5%:3%, comparative compound X, the compound of the present disclosure) were co-evaporated on the layer of the HTM2 film, with a film thickness of 400 Å, then ETL:LiQ (350 Å, at a ratio of 50%:50%) was co-evaporated on the light-emitting layer, and Yb (10 Å) was evaporated on the electron transfer layer material, finally a layer of metal iridium Ag (150 Å) was evaporated as the electrode.

| | | | | | Electron |
|---|---|---|---|---|---|
| Examples | HIL | HTL | EBL | Emitting layer | transfer layer |
| A1 | HTM1:NDP-9 | HTM1 | HTM2 | H1:H2:Ir(La004)₂(Lb005) | ETL:LiQ |
| A2 | HTM1:NDP-9 | HTM1 | HTM2 | H1:H2:Ir(La021)₂(Lb005) | ETL:LiQ |
| A3 | HTM1:NDP-9 | HTM1 | HTM2 | H1:H2:Ir(La028)₂(Lb005) | ETL:LiQ |
| A4 | HTM1:NDP-9 | HTM1 | HTM2 | H1:H2:Ir(La034)₂(Lb005) | ETL:LiQ |
| A5 | HTM1:NDP-9 | HTM1 | HTM2 | H1:H2:Ir(La034)₂(Lb007) | ETL:LiQ |
| A6 | HTM1:NDP-9 | HTM1 | HTM2 | H1:H2:Ir(La050)₂(Lb005) | ETL:LiQ |
| A7 | HTM1:NDP-9 | HTM1 | HTM2 | H1:H2:Ir(La055)₂(Lb005) | ETL:LiQ |
| A8 | HTM1:NDP-9 | HTM1 | HTM2 | H1:H2:Ir(La055)₂(Lb031) | ETL:LiQ |
| A9 | HTM1:NDP-9 | HTM1 | HTM2 | H1:H2:Ir(La067)₂(Lb005) | ETL:LiQ |
| A10 | HTM1:NDP-9 | HTM1 | HTM2 | H1:H2:Ir(La083)₂(Lb005) | ETL:LiQ |
| A11 | HTM1:NDP-9 | HTM1 | HTM2 | H1:H2:Ir(La096)₂(Lb005) | ETL:LiQ |
| A12 | HTM1:NDP-9 | HTM1 | HTM2 | H1:H2:Ir(La121)₂(Lb005) | ETL:LiQ |
| A13 | HTM1:NDP-9 | HTM1 | HTM2 | H1:H2:Ir(La121)₂(Lb043) | ETL:LiQ |
| A14 | HTM1:NDP-9 | HTM1 | HTM2 | H1:H2:Ir(La132)₂(Lb005) | ETL:LiQ |
| A15 | HTM1:NDP-9 | HTM1 | HTM2 | H1:H2:Ir(La133)₂(Lb005) | ETL:LiQ |
| A16 | HTM1:NDP-9 | HTM1 | HTM2 | H1:H2:Ir(La133)₂(Lb007) | ETL:LiQ |
| A17 | HTM1:NDP-9 | HTM1 | HTM2 | H1:H2:Ir(La138)₂(Lb005) | ETL:LiQ |
| A18 | HTM1:NDP-9 | HTM1 | HTM2 | H1:H2:Ir(La145)₂(Lb005) | ETL:LiQ |
| A19 | HTM1:NDP-9 | HTM1 | HTM2 | H1:H2:Ir(La151)₂(Lb005) | ETL:LiQ |
| A20 | HTM1:NDP-9 | HTM1 | HTM2 | H1:H2:Ir(La156)₂(Lb005) | ETL:LiQ |
| Comparative | HTM1:NDP-9 | HTM1 | HTM2 | H1:H2:Comparative | ETL:LiQ |
| Example 1 | | | | compound 1 | |
| Comparative | HTM1:NDP-9 | HTM1 | HTM2 | H1:H2:Comparative | ETL:LiQ |
| Example 2 | | | | compound 2 | |
| Comparative | HTM1:NDP-9 | HTM1 | HTM2 | H1:H2:Comparative | ETL:LiQ |
| Example 3 | | | | compound 3 | |
| Comparative | HTM1:NDP-9 | HTM1 | HTM2 | H1:H2:Comparative | ETL:LiQ |
| Example 4 | | | | compound 4 | |
| Comparative | HTM1:NDP-9 | HTM1 | HTM2 | H1:H2:Comparative | ETL:LiQ |
| Example 5 | | | | compound 5 | |

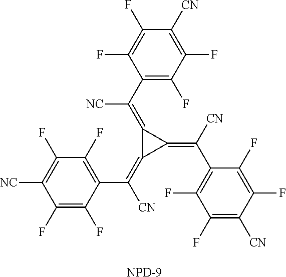

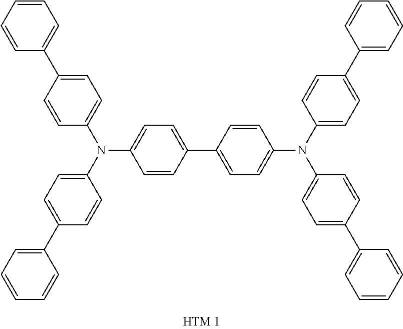 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

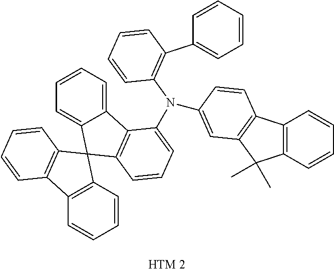 [SMILES: CC1(C)c2ccccc2-c2ccc(N(c3ccccc3-c3ccccc3)c3cccc4c3-c3ccccc3C43c4ccccc4-c4ccccc43)cc21]

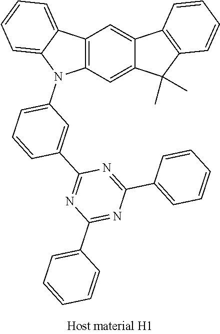 [SMILES: CC1(C)c2ccccc2-c2cc3c4ccccc4n(-c4cccc(-c5nc(-c6ccccc6)nc(-c6ccccc6)n5)c4)c3cc21]

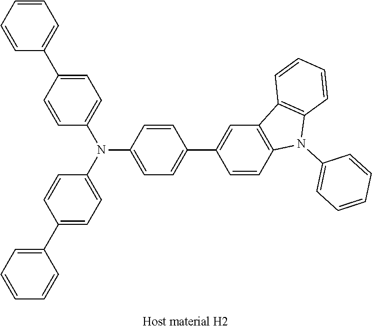 [SMILES: c1ccc(-c2ccc(N(c3ccc(-c4ccccc4)cc3)c3ccc(-c4ccc5c(c4)c4ccccc4n5-c4ccccc4)cc3)cc2)cc1]

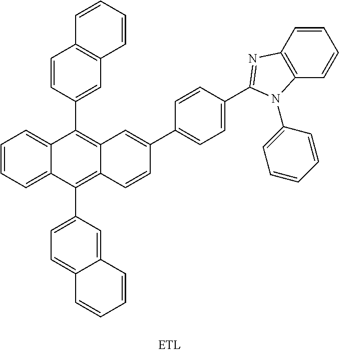 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

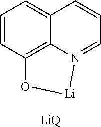

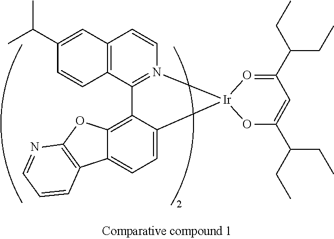

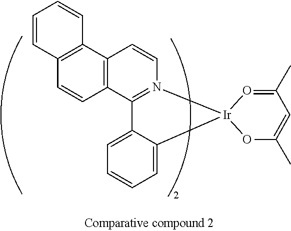

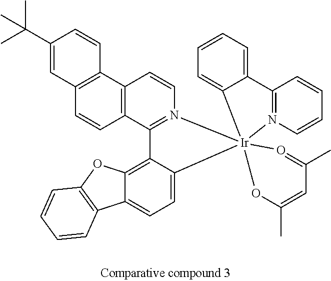

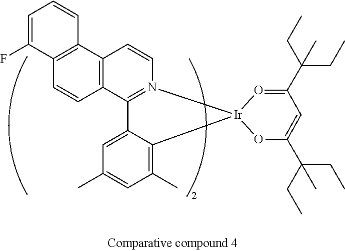

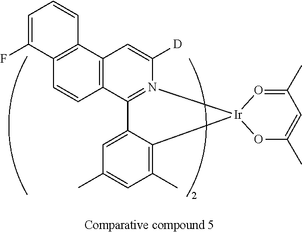

Evaluation: The above device was subjected to a device performance test. In the Examples and Comparative Examples, a constant current power supply (Keithley 2400) was used to flow a fixed current density through the light-emitting element, and a spectroradiometer (CS 2000) was used to measure the luminous spectrum. At the same time, the voltage value and the time when the test luminance reached 95% of the initial luminance (LT95) were measured. The results are as follows. The current efficiency and lifespan of the device were calculated with the values of the comparative compound 4 as 100%.

| | Start-up | Current | Peak | Full width | LT95@ |
|---|---|---|---|---|---|
| | voltage @20 | efficiency | wavelength/ | at half | 5000 |
| | mA/cm²/(V) | @20 mA/cm² | nm | maximum/nm | nits |
| Example A1 | 3.83 | 106 | 618 | 44 | 225 |
| Example A2 | 3.85 | 112 | 616 | 43 | 187 |
| Example A3 | 3.78 | 114 | 619 | 42 | 231 |
| Example A4 | 3.69 | 123 | 620 | 41 | 242 |
| Example A5 | 3.72 | 118 | 621 | 41 | 257 |
| Example A6 | 3.82 | 105 | 617 | 43 | 155 |
| Example A7 | 3.78 | 121 | 619 | 41 | 264 |
| Example A8 | 3.83 | 114 | 620 | 42 | 167 |
| Example A9 | 3.85 | 109 | 617 | 44 | 142 |
| Example A10 | 3.81 | 118 | 619 | 43 | 266 |
| Example A11 | 3.84 | 112 | 617 | 43 | 205 |
| Example A12 | 3.82 | 109 | 621 | 42 | 201 |
| Example A13 | 3.86 | 107 | 617 | 43 | 188 |
| Example A14 | 3.84 | 118 | 619 | 43 | 213 |
| Example A15 | 3.77 | 112 | 618 | 42 | 170 |
| Example A16 | 3.78 | 113 | 618 | 43 | 236 |
| Example A17 | 3.83 | 104 | 620 | 44 | 179 |
| Example A18 | 3.80 | 108 | 619 | 43 | 156 |
| Example A19 | 3.74 | 114 | 619 | 42 | 221 |
| Example A20 | 3.76 | 116 | 619 | 43 | 209 |
| Comparative Example 1 | 4.52 | 69 | 617 | 49 | 91 |
| Comparative Example 2 | 4.79 | 78 | 618 | 58 | 70 |
| Comparative Example 3 | 4.90 | 65 | 614 | 66 | 63 |
| Comparative Example 4 | 4.67 | 100 | 620 | 55 | 100 |
| Comparative Example 5 | 4.71 | 80 | 617 | 62 | 92 |

From the comparison of the data in the above table, it can be seen that the iridium complex prepared by using the compound of the present disclosure where a specific alkyl-substituted dibenzofuran linked to N-heterobenzoisoquinoline as a ligand has a strong rigid structure, which suppresses the vibration of the molecule, so that the compound has a narrow full width at half maximum and is used in the organic electroluminescent device as a dopant, in the same device, compared with the comparative compounds 1-6, it exhibits more superior performance in terms of driving voltage, light-emitting efficiency, and service life of device.

Comparison of evaporation temperatures: the evaporation temperature is defined as: at a vacuum degree of 10⁻⁷ Torr, the temperature corresponding to the evaporation rate of 1 angstrom per second. The test results are as follows:

| | Evaporation |
|---|---|
| Materials | temperature |
| Ir(La028)₂(Lb005) | 266 |
| Ir(La034)₂(Lb007) | 268 |
| Ir(La055)₂(Lb005) | 269 |
| Ir(La121)₂(Lb005) | 264 |
| Ir(La133)₂(Lb005) | 264 |
| Comparative compound 1 | 274 |
| Comparative compound 2 | 279 |
| Comparative compound 3 | 275 |
| Comparative compound 5 | 276 |

From the comparison of the data in the above table, it can be seen that the metal iridium complex of the present disclosure has a lower evaporation temperature, which is conducive to industrial application.

Compared with the prior art, the present disclosure unexpectedly provides better light-emitting efficiency and improved service life of device through the special combination of substituents, and provides a lower evaporation temperature and more saturated red light emission. The above results show that the compounds of the present disclosure have the advantages of a low sublimation temperature, high photochemical and electrochemical stability, a high color saturation, a high light-emitting efficiency, and a long service life of device, and the like, and can be used in organic electroluminescent devices. In particular, as a red light-emitting dopant, it has the potential to be applied in the OLED industry, especially for displays, lighting and car taillights.

1. A metal complex having a general formula of Ir(La)(Lb)(Lc), comprising a structure of formula (1), 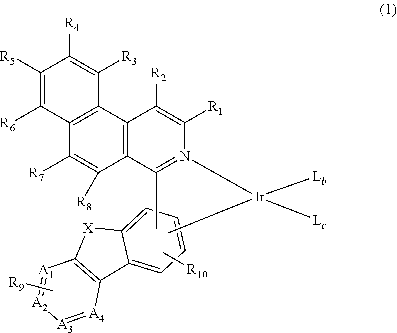
wherein La is 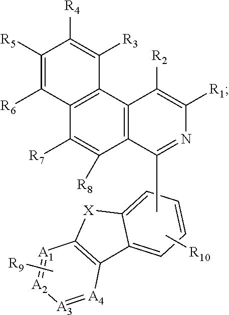
wherein X is selected from O, S, or Se;
wherein one of A₁ to A₄ is CR₉, and the other three of A₁ to A₄ are independently CR₀ or N, and at least one of the other three of A₁ to A₄ is N;
wherein R₀ and R₁-R₁₀ are independently selected from the group consisting of hydrogen, deuterium, halogen, a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, a substituted or unsubstituted heterocycloalkyl with 3-20 ring-forming carbon atoms, a substituted or unsubstituted C3-C30 alkylsilyl, a substituted or unsubstituted C1-C10 alkoxy, a substituted or unsubstituted C7-C30 aralkyl, a substituted or unsubstituted C6-C30 aryloxy, a substituted or unsubstituted C2-C20 alkenyl, a substituted or unsubstituted C2-C20 alkynyl, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano and phosphino;
wherein the substitution in R₀ and R₁-R₁₀ refers to being substituted with deuterium, F, Cl, Br, C1-C4 alkyl, C1-C4 alkoxy, C3-C6 cycloalkyl, C1-C4 alkyl substituted amino, C6-C10 aryl, C1-C4 alkyl substituted C6-C10 aryl, cyano, isocyano or phosphino;
wherein the heteroatom in the heteroalkyl, heterocycloalkyl or heteroaryl is at least one of S, O and N;
wherein each of Lb and Lc is a monoanionic bidentate ligand, and two of La, Lb and Lc are arbitrarily connected to each other to form a multidentate ligand, or La, Lb and Lc are connected through a single group; and
wherein at least two of La, Lb and Lc are the same.

2. The metal complex according to claim 1, wherein La has one of the following structures: 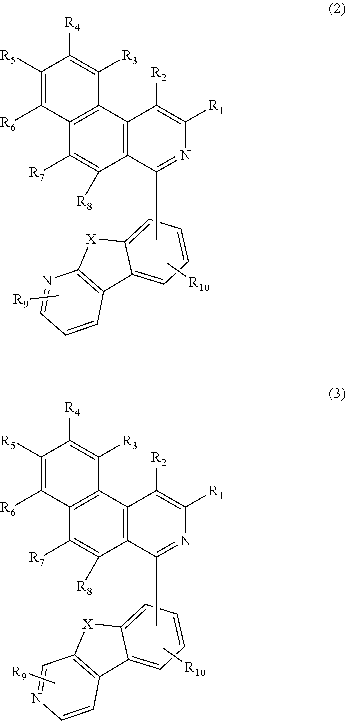
wherein R₁-R₁₀ are as defined above, and R₁₀ is not hydrogen.

3. The metal complex according to claim 2, wherein La has one of the following structures:

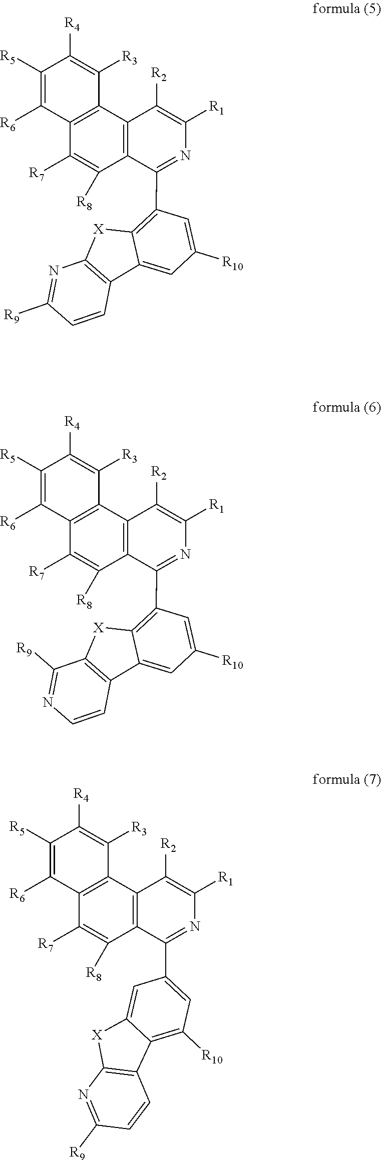

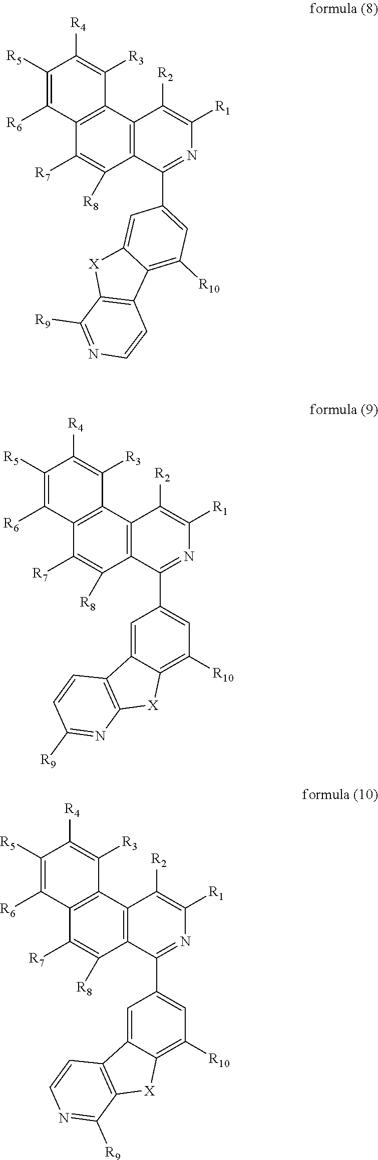

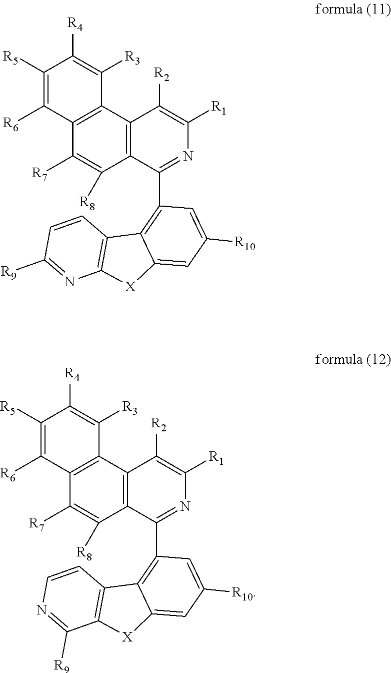

4. The metal complex according to claim 3, wherein at least one of R₁-R₉ is not hydrogen, and R₁₀ is a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, or a substituted or unsubstituted heterocycloalkyl with 3-20 ring-forming carbon atoms.

5. The metal complex according to claim 4, wherein R₉ and R₁₀ are a substituted or unsubstituted alkyl with a number of carbon atoms in the main chain of no more than 4, or a substituted or unsubstituted cycloalkyl with a number of ring-forming carbon atoms of no more than 6.

6. The metal complex according to claim 5, wherein R₁-R₈ are independently selected from the group consisting of hydrogen, deuterium, halogen, a substituted or unsubstituted alkyl with 1-10 main-chain carbon atoms, a substituted or unsubstituted cycloalkyl with 3-10 ring-forming carbon atoms, a substituted or unsubstituted C6-C20 aryl, a substituted or unsubstituted C3-C20 heteroaryl, cyano and isocyano; wherein the substitution in R₁-R₈ refers to being substituted with deuterium, F, Cl, Br, C1-C4 alkyl, cyano or isocyano, and X is an oxygen atom O.

7. The metal complex according to claim 6, wherein one of R₁-R₈ is an electron-withdrawing group, and the rest of R₁-R₈ are hydrogen or each contain one or two deuteriums; and the electron-withdrawing group is F, F substituted C1-C4 alkyl, cyano, or pyridyl.

8. The metal complex according to claim 1, wherein La is selected from one of the following structural formulas, or is one of the following structural formulas in which hydrogen is partially or completely replaced by deuterium or fluorine:

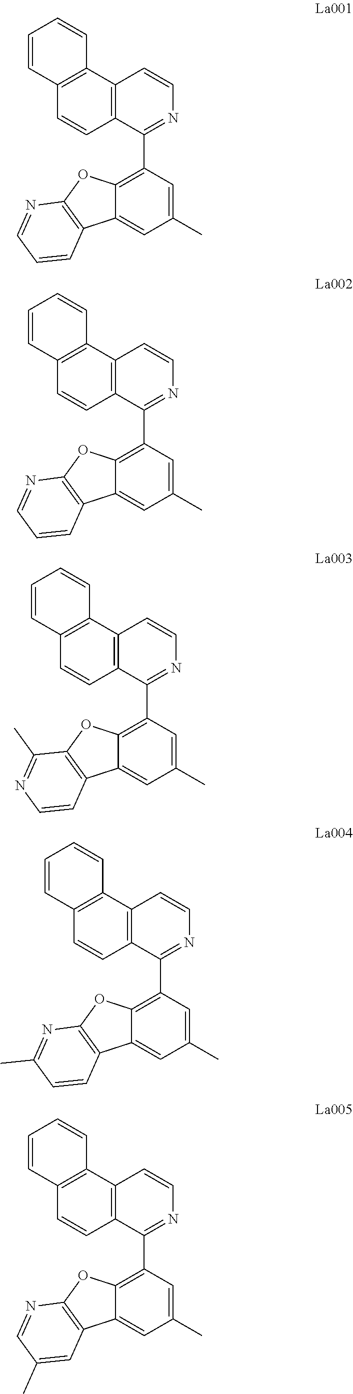

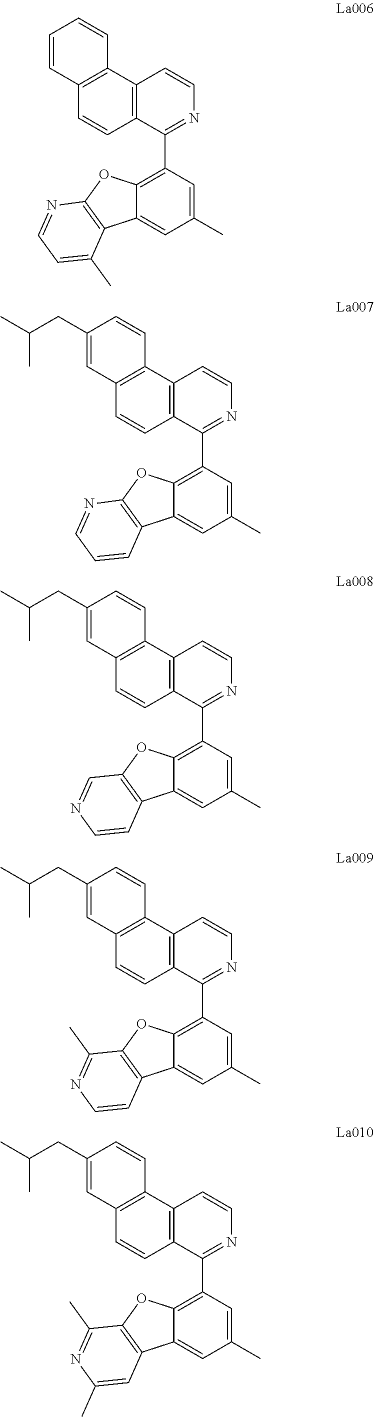

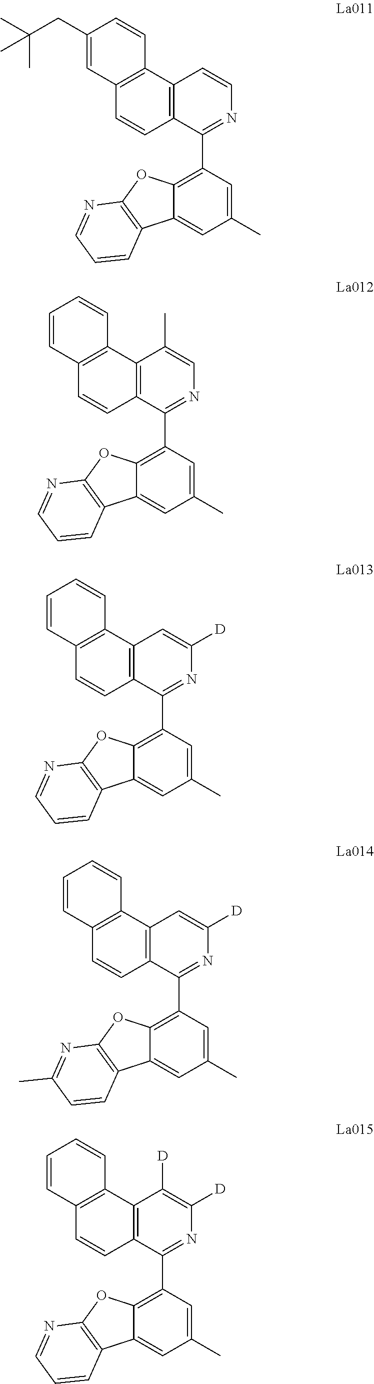

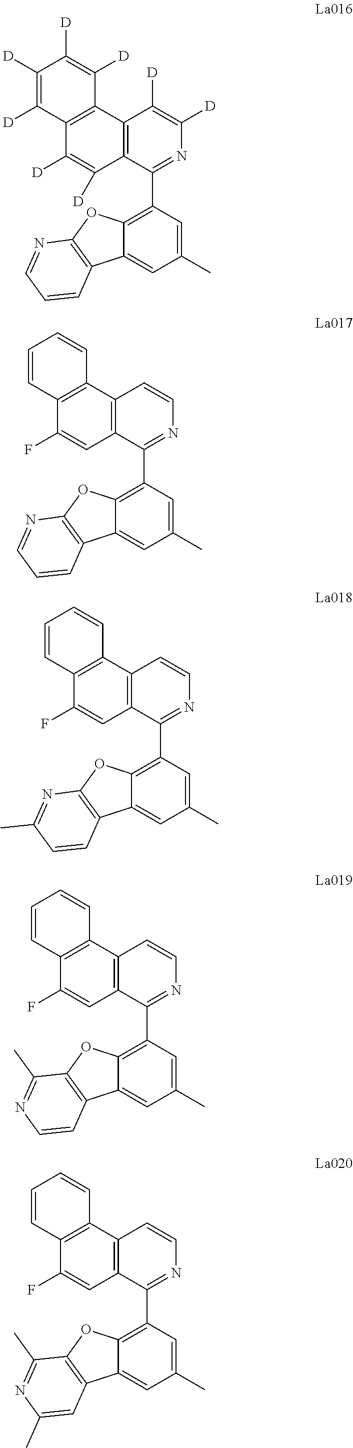

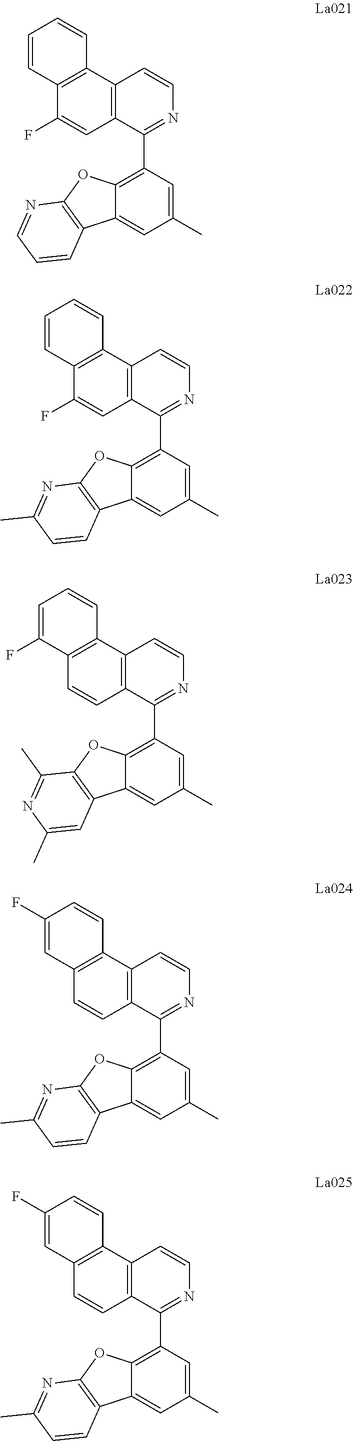

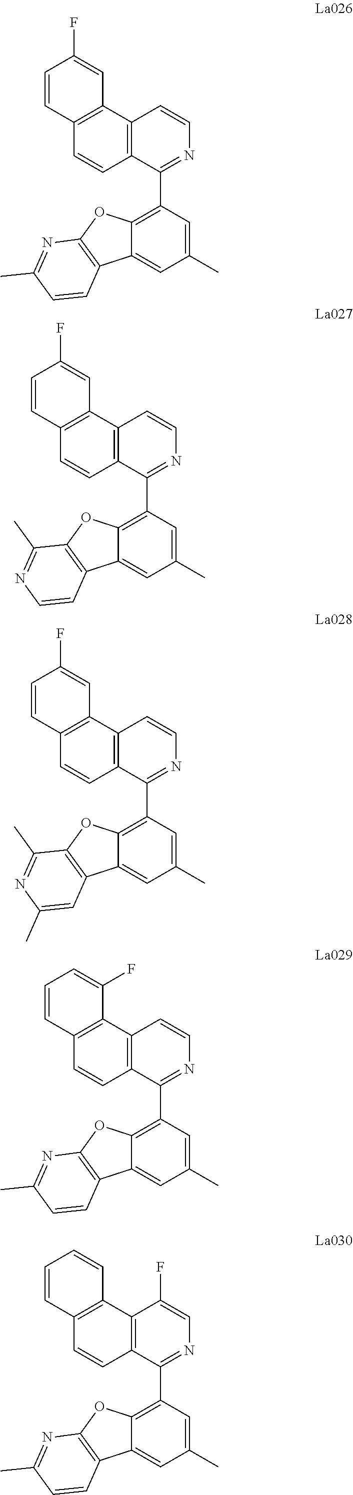

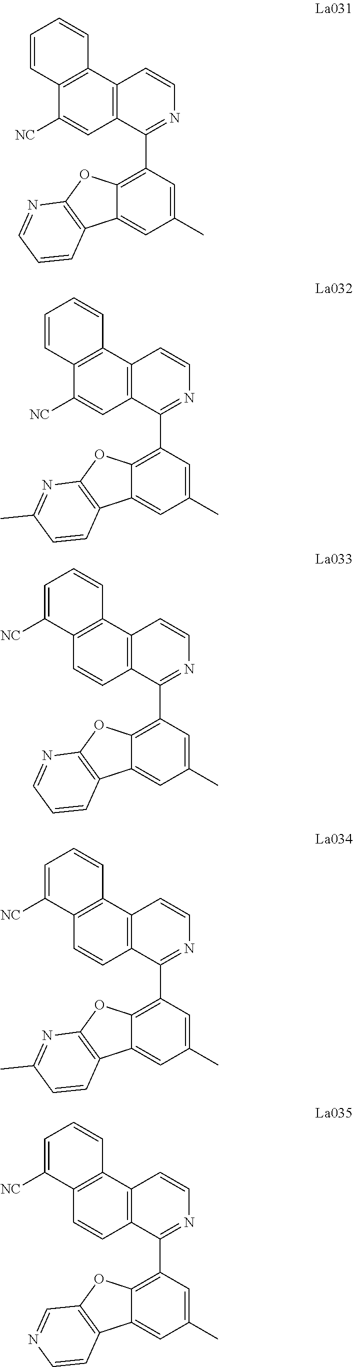

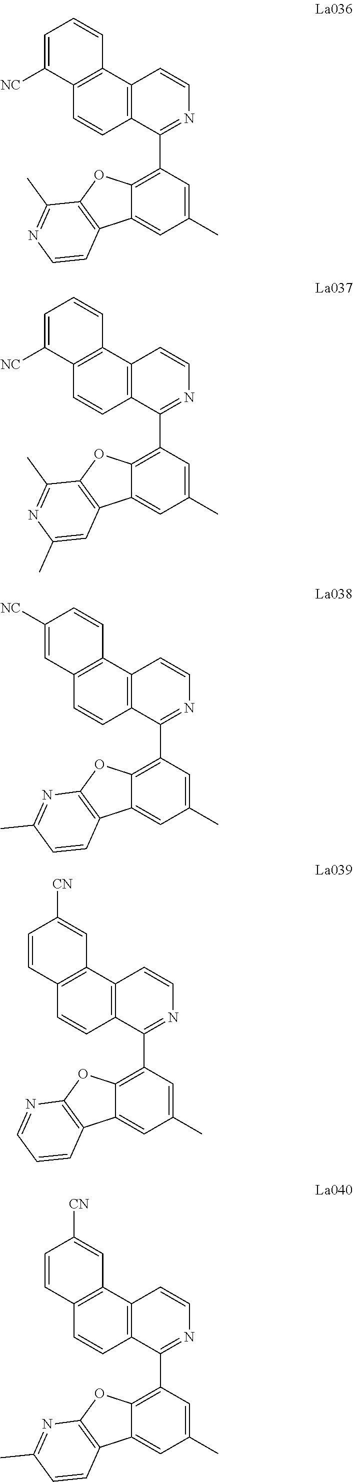

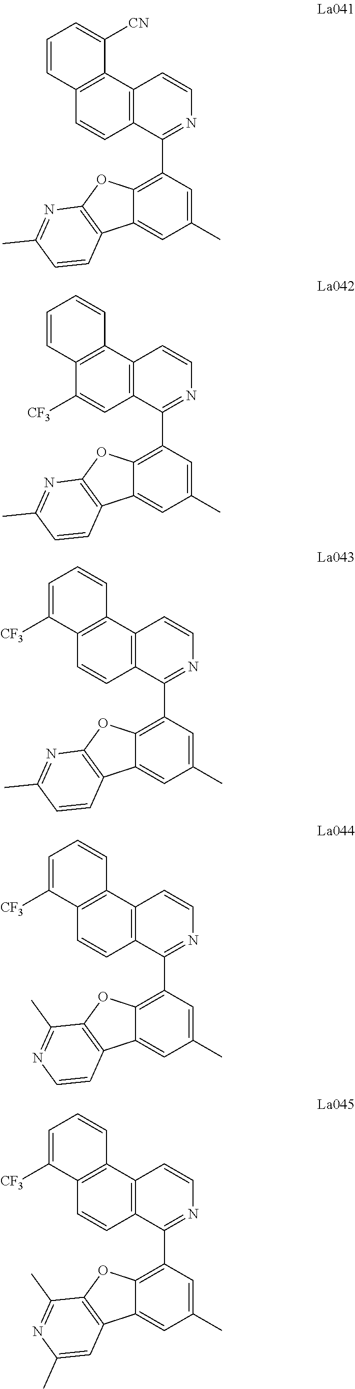

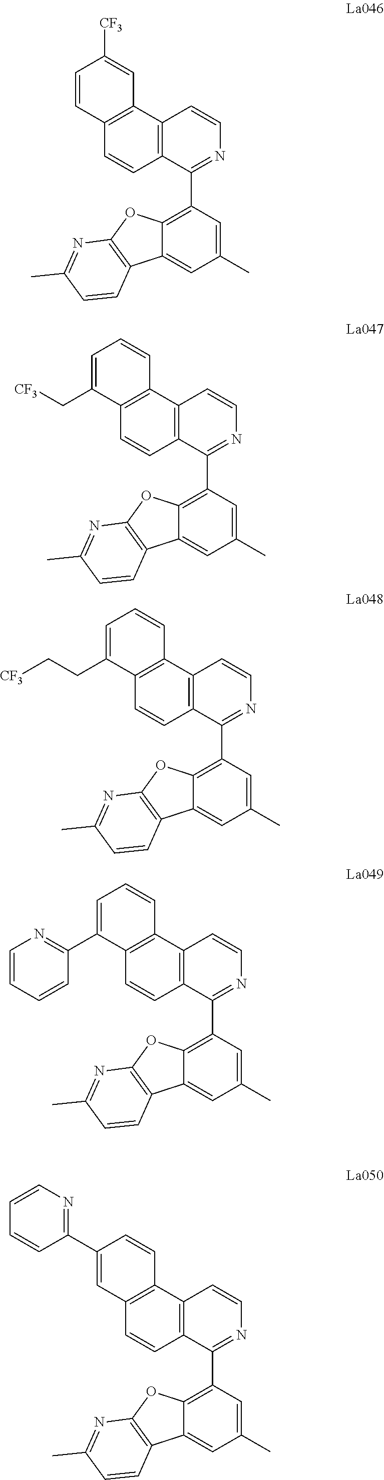

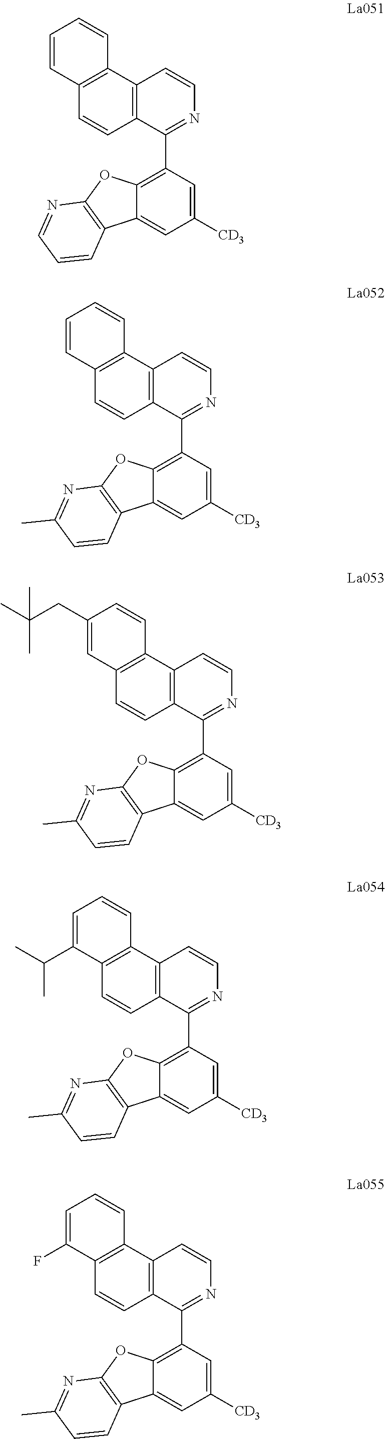

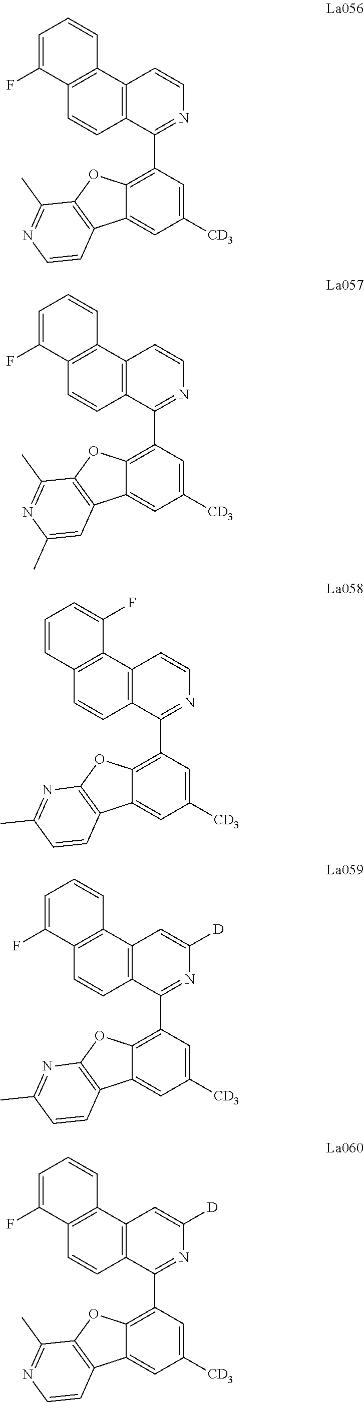

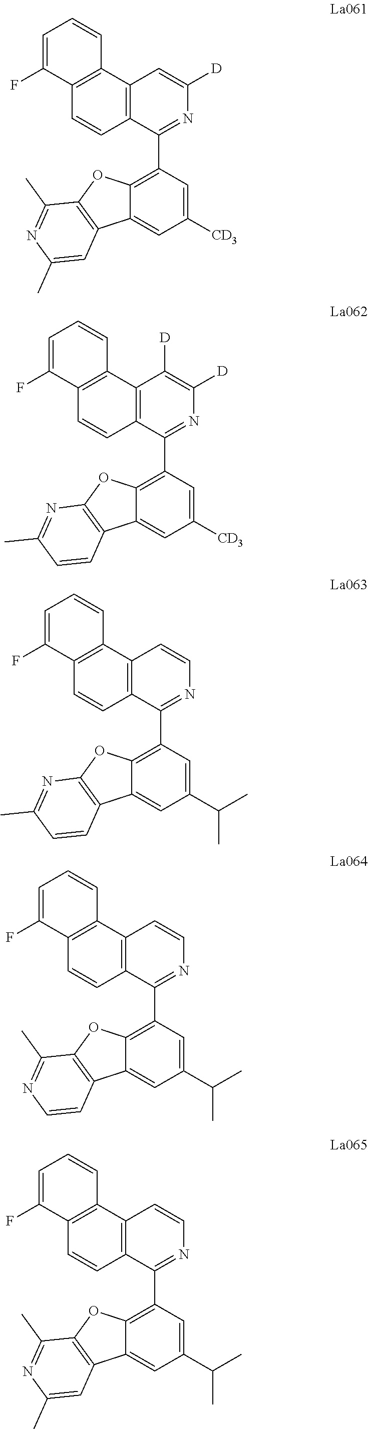

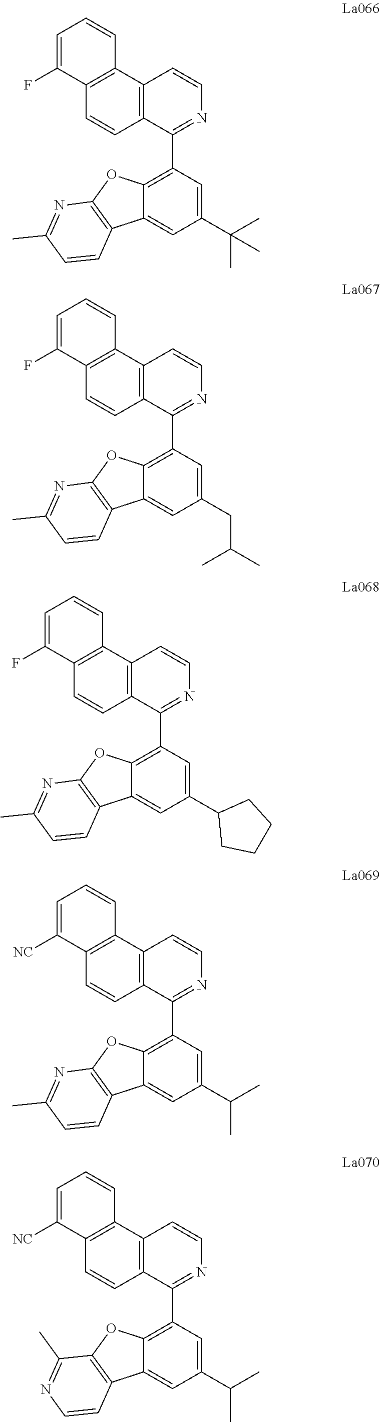

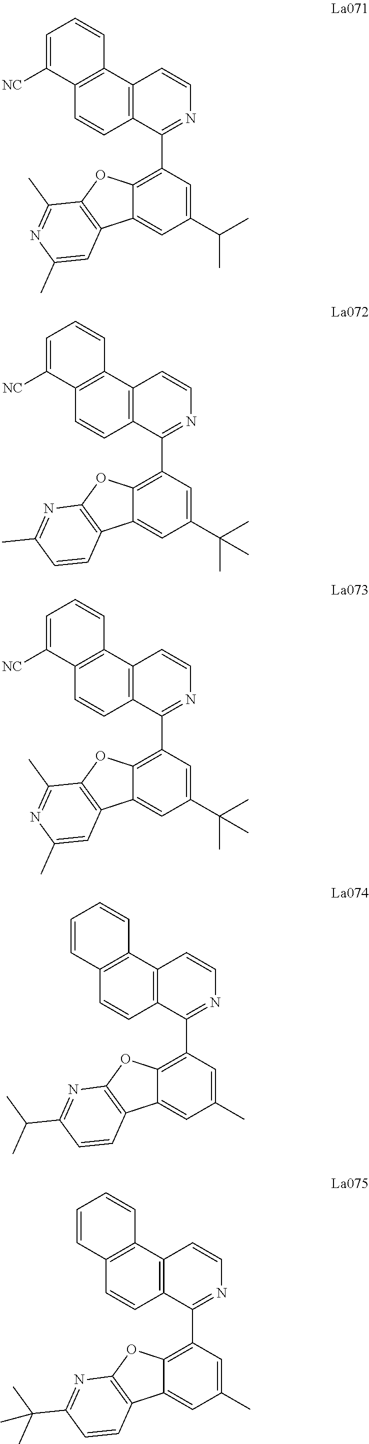

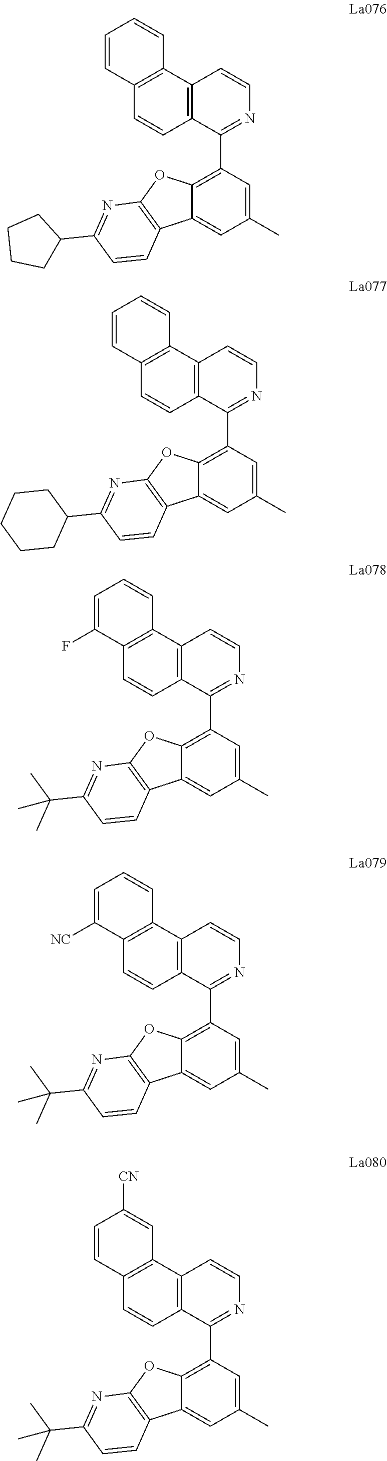

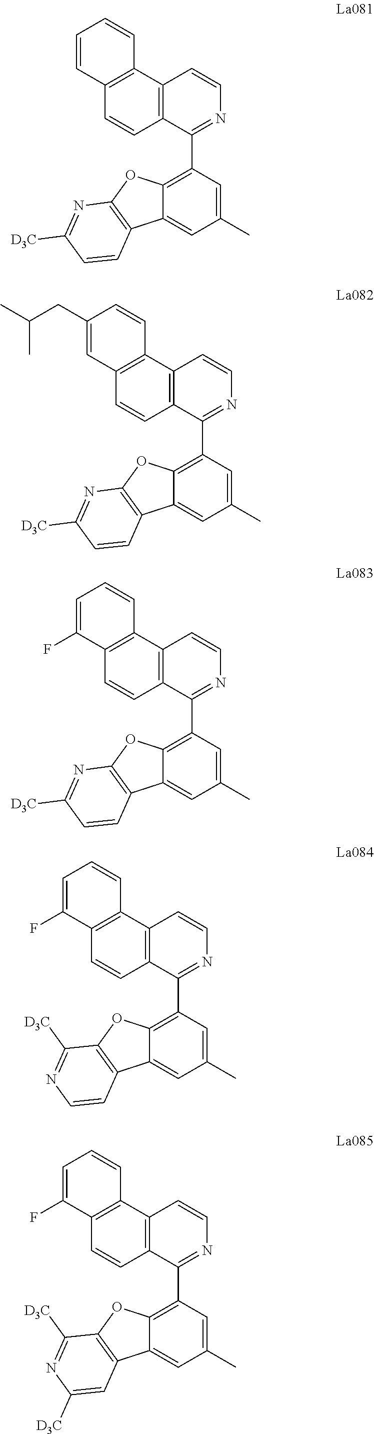

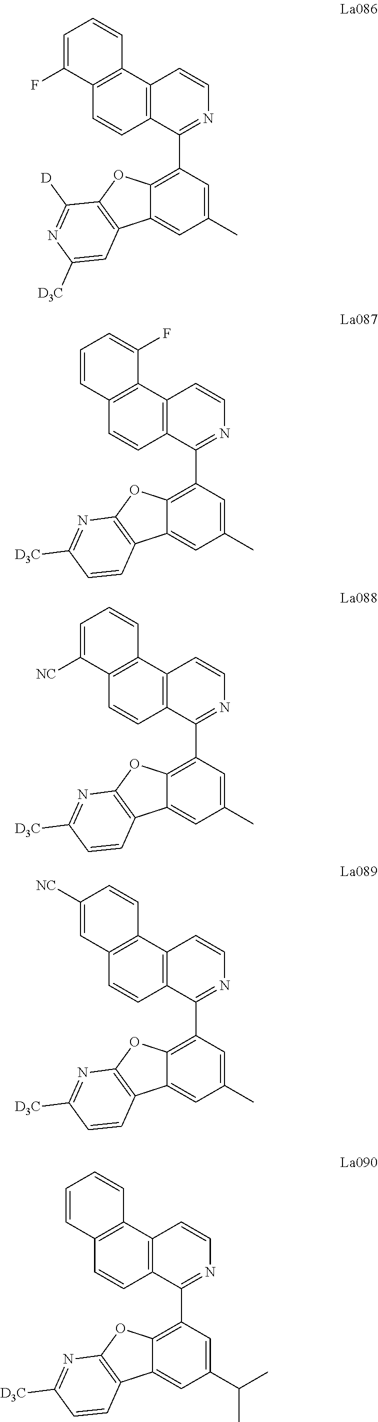

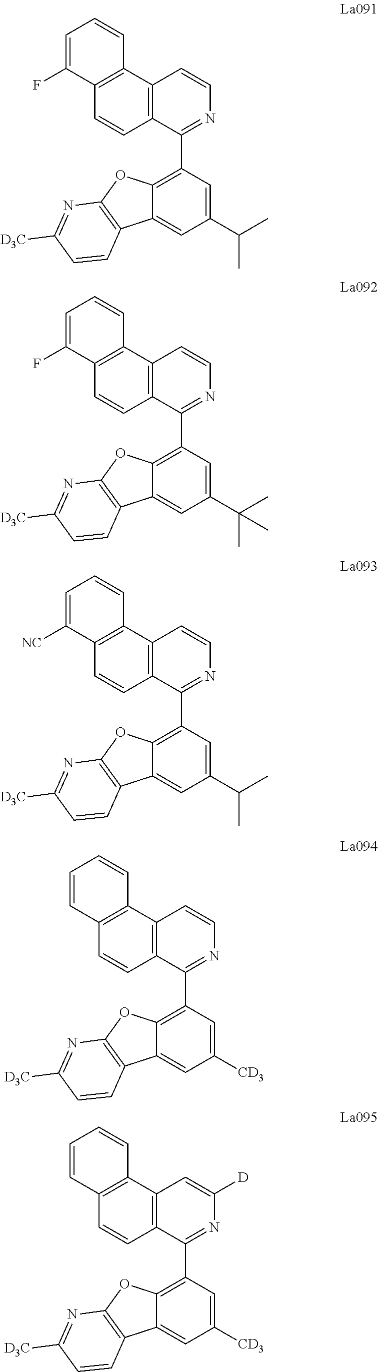

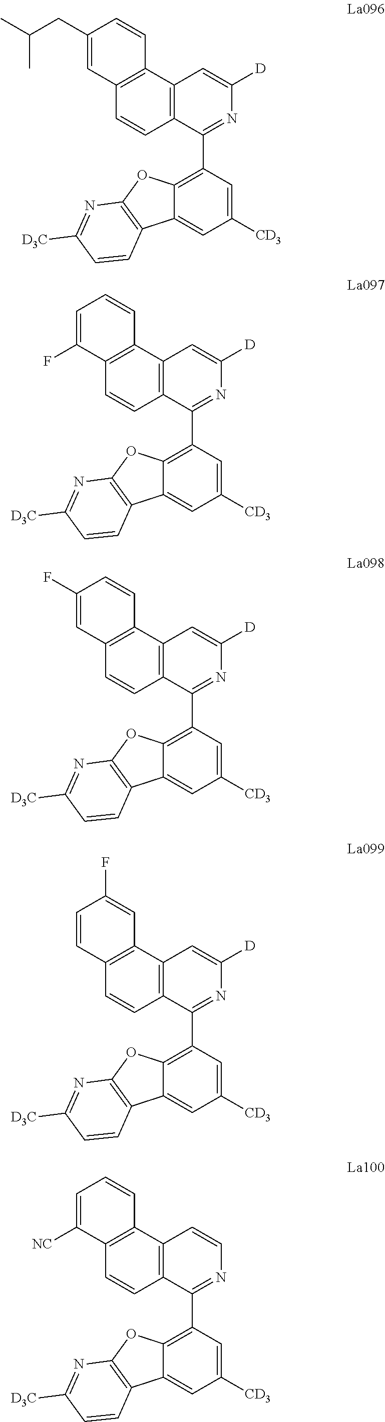

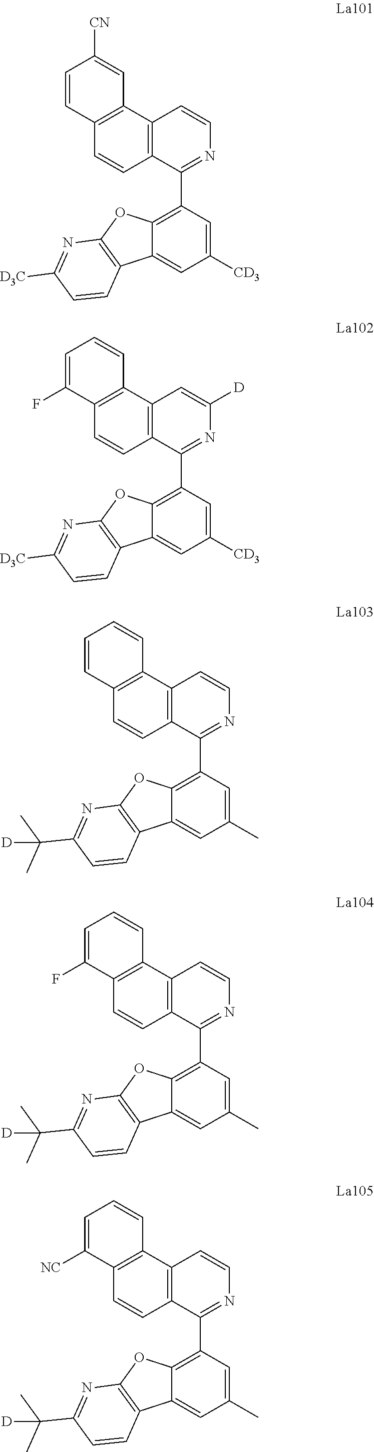

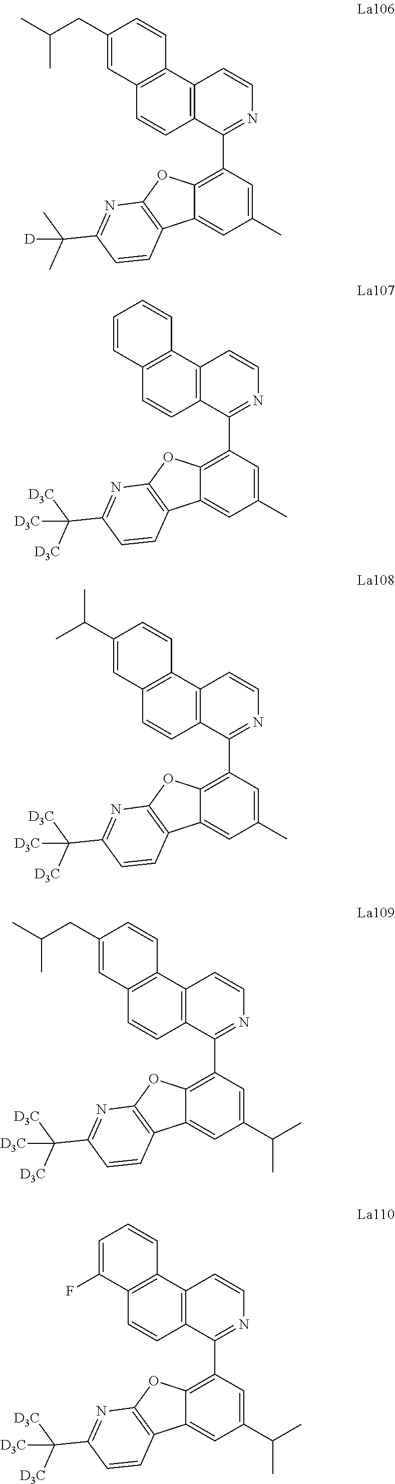

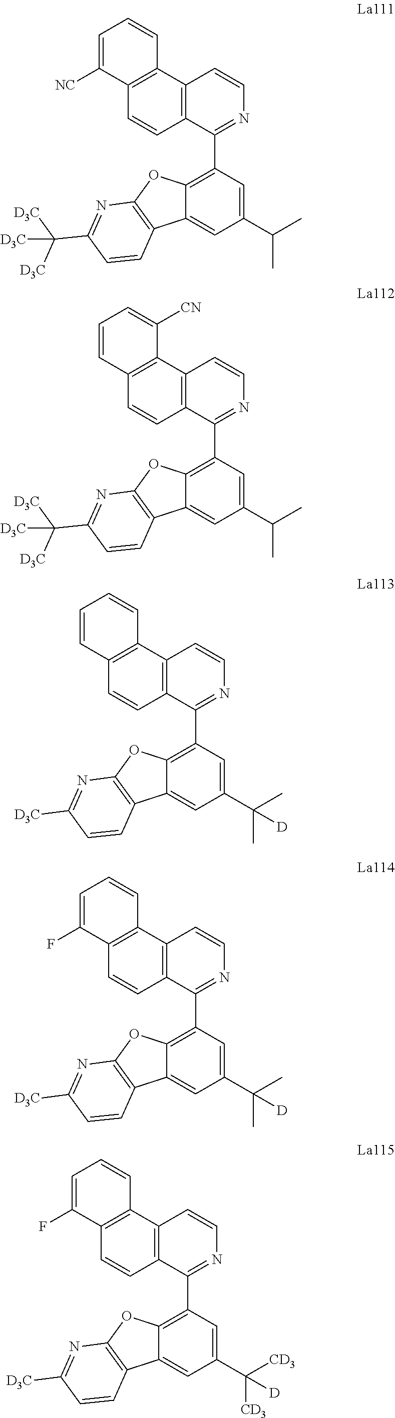

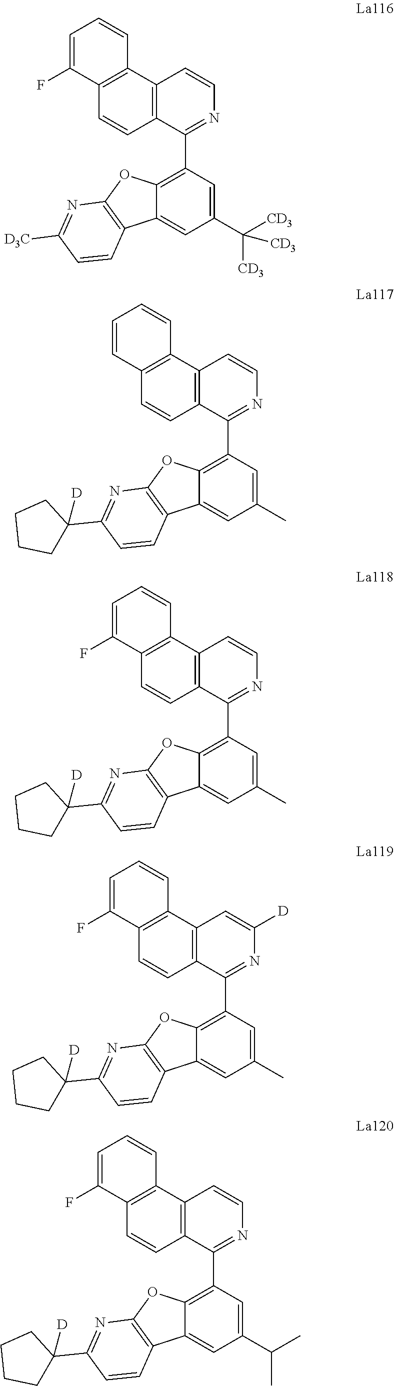

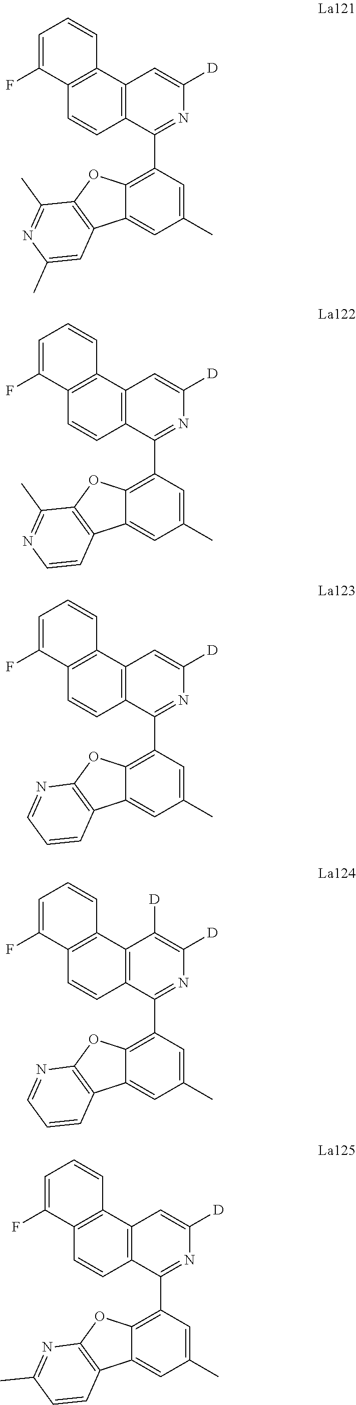

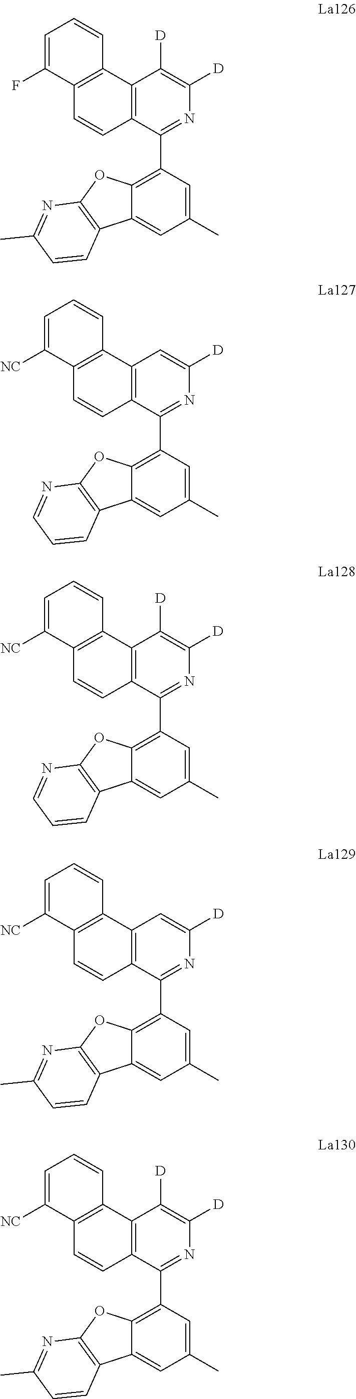

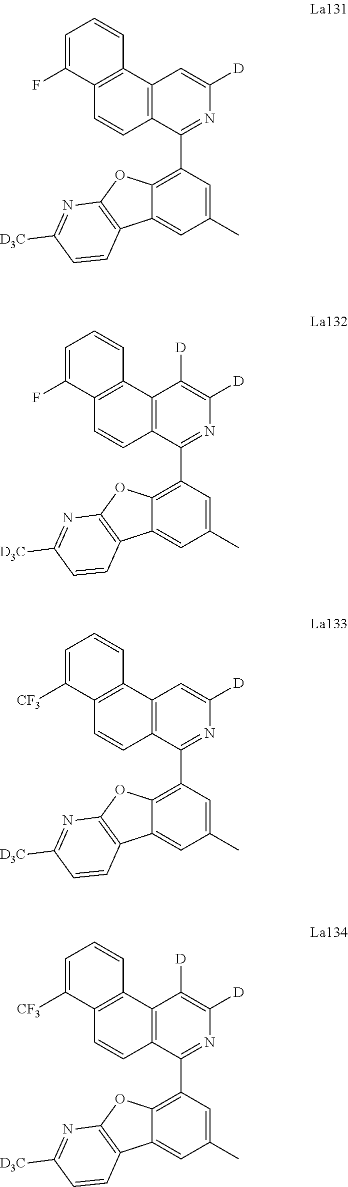 [SMILES: [2H]c1cc2c(ccc3c(F)cccc32)c(-c2cc(C)cc3c2oc2nc(C([2H])([2H])[2H])ccc23)n1 ; [2H]c1nc(-c2cc(C)cc3c2oc2nc(C([2H])([2H])[2H])ccc23)c2ccc3c(F)cccc3c2c1[2H] ; [2H]c1cc2c(ccc3c(C(F)(F)F)cccc32)c(-c2cc(C)cc3c2oc2nc(C([2H])([2H])[2H])ccc23)n1 ; [2H]c1nc(-c2cc(C)cc3c2oc2nc(C([2H])([2H])[2H])ccc23)c2ccc3c(C(F)(F)F)cccc3c2c1[2H]]

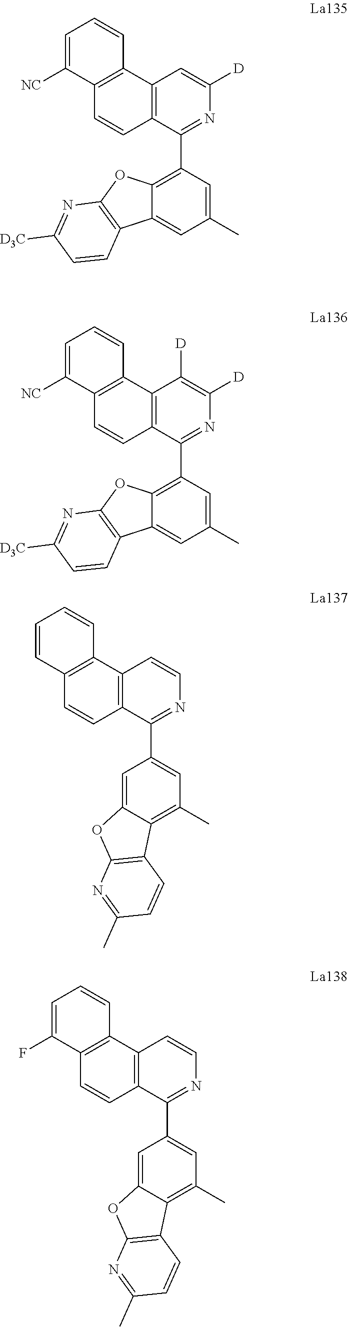

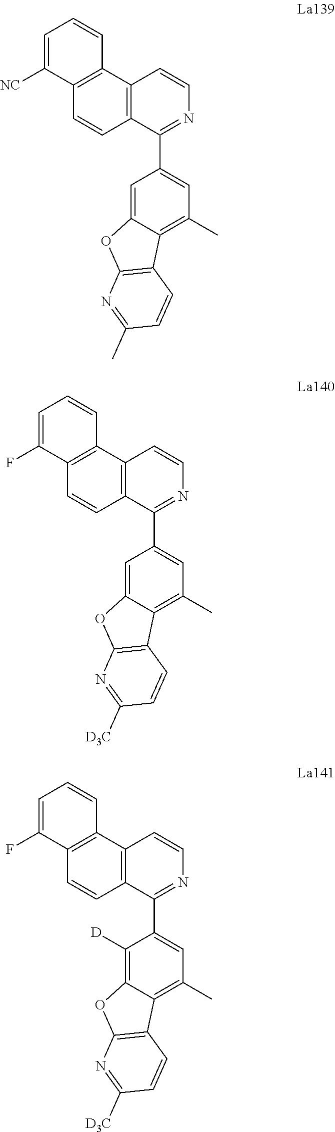 [SMILES: Cc1ccc2c(n1)oc1cc(-c3nccc4c3ccc3c(C#N)cccc34)cc(C)c12 ; [2H]C([2H])([2H])c1ccc2c(n1)oc1cc(-c3nccc4c3ccc3c(F)cccc34)cc(C)c12 ; [2H]c1c(-c2nccc3c2ccc2c(F)cccc23)cc(C)c2c1oc1nc(C([2H])([2H])[2H])ccc12]

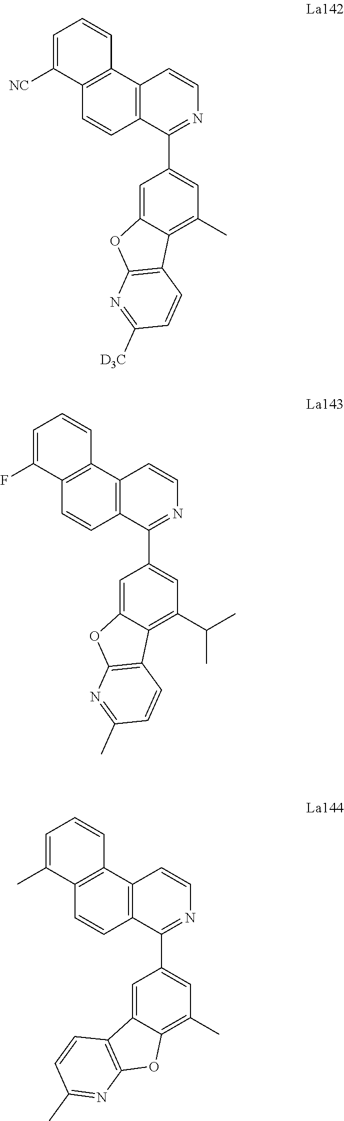

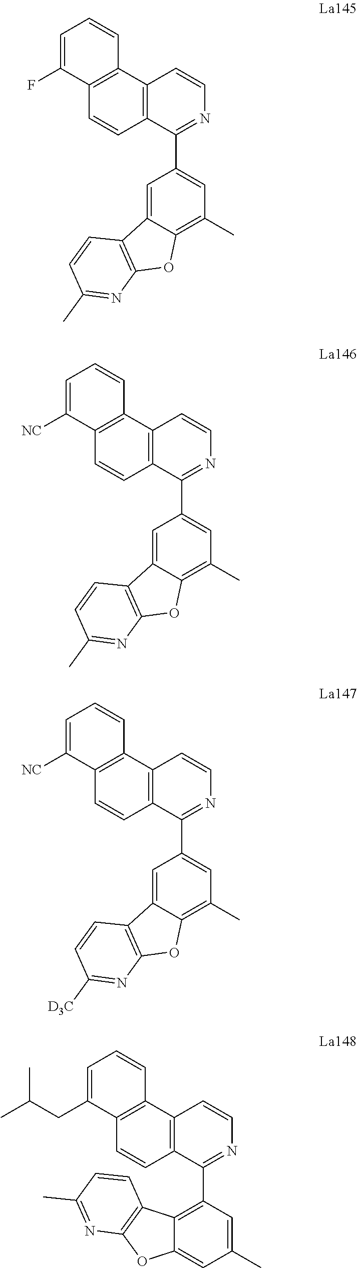

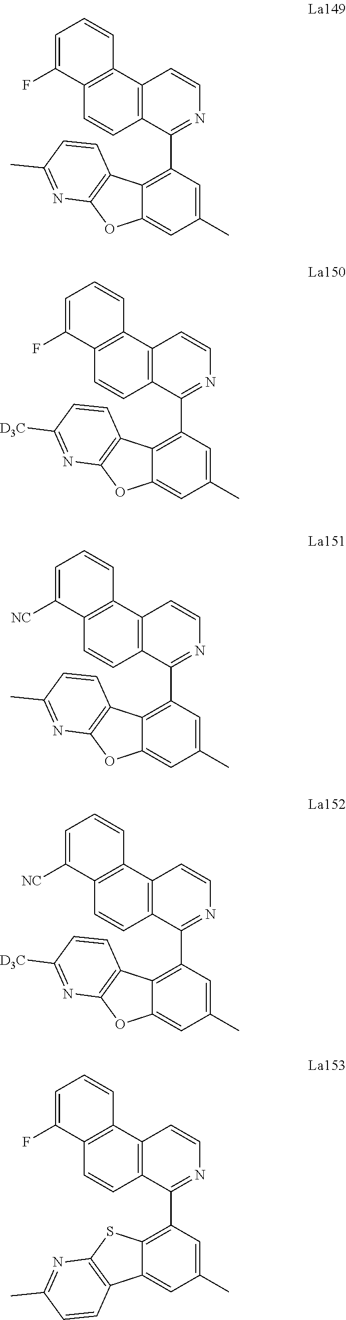

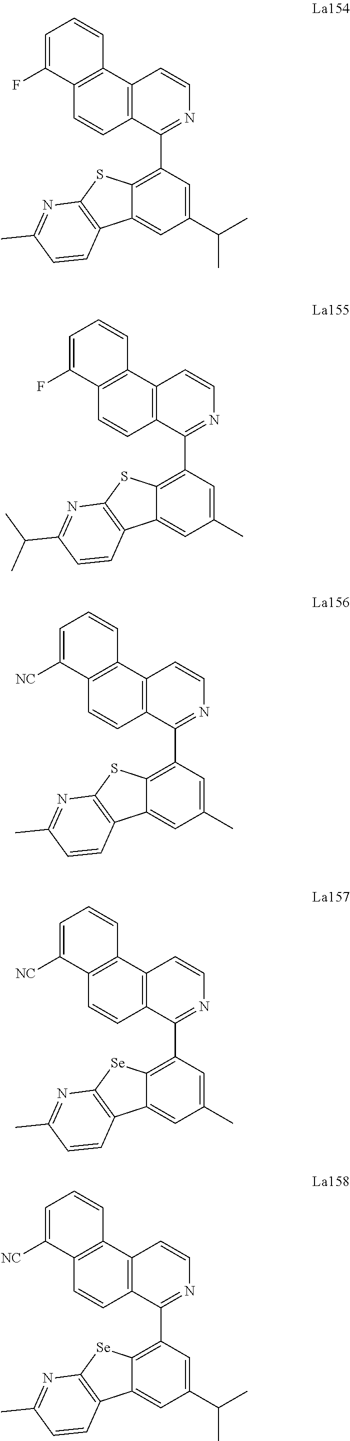

9. The metal complex according to claim 1, wherein Lc and La have the same structure and are formed a (La)₂Ir(Lb) structure.

10. The metal complex of claim 9, wherein Lb has a structure of formula (4): 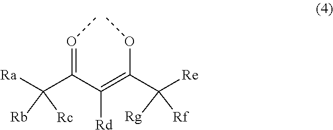
wherein a dotted line represents a position of connection to the metal iridium; and
wherein Rₐ-R_{g} are independently selected from the group consisting of hydrogen, deuterium, halogen, a substituted or unsubstituted alkyl with 1-10 main-chain carbon atoms, a substituted or unsubstituted cycloalkyl with 3-20 ring-forming carbon atoms, a substituted or unsubstituted heteroalkyl with 1-10 main-chain carbon atoms, and a substituted or unsubstituted heterocycloalkyl with 3-20 ring-forming carbon atoms; or two of Rₐ, R_{b} and R_{c} are connected to each other to form an aliphatic cyclic structure, and two of Rₑ, R_{f} and R_{g} are connected to each other to form an aliphatic cyclic structure; wherein the substitution in Rₐ-R_{g} refers to being substituted with deuterium, F, Cl, Br, C1-C4 alkyl, C1-C4 alkoxy, C3-C6 cycloalkyl, and C1-C4 alkyl substituted amino, cyano, isocyano, or phosphino.

11. The metal complex according to claim 10, wherein Rₐ, R_{b}, and R_{c} are the same as Rₑ, R_{f}, and R_{g}, respectively.

12. The metal complex according to claim 11, wherein Rₐ, R_{b}, R_{c}, Rₑ, R_{f} and R_{g} are independently selected from the group consisting of hydrogen, deuterium, halogen, a substituted or unsubstituted alkyl with 1-10 main-chain carbon atoms, and a substituted or unsubstituted cycloalkyl with 3-20 ring-forming carbon atoms, or two of Rₐ, R_{b} and R_{c} are connected to each other to form an aliphatic cyclic structure, and two of Rₑ, R_{f} and R_{g} are connected to each other to form an aliphatic cyclic structure; and R_{d} is selected from hydrogen, deuterium, halogen, or a substituted or unsubstituted alkyl with 1-10 main-chain carbon atoms; wherein the substitution in Rₐ-R_{g} refers to being substituted with deuterium, F, Cl, Br, C1-C4 alkyl, or C3-C6 cycloalkyl.

13. The metal complex according to claim 10, wherein Lb is selected from one of the following structural formulas, or is one of the following structural formulas in which hydrogen is partially or completely replaced by deuterium or fluorine:

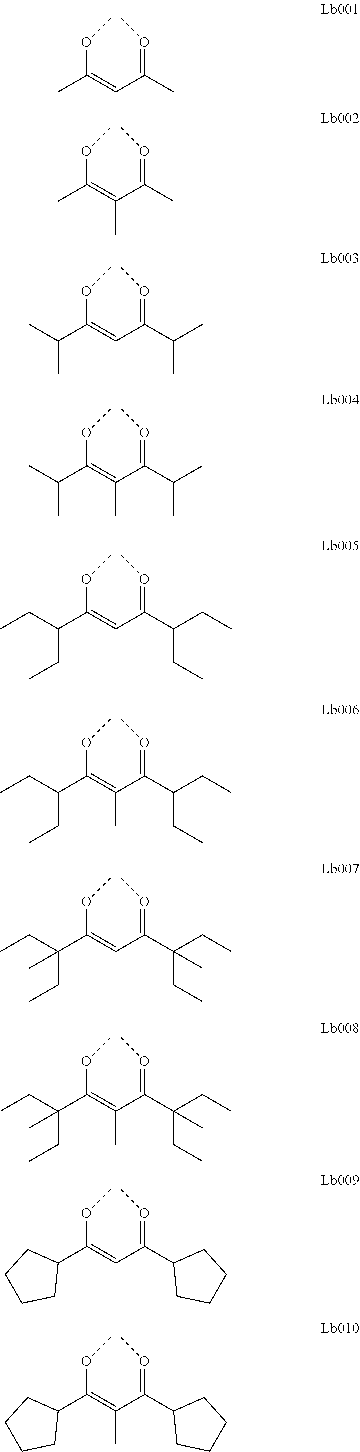

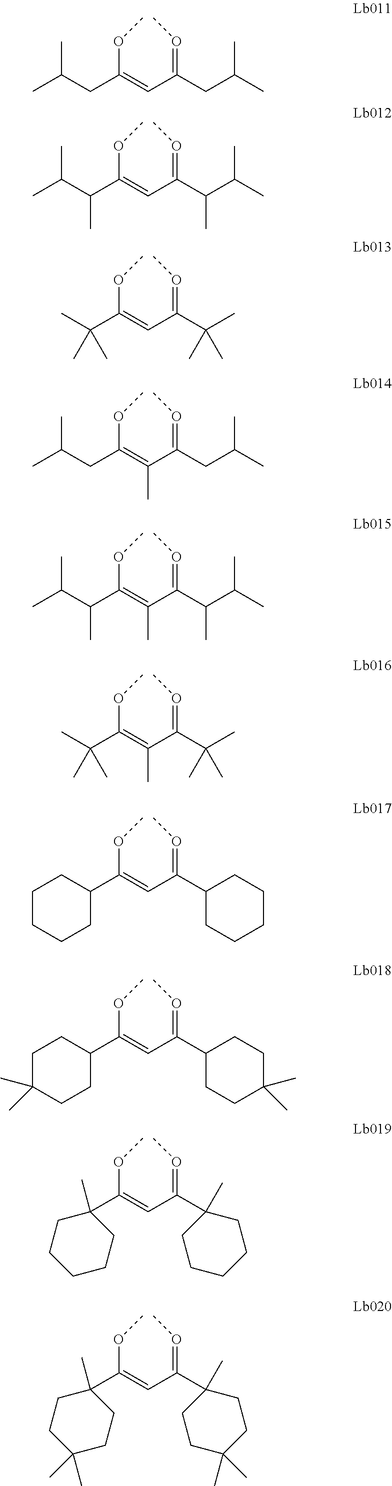

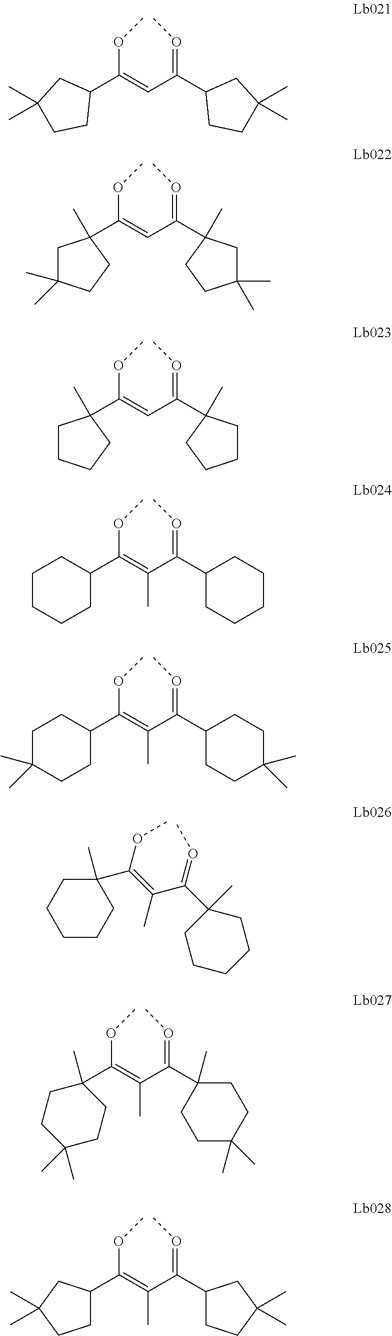

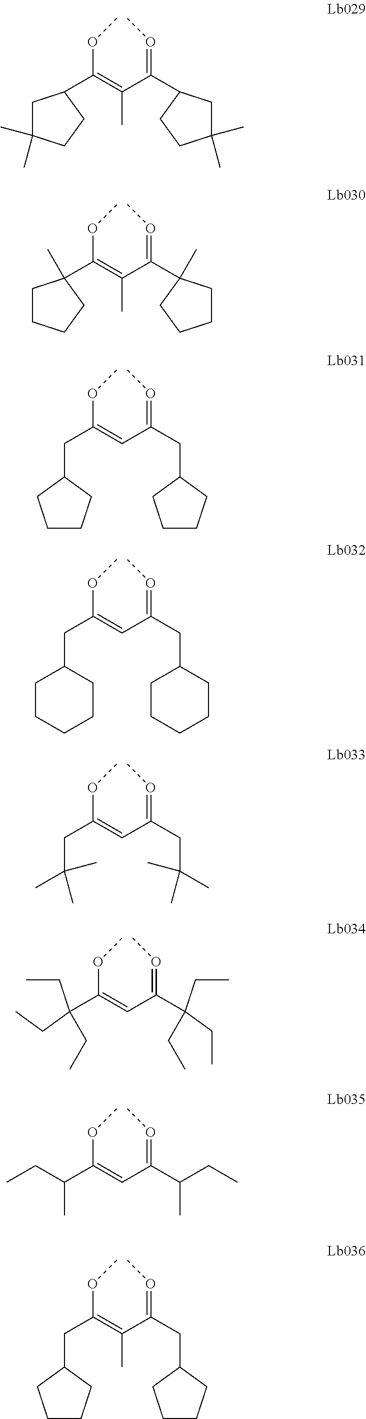

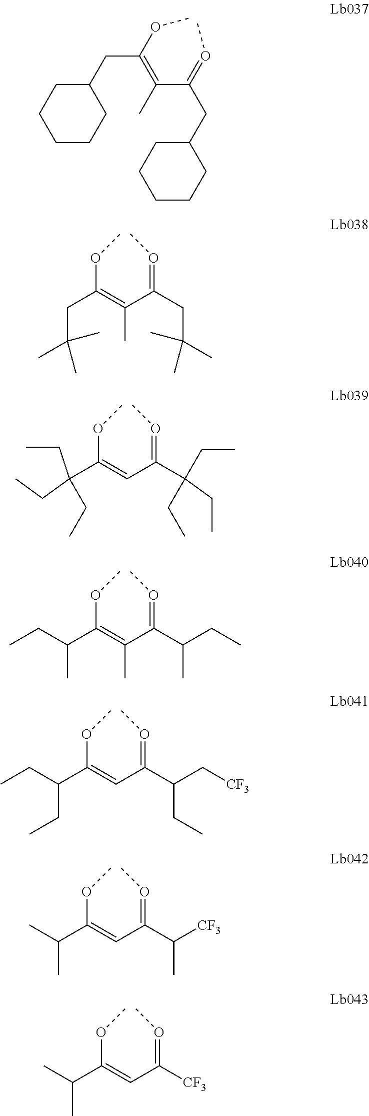

14. An electroluminescent device comprising a cathode, an anode, and an organic layer disposed between the cathode and the anode, wherein the organic layer comprises the metal complex according to claim 1.

15. The electroluminescent device according to claim 14, wherein the organic layer is a light-emitting layer, and the metal complex serves as a red light-emitting doping material of the light-emitting layer.
